(19) United States
(12) Patent Application Publication
(10) Pub. No.: US 2026/0047058 A1
(43) Pub. Date: Feb. 12, 2026

(54) SEMICONDUCTOR DEVICE

(71) Applicant: Samsung Electronics Co., Ltd., Suwon-si (KR)

(72) Inventors: Beakhyung Cho, Suwon-si (KR); Hyuckjoon Kwon, Suwon-si (KR); Hongsoo Jeon, Suwon-si (KR)

(73) Assignee: Samsung Electronics Co., Ltd., Suwon-si (KR)

(21) Appl. No.: 19/043,390

(22) Filed: Jan. 31, 2025

(30) Foreign Application Priority Data
Aug. 7, 2024 (KR) 10-2024-0105711

(51) Int. Cl. H10B 10/00

(52) U.S. Cl. CPC H10B 10/12

(57) ABSTRACT

The present disclosure provides a semiconductor device including an SRAM cell which is implemented with eight transistors capable of improving read and write performance without increasing the area as compared to an SRAM cell which is implemented with six transistors. Each memory cell includes a first inverter, a second inverter, a first pass gate transistor, and a second pass gate transistor. In addition, each memory cell includes a first additional transistor that is connected between the first pass gate transistor and the second inverter, and a second additional transistor that is connected between the second pass gate transistor and the first inverter.

### CROSS-REFERENCE TO RELATED APPLICATION

This application claims priority to and the benefit under 35 U.S.C. § 119 (a)-(d) of Korean Patent Application No. 10-2024-0105711 filed in the Korean Intellectual Property Office on Aug. 7, 2024, the entire contents of which are incorporated herein by reference.

### BACKGROUND OF THE INVENTION

### (a) Field of the Invention

The present disclosure relates to a semiconductor device.

### (b) Description of the Related Art

As electronic devices have been downsized, memory devices to be mounted in electronic devices have also been gradually downsized. As memory devices have been downsized, various researches for integrating more circuit elements in a limited space have been carried out.

Static random access memory (SRAM) devices have lower power consumption and faster operating characteristics as compared to dynamic random access memory (DRAM) devices, and are widely used in cache memory devices for computers or portable electronic devices. Electrical characteristics are important for SRAM devices, and it is required to improve these electrical characteristics.

### SUMMARY OF THE INVENTION

The present disclosure attempts to provide a semiconductor device including an SRAM cell which is implemented with eight transistors capable of improving read and write performance without increasing the area as compared to an SRAM cell which is implemented with six transistors.

A semiconductor device according to an exemplary embodiment includes a substrate having an upper surface; a memory cell array that includes a plurality of memory cells which is disposed on the substrate; and a bit line and a complementary bit line that extend in a first direction parallel with the upper surface of the substrate, and each of at least some of the plurality of memory cells includes a first inverter, a second inverter, a first pass gate transistor that is connected between the bit line and the second inverter, a second pass gate transistor that is connected between the complementary bit line and the first inverter, a first additional transistor that is connected between the first pass gate transistor and the second inverter, and a second additional transistor that is connected between the second pass gate transistor and the first inverter, and the plurality of memory cells includes a first memory cell, a second memory cell, and a third memory cell which are sequentially disposed in the first direction, and the first additional transistor of the second memory cell and the first additional transistor of the first memory cell share a source region, and the second additional transistor of the second memory cell and the second additional transistor of the third memory cell share a source region.

A semiconductor device according to an exemplary embodiment includes a substrate having an upper surface; a memory cell array that includes a plurality of memory cells which is disposed on the substrate; a bit line and a complementary bit line that extend in a first direction parallel with the upper surface of the substrate; and a word line and a complementary word line that extend in a second direction parallel with the upper surface of the substrate and perpendicular to the first direction, and each of at least some of the plurality of memory cells includes a first inverter, a second inverter, a first pass gate transistor and a first additional transistor that are connected between the bit line and the second inverter, and a second pass gate transistor and a second additional transistor that are connected between the complementary bit line and the first inverter, and the first pass gate transistor and the second pass gate transistor are connected to the word line, and the first additional transistor and the second additional transistor are connected to the complementary word line, and the plurality of memory cells includes a first memory cell, a second memory cell, and a third memory cell which are sequentially disposed in the first direction, and the first additional transistor of the second memory cell and the first additional transistor of the first memory cell share a source region, and the second additional transistor of the second memory cell and the second additional transistor of the third memory cell share a source region.

A semiconductor device according to an exemplary embodiment includes a substrate having an upper surface; a memory cell array that includes a plurality of memory cells which is disposed on the substrate; a bit line and a complementary bit line that extend in a first direction parallel with the upper surface of the substrate; and a first power line to which a first power voltage is applied, and a second power line to which a second power voltage is applied, and each of at least some of the plurality of memory cells includes a first inverter and a second inverter that are connected between the first power line and the second power line, a first pass gate transistor that is connected between the bit line and the second inverter, a second pass gate transistor that is connected between the complementary bit line and the first inverter, a first additional transistor that is connected between the second inverter, and the first power line and the second power line, and a second additional transistor that is connected between the first inverter, and the first power line and the second power line, and the plurality of memory cells includes a first memory cell, a second memory cell, and a third memory cell which are sequentially disposed in the first direction, and the first additional transistor of the second memory cell and the first additional transistor of the first memory cell share a source region, and the second additional transistor of the second memory cell and the second additional transistor of the third memory cell share a source region.

According to the exemplary embodiments, it is possible to provide a semiconductor device including an SRAM cell which is implemented with eight transistors capable of improving read and write performance without increasing the area as compared to an SRAM cell which is implemented with six transistors.

### BRIEF DESCRIPTION OF THE DRAWINGS

FIG. 1 is a view schematically illustrating a memory cell array of a semiconductor device according to an exemplary embodiment.

FIG. 2 is an equivalent circuit diagram of a memory cell of the semiconductor device according to the exemplary embodiment.

FIGS. 3 to 5 are plan layout diagrams of a memory cell of the semiconductor device according to the exemplary embodiment.

FIG. 6 is a cross-sectional view taken along line A-A′ of FIGS. 3 to 5.

FIG. 7 is a cross-sectional view taken along line B-B′ of FIGS. 3 to 5.

FIG. 8 is a cross-sectional view taken along line C-C′ of FIGS. 3 to 5.

FIG. 9 is a cross-sectional view taken along line D-D′ of FIGS. 3 to 5.

FIG. 10 is a view schematically illustrating a plurality of memory cells of the semiconductor device according to the exemplary embodiment.

FIG. 11 is an equivalent circuit diagram of a memory cell of the semiconductor device according to the exemplary embodiment.

FIGS. 12 to 14 are plan layout diagrams of a memory cell of the semiconductor device according to the exemplary embodiment.

FIG. 15 is a cross-sectional view taken along line A-A′ of FIGS. 12 to 14.

FIG. 16 is a cross-sectional view taken along line B-B′ of FIGS. 12 to 14.

FIG. 17 is a cross-sectional view taken along line C-C′ of FIGS. 12 to 14.

FIG. 18 is a cross-sectional view taken along line D-D′ of FIGS. 12 to 14.

FIG. 19 is a cross-sectional view taken along line E-E′ of FIGS. 12 to 14.

FIG. 20 is a view schematically illustrating a plurality of memory cells of the semiconductor device according to the exemplary embodiment.

FIG. 21 is an equivalent circuit diagram of a memory cell of a semiconductor device according to an exemplary embodiment.

FIGS. 22 to 24 are plan layout diagrams of a memory cell of the semiconductor device according to the exemplary embodiment.

FIG. 25 is a cross-sectional view taken along line A-A′ of FIGS. 22 to 24.

FIG. 26 is a cross-sectional view taken along line B-B′ of FIGS. 22 to 24.

FIG. 27 is a cross-sectional view taken along line C-C′ of FIGS. 22 to 24.

FIG. 28 is a cross-sectional view taken along line D-D′ of FIGS. 22 to 24.

FIG. 29 is a cross-sectional view taken along line E-E′ of FIGS. 22 to 24.

FIG. 30 is a view schematically illustrating a plurality of memory cells of the semiconductor device according to the exemplary embodiment.

FIG. 31 is a view schematically illustrating a memory cell array of a semiconductor device according to an exemplary embodiment.

FIGS. 32 to 34 are plan layout diagrams of a memory cell of the semiconductor device according to the exemplary embodiment.

FIG. 35 is a cross-sectional view taken along line A-A′ of FIGS. 32 to 34.

FIG. 36 is a cross-sectional view taken along line B-B′ of FIGS. 32 to 34.

FIG. 37 is a cross-sectional view taken along line C-C′ of FIGS. 32 to 34.

FIG. 38 is a cross-sectional view taken along line D-D′ of FIGS. 32 to 34.

FIG. 39 is a cross-sectional view taken along line E-E′ of FIGS. 32 to 34.

FIG. 40 is a cross-sectional view taken along line F-F′ of FIGS. 32 to 34.

FIG. 41 is a view schematically illustrating a plurality of memory cells of the semiconductor device according to the exemplary embodiment.

FIGS. 42 to 44 are plan layout diagrams of a memory cell of the semiconductor device according to the exemplary embodiment.

FIG. 45 is a cross-sectional view taken along line A-A′ of FIGS. 42 to 44.

FIG. 46 is a cross-sectional view taken along line B-B′ of FIGS. 42 to 44.

FIG. 47 is a cross-sectional view taken along line C-C′ of FIGS. 42 to 44.

FIG. 48 is a cross-sectional view taken along line D-D′ of FIGS. 42 to 44.

FIG. 49 is a cross-sectional view taken along line E-E′ of FIGS. 42 to 44.

FIG. 50 is a cross-sectional view taken along line F-F′ of FIGS. 42 to 44.

FIG. 51 is a view schematically illustrating a plurality of memory cells of the semiconductor device according to the exemplary embodiment.

FIGS. 52 to 54 are plan layout diagrams of a memory cell of the semiconductor device according to the exemplary embodiment.

FIG. 55 is a cross-sectional view taken along line A-A′ of FIGS. 52 to 54.

FIG. 56 is a cross-sectional view taken along line B-B′ of FIGS. 52 to 54.

FIG. 57 is a cross-sectional view taken along line C-C′ of FIGS. 52 to 54.

FIG. 58 is a cross-sectional view taken along line D-D′ of FIGS. 52 to 54.

FIG. 59 is a cross-sectional view taken along line E-E′ of FIGS. 52 to 54.

FIG. 60 is a cross-sectional view taken along line F-F′ of FIGS. 52 to 54.

FIG. 61 is a view schematically illustrating a plurality of memory cells of the semiconductor device according to the exemplary embodiment.

### DETAILED DESCRIPTION OF THE EMBODIMENTS

In the following detailed description, only certain exemplary embodiments have been shown and described, simply by way of illustration. The present invention can be variously implemented and is not limited to the following exemplary embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not necessarily limited thereto. In the drawings, the thickness of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

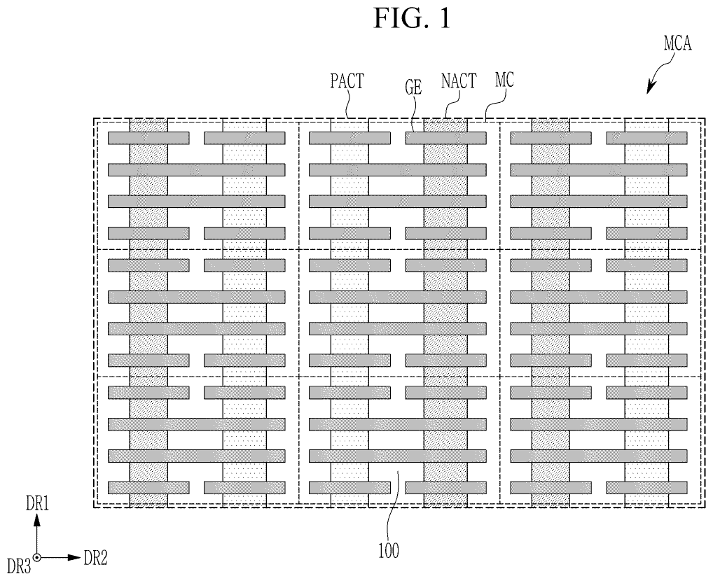

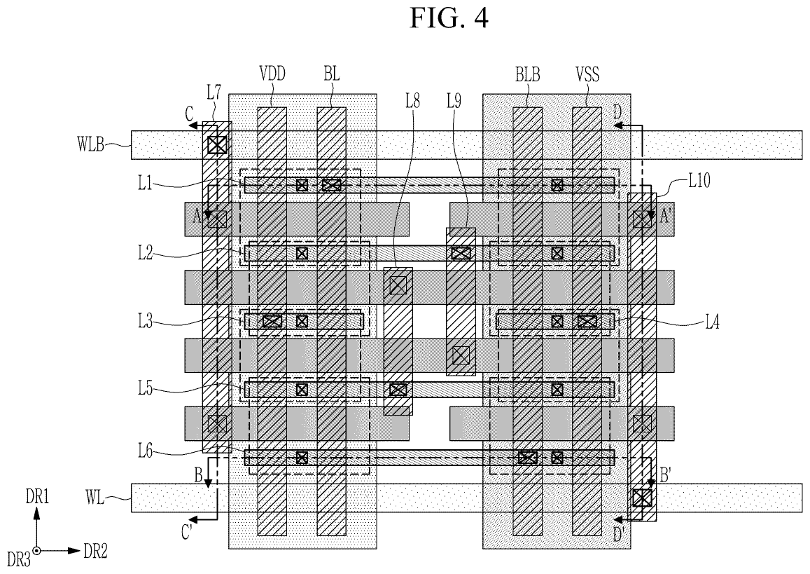

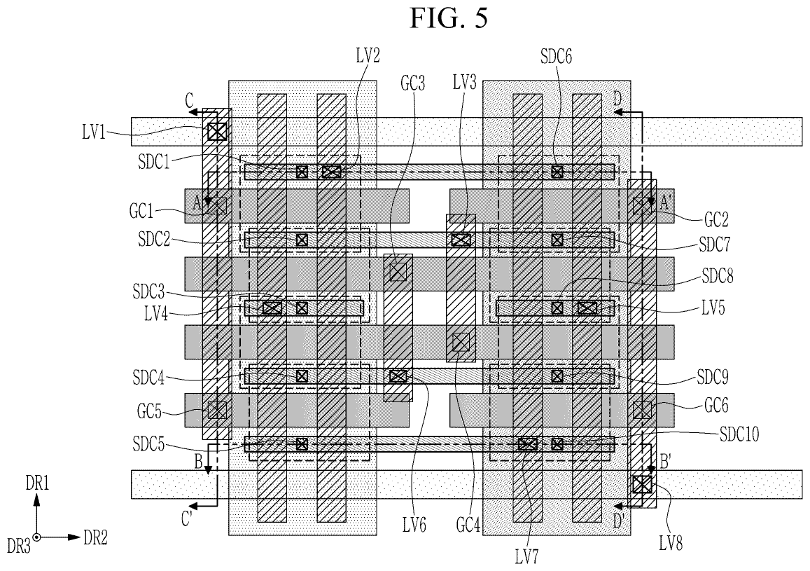

Hereinafter, a semiconductor device according to an exemplary embodiment will be described with reference to FIGS. 1 to 10.

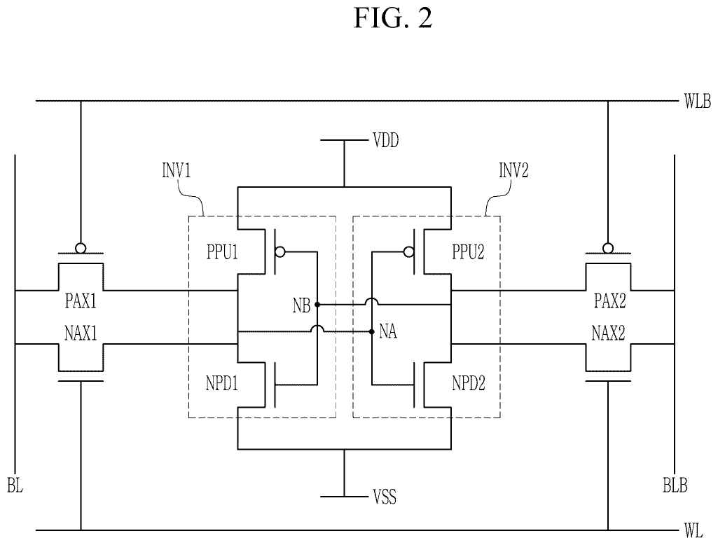

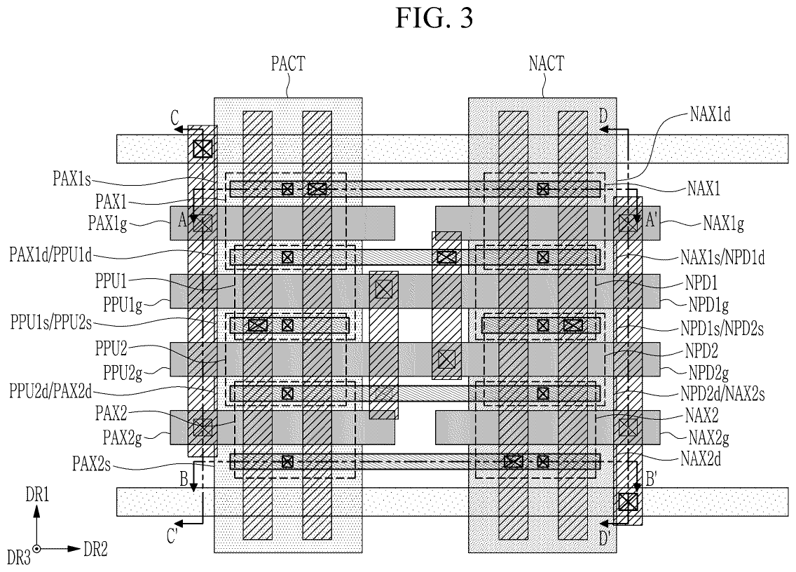

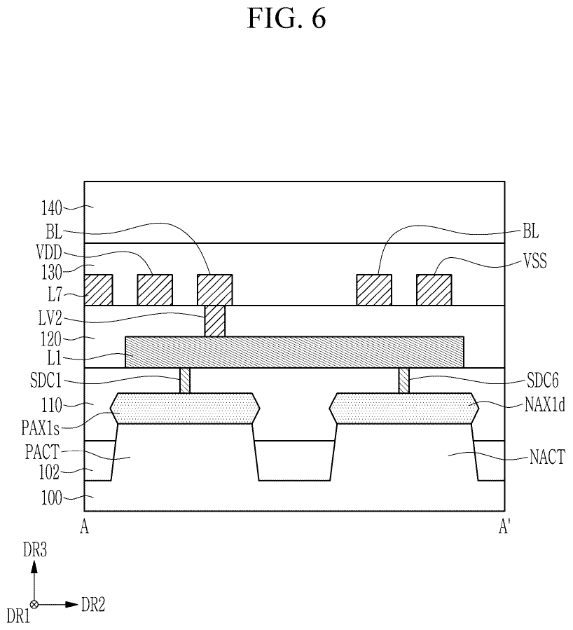

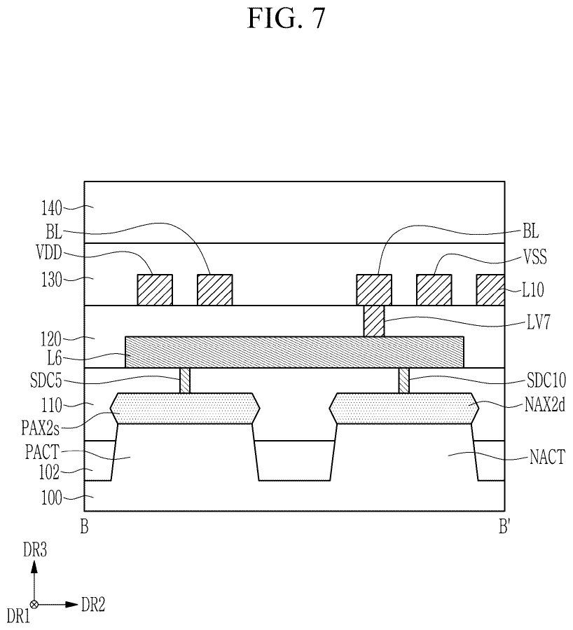

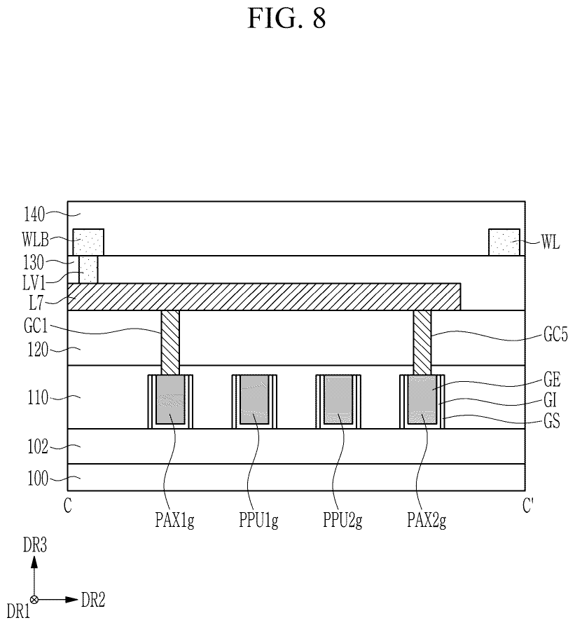

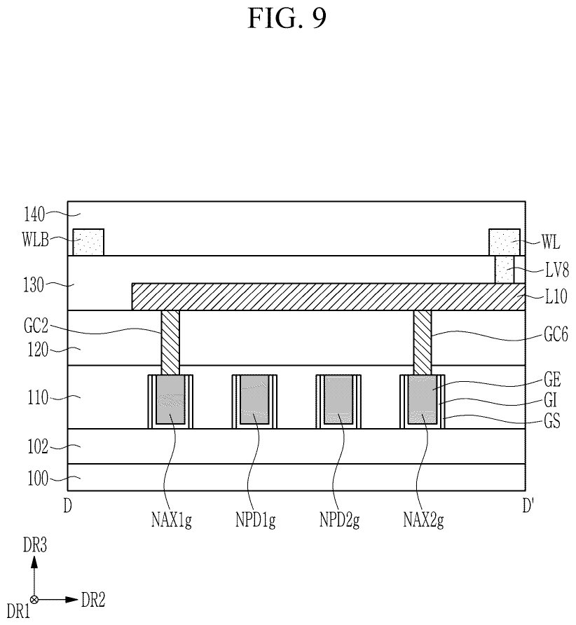

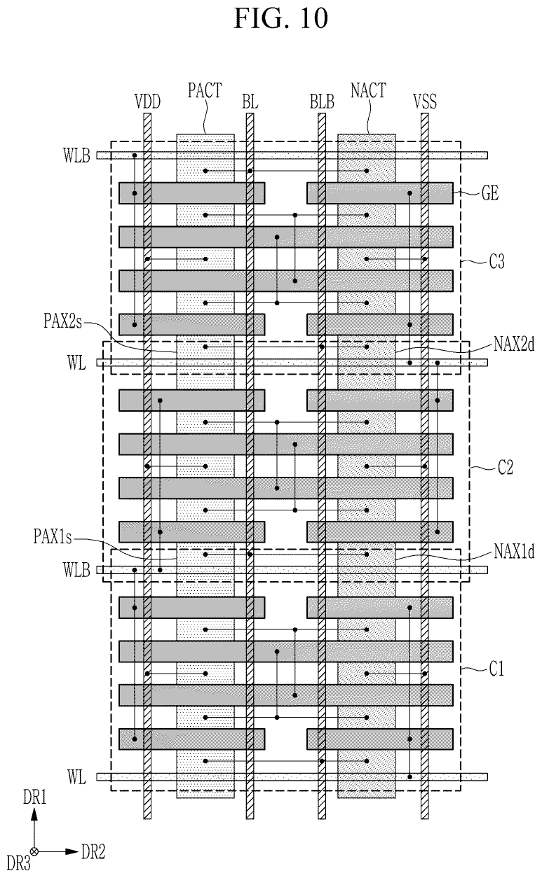

FIG. 1 is a view schematically illustrating a memory cell array of a semiconductor device according to an exemplary embodiment. FIG. 2 is an equivalent circuit diagram of a memory cell of the semiconductor device according to the exemplary embodiment. FIGS. 3 to 5 are plan layout diagrams of a memory cell of the semiconductor device according to the exemplary embodiment. FIG. 6 is a cross-sectional view taken along line A-A′ of FIGS. 3 to 5. FIG. 7 is a cross-sectional view taken along line B-B′ of FIGS. 3 to 5. FIG. 8 is a cross-sectional view taken along line C-C′ of FIGS. 3 to 5. FIG. 9 is a cross-sectional view taken along line D-D′ of FIGS. 3 to 5. FIG. 10 is a view schematically illustrating a plurality of memory cells of the semiconductor device according to the exemplary embodiment.

Referring to FIG. 1, a semiconductor device may include a substrate 100, and a memory cell array MCA including a plurality of memory cells MC on the substrate 100. The substrate 100 may include a first active region PACT where a transistor of a first conductivity type is disposed, and a second active region NACT where a transistor of a second conductivity type is disposed. The first active region PACT and the second active region NACT may be portions of the substrate 100.

In an exemplary embodiment, the first conductivity type may be a p-type, and the second conductivity type may be an n-type. A portion of the first active region PACT may contain a p-type impurity and the region containing the p-type impurity may be provided as a source region or a drain region to be described below. A portion of the second active region NACT may contain an n-type impurity, and the region containing the n-type impurity may be provided as a source region or a drain region to be described below.

The first active region PACT and the second active region NACT may extend in a first direction DR1 parallel with the upper surface of the substrate 100. The first active region PACT and the second active region NACT may be disposed so as to be parallel with the upper surface of the substrate 100 and be spaced apart in a second direction DR2 perpendicular to the first direction DR1.

The substrate 100 may include a plurality of first active regions PACT and a plurality of second active regions NACT. The plurality of first active regions PACT may be disposed two by two such that two are adjacent to each other. The plurality of second active regions NACT may be disposed two by two such that two are adjacent to each other. Two first active regions PACT and two second active regions NACT may be alternately disposed.

The semiconductor device may include gate electrodes GE which extend the second direction DR2 while crossing the first active region PACT and the second active region NACT. The gate electrodes GE may include a first gate electrode that crosses the first active region PACT, a second gate electrode that crosses the second active region NACT, and a third gate electrode that crosses the first active region PACT and the second active region NACT.

According to an exemplary embodiment, a plurality of memory cells MC may be disposed in an array form along the first direction DR1 and the second direction DR2. Each of the plurality of memory cells MC may be disposed on the first active region PACT and the second active region NACT. A plurality of memory cells MC which is disposed along the first direction DR1 may be disposed on the same first active region PACT and the same second active region NACT. A plurality of memory cells MC which is disposed along the second direction DR2 may be disposed on different first active regions PACT and different second active regions NACT.

According to an exemplary embodiment, each of the plurality of memory cells MC may include two first gate electrodes that cross a first active region PACT, two second gate electrodes that cross a second active region NACT, and two third gate electrodes that cross the first active region PACT and the second active region NACT. In this case, a first gate electrode and a second gate electrode may be disposed on the same extension line along the second direction DR2. Two third gate electrodes may be disposed between two first gate electrodes adjacent in the first direction DR1. Two third gate electrodes may be disposed two second gate electrodes adjacent in the first direction DR1.

On both sides of a gate electrode GE, a source region and a drain region may be provided, respectively. The gate electrode GE, and the source region and the drain electrode that are positioned on both sides of the gate electrode GE may constitute a transistor. For example, in the first active region PACT on both sides of a gate electrode GE, a source region and a drain region doped with a p-type impurity may be provided. In the second active region NACT on both sides of a gate electrode GE, a source region and a drain region doped with an n-type impurity may be provided.

In an exemplary embodiment, each of the plurality of memory cells MC may include at least eight transistors. For example, each of the plurality of memory cells MC may include four transistors that are positioned on a first active region PACT, and four transistors that are positioned on a second active region NACT. According to an exemplary embodiment, a transistor that is positioned on a first active region PACT may be a p-type transistor, and a transistor that is positioned on a second active region NACT may be an n-type transistor. In other words, each of the plurality of memory cells MC may include four p-type transistors and four n-type transistors.

Hereinafter, a circuit which is configured by eight transistors of each of the plurality of memory cells MC will be described with reference to FIG. 2. According to an exemplary embodiment, each of the plurality of memory cells MC may be an SRAM cell consisting of eight transistors.

Referring to FIG. 2, each of the plurality of memory cells MC may pull-up transistor PPU2, a second pull-down transistor NPD2, a first pass gate transistor NAX1, a second pass gate transistor NAX2, a first additional transistor PAX1, and a second additional transistor PAX2.

The first pull-up transistor PPU1 and the second pull-up transistor PPU2 may be p-type transistors. The first pull-down transistor NPD1 and the second pull-down transistor NPD2 may be n-type transistors. According to an exemplary embodiment, the first pass gate transistor NAX1 and the second pass gate transistor NAX2 may be n-type transistors, and the first additional transistor PAX1 and the second additional transistor PAX2 may be p-type transistors.

The drain of the first pull-up transistor PPU1 and the drain of the first pull-down transistor NPD1 may be connected to a first node NA. The source of the first pull-up transistor PPU1 may be connected to a first power line VDD. The source of the first pull-down transistor NPD1 may be connected to a second power line VSS. A first power voltage may be applied to the first power line VDD, and a second power voltage different from the first power voltage may be applied to the second power line VSS. The second power voltage may be lower than the first power voltage, and may be connected, for example, to a ground. The gate of the first pull-up transistor PPU1 and the gate of the first pull-down transistor NPD1 may be electrically connected to each other, and may be connected a second node NB. The first pull-up transistor PPU1 and the first pull-down transistor NPD1 may constitute a first inverter INV1. The gate of the first pull-up transistor PPU1 and the gate of the first pull-down transistor NPD1 may correspond to the input terminal of the first inverter INV1, and the first node NA may correspond to the output terminal of the first inverter INV1.

The drain of the second pull-up transistor PPU2 and the drain of the second pull-down transistor NPD2 may be connected to the second node NB. The source of the second pull-up transistor PPU2 may be connected to the first power line VDD. The source of the second pull-down transistor NPD2 may be connected to the second power line VSS. The gate of the second pull-up transistor PPU2 and the gate of the second pull-down transistor NPD2 may be electrically connected to each other, and may be connected to the first node NA. The second pull-up transistor PPU2 and the second pull-down transistor NPD2 may constitute a second inverter INV2. The gate of the second pull-up transistor PPU2 and the gate of the second pull-down transistor NPD2 may correspond to the input terminal of the second inverter INV2, and the second node NB may correspond to the output terminal of the second inverter INV2.

The first inverter INV1 and the second inverter INV2 may be coupled to constitute a latch structure. In other words, the gate of the first pull-up transistor PPU1 and the gate of the first pull-down transistor NPD1 may be electrically connected, and the gate of the second pull-up transistor PPU2 and the gate of the second pull-down transistor NPD2 may be electrically connected to the first node NA.

The source of the first pass gate transistor NAX1 and the drain of the first additional transistor PAX1 may be connected to the first node NA, and the drain of the first pass gate transistor NAX1 and the source of the first additional transistor PAX1 may be connected to a bit line BL. The source of the second pass gate transistor NAX2 and the drain of the second additional transistor PAX2 may be connected to the second node NB, and the drain of the second pass gate transistor NAX2 and the source of the second additional transistor PAX2 may be connected to a complementary bit line BLB. The gate of the first pass gate transistor NAX1 and the gate of the second pass gate transistor NAX2 may be electrically connected to a word line WL. The gate of the first additional transistor PAX1 and the gate of the second additional transistor PAX2 may be electrically connected to a complementary word line WLB.

Accordingly, an SRAM cell including eight transistors according to an exemplary embodiment may be implemented.

Hereinafter, the arrangement and connection relationship of eight transistors constituting each of the plurality of memory cells MC will be described with reference to FIGS. 3 to 9.

Referring to FIGS. 3 to 9, an element isolation layer 102 may be disposed on the substrate 100. The first active region PACT and the second active region NACT may be defined by the element isolation layer 102. The substrate 100 may contain a semiconductor material such as silicon, germanium, or silicon-germanium. The element isolation layer 102 may contain an insulating material such as silicon oxide.

The first active region PACT and the second active region NACT may be portions of the substrate 100. The first active region PACT and the second active region NACT may extend in parallel with each other in the first direction DR1. A trench may be defined between the first active region PACT and the second active region NACT adjacent to each other, and the element isolation layer 102 may fill the trench. The upper portions of the first active region PACT and the second active region NACT may protrude to a higher level than the upper surface of the element isolation layer 102. Each of the upper portions of the first active region PACT and the second active region NACT may have a fin shape. In the upper portions of the first active region PACT and the second active region NACT, channels and source/drain regions may be provided. The source/drain regions of the first active region PACT may be p-type impurity regions. The source/drain regions of the second active region NACT may be n-type impurity regions. Each of the channels may be interposed between a pair of source/drain regions.

The source/drain regions may be formed by a selective epitaxial growth process. The upper surfaces of the source/drain regions may be positioned at a higher level than the upper surfaces of the channels. The source/drain regions may contain a semiconductor element identical to or different from that of the substrate 100. The source/drain regions of the first active region PACT may contain a semiconductor element having a lattice constant larger than the lattice constant of the semiconductor element of the substrate 100. Accordingly, the source/drain regions of the first active region PACT may provide compressive stress to the channels. For example, the source/drain regions of the first active region PACT may contain silicon-germanium (SiGe). The source/drain regions of the second active region NACT may contain a semiconductor element identical to the semiconductor element of the substrate 100. For example, the source/drain regions of the second active region NACT may contain silicon (Si).

Gate electrodes GE which extend in the second direction DR2 while crossing the first active region PACT and the second active region NACT may be provided. For example, the second direction DR2 may be a direction perpendicular to the first direction DR1. The gate electrodes GE may overlap the channels of the first active region PACT and the channels of the second active region NACT in a third direction DR3. The third direction DR3 may be a direction perpendicular to the upper surface of the substrate 100. As an example, the gate electrodes GE may contain at least one of conductive metal nitrides (e.g., titanium nitride or tantalum nitride) and metal materials (e.g., titanium, tantalum, tungsten, copper, or aluminum).

On both side surfaces of each of the gate electrodes GE, a pair of gate spacers GS may be disposed. The gate spacers GS may extend in the second direction DR2 along the gate electrodes GE. For example, the gate spacers GS may contain at least one of SiO₂, SiCN, SiCON, and SIN. As another example, the gate spacers GS may consist of multiple layers formed of at least two of SiO₂, SiCN, SiCON, and SiN.

Between the gate electrodes GE, and the first active region PACT and second active region NACT, gate insulating patterns GI may be interposed. The gate insulating patterns GI may extend along the bottom surfaces of the gate electrodes GE, respectively. The gate insulating patterns GI may cover the upper surface and both side walls of each of the first active region PACT and the second active region NACT. For example, the gate insulating patterns GI may contain silicon oxide, silicon nitride, silicon oxynitride, or a high-dielectric constant material. The high-dielectric constant material may be a material having a higher dielectric constant than silicon oxide. As an example, the high-dielectric constant material may contain at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

According to an exemplary embodiment, the first pull-up transistor PPU1, the second pull-up transistor PPU2, the first additional transistor PAX1, and the second additional transistor PAX2 may be positioned on the first active region PACT, and the first pull-down transistor NPD1, the second pull-down transistor NPD2, the first pass gate transistor NAX1, and the second pass gate transistor NAX2 may be positioned on the second active region NACT.

The first pull-up transistor PPU1 and the second pull-up transistor PPU2 may be disposed adjacent in the first direction DR1. The first additional transistor PAX1 and the second additional transistor PAX2 may be positioned on both sides of the first pull-up transistor PPU1 and the second pull-up transistor PPU2. The first pull-up transistor PPU1 and the second pull-up transistor PPU2 may be positioned between the first additional transistor PAX1 and the second additional transistor PAX2. For example, the first additional transistor PAX1, the first pull-up transistor PPU1, the second pull-up transistor PPU2, and the second additional transistor PAX2 may be sequentially disposed along the first direction DR1; however, the present disclosure is not necessarily limited thereto. As another example, they may be disposed in the order of the first additional transistor PAX1, the second pull-up transistor PPU2, the first pull-up transistor PPU1, and the second additional transistor PAX2.

The first pull-down transistor NPD1 and the second pull-down transistor NPD2 may be disposed adjacent in the first direction DR1. The first pass gate transistor NAX1 and the second pass gate transistor NAX2 may be positioned on both sides of the first pull-down transistor NPD1 and the second pull-down transistor NPD2, respectively. The first pull-down transistor NPD1 and the second pull-down transistor NPD2 may be positioned between the first pass gate transistor NAX1 and the second pass gate transistor NAX2. For example, the first pass gate transistor NAX1, the first pull-down transistor NPD1, the second pull-down transistor NPD2, and the second pass gate transistor NAX2 may be sequentially disposed along the first direction DR1; however, the present disclosure is not necessarily limited thereto. As another example, they may be disposed in the order of the first pass gate transistor NAX1, the second pull-down transistor NPD2, the first pull-down transistor NPD1, and the second pass gate transistor NAX2.

The first pull-up transistor PPU1 and the first pull-down transistor NPD1 may be disposed so as to face each other in the second direction DR2. The second pull-up transistor PPU2 and the second pull-down transistor NPD2 may be disposed so as to face each other in the second direction DR2. The first additional transistor PAX1 and the first pass gate transistor NAX1 may be disposed so as to face each other in the second direction DR2. The second additional transistor PAX2 and the second pass gate transistor NAX2 may be disposed so as to face each other in the second direction DR2.

The gate electrode PPU1g of the first pull-up transistor PPU1 may be formed integrally with the gate electrode zNPD1g of the first pull-down transistor NPD1. The gate electrode PPU2g of the second pull-up transistor PPU2 may be formed integrally with the gate electrode NPD2g of the second pull-down transistor NPD2. The gate electrode PAX1g of the first additional transistor PAX1 and the gate electrode NAX1g of the first pass gate transistor NAX1 may be arranged in the second direction DR2. The gate electrode PAX2g of the second additional transistor PAX2 and the gate electrode NAX2g of the second pass gate transistor NAX2 may be arranged in the second direction DR2.

Between the gate electrode PAX1g of the first additional transistor PAX1 and the gate electrode NAX1g of the first pass gate transistor NAX1, an insulating pattern may be interposed. Between the gate electrode PAX2g of the second additional transistor PAX2 and the gate electrode NAX2g of the second pass gate transistor NAX2, an insulating pattern may be interposed. The insulating pattern may isolate the gate electrode PAX1g of the first additional transistor PAX1 and the gate electrode NAX1g of the first pass gate transistor NAX1. The insulating pattern may isolate the gate electrode PAX2g of the second additional transistor PAX2 and the gate electrode NAX2g of the second pass gate transistor NAX2.

In the first active region PACT on both sides of the gate electrode PAX1g of the first additional transistor PAX1, the source region PAX1s and drain region PAX1d of the first additional transistor PAX1 may be disposed. In the first active region PACT on both sides of the gate electrode PPU1g of the first pull-up transistor PPU1, the source region PPU1s and drain region PPU1d of the first pull-up transistor PPU1 may be disposed. In the first active region PACT on both sides of the gate electrode PPU2g of the second pull-up transistor PPU2, the source region PPU2s and drain region PPU2d of the second pull-up transistor PPU2 may be disposed. In the first active region PACT on both sides of the gate electrode PAX2g of the second additional transistor PAX2, the source region PAX2s and drain region PAX2d of the second additional transistor PAX2 may be disposed.

In the second active region NACT on both sides of the gate electrode NAX1g of the first pass gate transistor NAX1, the source region NAX1s and drain region NAX1d of the first pass gate transistor NAX1 may be disposed. In the second active region NACT on both sides of the gate electrode NPD1g of the first pull-down transistor NPD1, the source region NPD1s and drain region NPD1d of the first pull-down transistor NPD1 may be disposed. In the second active region NACT on both sides of the gate electrode NPD2g of the second pull-down transistor NPD2, the source region NPD2s and drain region NPD2d of the second pull-down transistor NPD2 may be disposed. In the second active region NACT on both sides of the gate electrode NAX2g of the second pass gate transistor NAX2, the source region NAX2s and drain region NAX2d of the second pass gate transistor NAX2 may be disposed.

Transistors which are positioned on the same active region and are adjacent in the first direction DR1 may share a source region or a drain region which is positioned between the gate electrodes of the individual transistors. For example, when a first transistor and a second transistor are positioned on a first active region so as to be adjacent in the first direction DR1, the source/drain region of the first transistor and the source/drain region of the second transistor which are positioned between the gate electrodes of the first transistor and the second transistor may be integrally formed. When a third transistor and a fourth transistor are positioned on a second active region so as to be adjacent in the first direction DR1, the source/drain region of the third transistor and the source/drain region of the fourth transistor which are positioned between the gate electrodes of the third transistor and the fourth transistor may be integrally formed.

The drain region PAX1d of the first additional transistor PAX1 and the drain region PPU1d of the first pull-up transistor PPU1 may be integrally formed. The source region PPU1s of the first pull-up transistor PPU1 and the source region PPU2s of the second pull-up transistor PPU2 may be integrally formed. The drain region PPU2d of the second pull-up transistor PPU2 and the drain region PAX2d of the second additional transistor PAX2 may be integrally formed.

The source region NAX1s of the first pass gate transistor NAX1 and the drain region NPD1d of the first pull-down transistor NPD1 may be integrally formed. The source region NPD1s of the first pull-down transistor NPD1 and the source region NPD2s of the second pull-down transistor NPD2 may be integrally formed. The drain region NPD2d of the second pull-down transistor NPD2 and the source region PAX2s of the second additional transistor PAX2 may be integrally formed.

A first interlayer insulating layer 110 may be positioned on the substrate 100. The first interlayer insulating layer 110 may cover the gate electrodes GE, the gate spacers GS, and the gate insulating patterns GI. The first interlayer insulating layer 110 may cover the source/drain regions of the first active region PACT and the source/drain regions of the second active region NACT. The first interlayer insulating layer 110 may cover the upper surface of the element isolation layer 102. The first interlayer insulating layer 110 may cover both side surfaces of each of the upper portions of the first active region PACT and the second active region NACT which are positioned at a higher level than the upper surface of the element isolation layer 102.

Source drain contacts SDC1, SDC2, SDC3, SDC4, SDC5, SDC6, SDC7, SDC8, SDC9, and SDC10 may pass through the first interlayer insulating layer 110 and be connected to the source/drain regions. On the first interlayer insulating layer 110, a second interlayer insulating layer 120 may be positioned. The upper surfaces of the source drain contacts SDC1, SDC2, SDC3, SDC4, SDC5, SDC6, SDC7, SDC8, SDC9, and SDC10 may be positioned substantially at the same level as that of the lower surface of the second interlayer insulating layer 120.

According to an exemplary embodiment, the source drain contacts SDC1, SDC2, SDC3, SDC4, SDC5, SDC6, SDC7, SDC8, SDC9, and SDC10 may be connected to a first wiring layer which is disposed inside the second interlayer insulating layer 120; however, the present disclosure is not necessarily limited thereto. For example, the first wiring layer may include first to sixth connection wiring lines L1, L2, L3, L4, L5, and L6. The first to sixth connection wiring lines L1, L2, L3, L4, L5, and L6 may be disposed so as to each extend in the second direction DR2 and be spaced apart in the first direction DR1. The first connection wiring line L1, the second connection wiring line L2, the third connection wiring line L3, the fifth connection wiring line L5, the sixth connection wiring line L6 may be sequentially disposed along the first direction DR1. The fourth connection wiring line L4 may be positioned substantially at the same position as that of the third connection wiring line L3 in the first direction DR1. The third connection wiring line L3 and the fourth connection wiring line L4 may be disposed on the same extension line along the second direction DR2.

The second interlayer insulating layer 120 may be positioned between the first to sixth connection wiring lines L1, L2, L3, L4, L5, and L6. The second interlayer insulating layer 120 may cover the upper surfaces and side surfaces of the first to sixth connection wiring lines L1, L2, L3, L4, L5, and L6. The lower surfaces of the first to sixth connection wiring lines L1, L2, L3, L4, L5, and L6 may be positioned substantially at the same level as the lower surface of the second interlayer insulating layer 120.

The first source drain contact SDC1 may be connected to the source region PAX1s of the first additional transistor PAX1. The sixth source drain contact SDC6 may be connected to the drain region NAX1d of the first pass gate transistor NAX1. The first source drain contact SDC1 and the sixth source drain contact SDC6 may be connected to the first connection wiring line L1. The source region PAX1s of the first additional transistor PAX1 and the drain region NAX1d of the first pass gate transistor NAX1 may be electrically connected by the first source drain contact SDC1, the sixth source drain contact SDC6, and the first connection wiring line L1.

The second source drain contact SDC2 may be connected to the drain region PAX1d of the first additional transistor PAX1 and the drain region PPU1d of the first pull-up transistor PPU1. The seventh source drain contact SDC7 may be connected to the source region NAX1s of the first pass gate transistor NAX1 and the drain region NPD1d of the first pull-down transistor NPD1. The second source drain contact SDC2 and the seventh source drain contact SDC7 may be connected to the second connection wiring line L2. The drain region PAX1d of the first additional transistor PAX1, the drain region PPU1d of the first pull-up transistor PPU1, the source region NAX1s of the first pass gate transistor NAX1, and the drain region NPD1d of the first pull-down transistor NPD1 may be electrically connected by the second source drain contact SDC2, the seventh source drain contact SDC7, and the second connection wiring line L2.

The third source drain contact SDC3 may be connected to the source region PPU1s of the first pull-up transistor PPU1 and the source region PPU2s of the second pull-up transistor PPU2. The third source drain contact SDC3 may be connected to the third connection wiring line L3.

The eighth source drain contact SDC8 may be connected to the source region NPD1s of the first pull-down transistor NPD1 and the source region NPD2s of the second pull-down transistor NPD2. The eighth source drain contact SDC8 may be connected to the fourth connection wiring line L4.

The fourth source drain contact SDC4 may be connected to the drain region PPU2d of the second pull-up transistor PPU2 and the drain region PAX2d of the second additional transistor PAX2. The ninth source drain contact SDC9 may be connected to the drain region NPD2d of the second pull-down transistor NPD2 and the source region NAX2s of the second pass gate transistor NAX2. The fourth source drain contact SDC4 and the ninth source drain contact SDC9 may be connected to the fifth connection wiring line L5. The drain region PPU2d of the second pull-up transistor PPU2, the drain region PAX2d of the second additional transistor PAX2, the drain region NPD2d of the second pull-down transistor NPD2, and the source region NAX2s of the second pass gate transistor NAX2 may be electrically connected by the fourth source drain contact SDC4, the ninth source drain contact SDC9, and the fifth connection wiring line L5.

The fifth source drain contact SDC5 may be connected to the source region PAX2s of the second additional transistor PAX2. The tenth source drain contact SDC10 may be connected to the drain region NAX2d of the second pass gate transistor NAX2. The fifth source drain contact SDC5 and the tenth source drain contact SDC10 may be connected to the sixth connection wiring line L6. The source region PAX2s of the second additional transistor PAX2 and the drain region NAX2d of the second pass gate transistor NAX2 may be electrically connected by the fifth source drain contact SDC5, the tenth source drain contact SDC10, and the sixth connection wiring line L6.

Gate contacts GC1, GC2, GC3, GC4, GC5, and GC6 may pass through the second interlayer insulating layer 120 and the first interlayer insulating layer 110 and be connected to the gate electrodes GE. A third interlayer insulating layer 130 may be positioned on the second interlayer insulating layer 120. The upper surfaces of the gate contacts GC1, GC2, GC3, GC4, GC5, and GC6 may be positioned substantially at the same level as that of the lower surface of the third interlayer insulating layer 130.

According to an exemplary embodiment, the gate contacts GC1, GC2, GC3, GC4, GC5, and GC6 may be connected to a second wiring layer which is disposed inside the third interlayer insulating layer 130; however, the present disclosure is not necessarily limited thereto. For example, the second wiring layer may include seventh to tenth connection wiring lines L7, L8, L9, and L10, the bit line BL, the complementary bit line BLB, the first power line VDD, and the second power line VSS. The seventh to tenth connection wiring lines L7, L8, L9, and L10, the bit line BL, the complementary bit line BLB, the first power line VDD, and the second power line VSS may be disposed so as to each extend in the first direction DR1 and be spaced apart in the second direction DR2. For example, the seventh connection wiring line L7, the first power line VDD, the bit line BL, the eighth connection wiring line L8, the ninth connection wiring line L9, the complementary bit line BLB, the second power line VSS, and the tenth connection wiring line L10 may be sequentially disposed along the second direction DR2; however, the exemplary embodiment is not necessarily limited thereto. The arrangement order of the wiring lines in the second wiring layer may be variously changed.

The third interlayer insulating layer 130 may be positioned between the seventh to tenth connection wiring lines L7, L8, L9, and L10, the bit line BL, the complementary bit line BLB, the first power line VDD, and the second power line VSS. The third interlayer insulating layer 130 may cover the upper surfaces and side surfaces of the seventh to tenth connection wiring lines L7, L8, L9, and L10), the bit line BL, the complementary bit line BLB, the first power line VDD, and the second power line VSS. The lower surfaces of the seventh to tenth connection wiring lines L7, L8, L9, and L10, the bit line BL, the complementary bit line BLB, the first power line VDD, and the second power line VSS may be positioned substantially at the same level as that of the lower surface of the third interlayer insulating layer 130.

In an exemplary embodiment, the seventh to tenth connection wiring lines L7, L8, L9, and L10, the bit line BL, the complementary bit line BLB, the first power line VDD, and the second power line VSS may be positioned in the same layer; however, the exemplary embodiment is not limited thereto. At least some of the seventh to tenth connection wiring lines L7, L8, L9, and L10, the bit line BL, the complementary bit line BLB, the first power line VDD, and the second power line VSS may be positioned in different layers. For example, the seventh to tenth connection wiring lines L7, L8, L9, and L10 may be positioned in a layer different from that of the bit line BL, the complementary bit line BLB, the first power line VDD, and the second power line VSS. As another example, the first power line VDD and the second power line VSS may be positioned in a layer different from that of the bit line BL and the complementary bit line BLB.

The first gate contact GC1 may be connected to the gate electrode PAX1g of the first additional transistor PAX1. The fifth gate contact GC5 may be connected to the gate electrode PAX2g of the second additional transistor PAX2. The seventh connection wiring line L7 may be connected to the first gate contact GC1 and the fifth gate contact GC5. The gate electrode PAX1g of the first additional transistor PAX1 and the gate electrode PAX2g of the second additional transistor PAX2 may be electrically connected by the first gate contact GC1, the fifth gate contact GC5, and the seventh connection wiring line L7.

The second gate contact GC2 may be connected to the gate electrode NAX1g of the first pass gate transistor NAX1. The sixth gate contact GC6 may be connected to the gate electrode NAX2g of the second pass gate transistor NAX2. The second gate contact GC2 and the sixth gate contact GC6 may be connected to the tenth connection wiring line L10. The gate electrode NAX1g of the first pass gate transistor NAX1 and the gate electrode NAX2g of the second pass gate transistor NAX2 may be electrically connected by the second gate contact GC2, the sixth gate contact GC6, and the tenth connection wiring line L10.

The third gate contact GC3 may be connected to the gate electrode PPU1g of the first pull-up transistor PPU1 and the gate electrode NPD1g of the first pull-down transistor NPD1. The third gate contact GC3 may be connected to the eighth connection wiring line L8.

The fourth gate contact GC4 may be connected to the gate electrode PPU2g of the second pull-up transistor PPU2 and the gate electrode NPD2g of the second pull-down transistor NPD2. The fourth gate contact GC4 may be connected to the ninth connection wiring line L9.

On the third interlayer insulating layer 130, a fourth interlayer insulating layer 140 may be positioned. Inside the fourth interlayer insulating layer 140, a third wiring layer may be disposed. The third wiring layer may include the word line WL and the complementary word line WLB

The word line WL and the complementary word line WLB may be disposed so as to each extend in the second direction DR2 and be spaced apart in the first direction DR1. For example, the word line WL and the complementary word line WLB may be positioned at the edge of the memory cell; however, the exemplary embodiment is not necessarily limited thereto.

The fourth interlayer insulating layer 140 may be positioned between the word line WL and the complementary word line WLB. The fourth interlayer insulating layer 140 may cover the upper surfaces and side surfaces of the word line WL and the complementary word line WLB. The lower surfaces of the word line WL and the complementary word line WLB may be positioned substantially at the same level as that of the lower surface of the fourth interlayer insulating layer 140.

In an exemplary embodiment, the word line WL and the complementary word line WLB may be positioned in a higher layer (a wiring layer farther from the upper surface of the substrate 100) than the bit line BL and the complementary bit line BLB; however, the exemplary embodiment is not limited thereto. The bit line BL and the complementary bit line BLB may be positioned in a higher layer than the word line WL and the complementary word line WLB.

Vias LV1, LV2, LV3, LV4, LV5, LV6, LV7, and LV8 may connect the first wiring layer, the second wiring layer, and the third wiring layer. The first via LV1 and the eighth via LV8 may pass through the third interlayer insulating layer 130 and connect the second wiring layer and the third wiring layer. The second to seventh vias LV2, LV3, LV4, LV5, LV6, and LV7 may pass through the second interlayer insulating layer 120 and connect the first wiring layer and the second wiring layer.

The first via LV1 may connect the complementary word line WLB and the seventh connection wiring line L7. In other words, the gate electrode PAX1g of the first additional transistor PAX1 and the gate electrode PAX2g of the second additional transistor PAX2 may be electrically connected to the complementary word line WLB by the first gate contact GC1, the fifth gate contact GC5, the seventh connection wiring line L7, and the first via LV1.

The eighth via LV8 may connect the word line WL and the tenth connection wiring line L10. In other words, the gate electrode NAX1g of the first pass gate transistor NAX1 and the gate electrode NAX2g of the second pass gate transistor NAX2 may be electrically connected to the word line WL by the second gate contact GC2, the sixth gate contact GC6, the tenth connection wiring line L10, and the eighth via LV8.

The second via LV2 may connect the bit line BL and the first connection wiring line L1. In other words, the source region PAX1s of the first additional transistor PAX1 and the drain region NAX1d of the first pass gate transistor NAX1 may be electrically connected to the bit line BL by the first source drain contact SDC1, the sixth source drain contact SDC6, the first connection wiring line L1, and the second via LV2.

The seventh via LV7 may connect the complementary bit line BLB and the sixth connection wiring line L6. In other words, the source region PAX2s of the second additional transistor PAX2 and the drain region NAX2d of the second pass gate transistor NAX2 may be electrically connected to the complementary bit line BLB by the fifth source drain contact SDC5, the tenth source drain contact SDC10, the sixth connection wiring line L6, and the seventh via LV7.

The third via LV3 may connect the ninth connection wiring line L9 and the second connection wiring line L2. In other words, the drain region PAX1d of the first additional transistor PAX1, the drain region PPU1d of the first pull-up transistor PPU1, the source region NAX1s of the first pass gate transistor NAX1, and the drain region NPD1d of the first pull-down transistor NPD1 may be electrically connected to the gate electrode PPU2g of the second pull-up transistor PPU2 and the gate electrode NPD2g of the second pull-down transistor NPD2 by the second source drain contact SDC2, the seventh source drain contact SDC7, the second connection wiring line L2, the fourth gate contact GC4, the third via LV3, and the ninth connection wiring line L9.

The sixth via LV6 may connect the eighth connection wiring line L8 and the fifth connection wiring line L5. In other words, the drain region PAX2d of the second additional transistor PAX2, the drain region PPU2d of the second pull-up transistor PPU2, the source region NAX2s of the second pass gate transistor NAX2, and the drain region NPD2d of the second pull-down transistor NPD2 may be electrically connected to the gate electrode PPU1g of the first pull-up transistor PPU1 and the gate electrode NPD1g of the first pull-down transistor NPD1 by the first source drain contact SDC1, the ninth source drain contact SDC9, the fifth connection wiring line L5, the third gate contact GC3, the sixth via LV6, and the eighth connection wiring line L8.

The fourth via LV4 may connect the first power line VDD and the third connection wiring line L3. In other words, the source region PPU1s of the first pull-up transistor PPU1 and the source region PPU2s of the second pull-up transistor PPU2 may be electrically connected to the first power line VDD by the third source drain contact SDC3, the third connection wiring line L3, and the fourth via LV4.

The fifth via LV5 may connect the second power line VSS and the fourth connection wiring line L4. In other words, the source region NPD1s of the first pull-down transistor NPD1 and the source region NPD2s of the second pull-down transistor NPD2 may be electrically connected to the second power line VSS by the eighth source drain contact SDC8, the fourth connection wiring line L4, and the fifth via LV5.

The source drain contacts SDC1, SDC2, SDC3, SDC4, SDC5, SDC6, SDC7, SDC8, SDC9, and SDC10 and the gate contacts GC1, GC2, GC3, GC4, GC5, and GC6 may contain at least one of conductive metal nitrides (e.g., titanium nitride or tantalum nitride) and metal materials (e.g., titanium, tantalum, tungsten, copper, or aluminum), and may consist of a single layer or multiple layers.

The interlayer insulating layers 110, 120, 130, and 140 may contain silicon oxide.

The bit line BL, the complementary bit line BLB, the word line WL, the complementary word line WLB, the first power line VDD, the second power line VSS, the connection wiring lines L1, L2, L3, L4, L5, L6, L7, L8, L9, and L10, and the vias LV1, LV2, LV3, LV4, LV5, LV6, LV7, and LV8 may contain at least one of conductive metal nitrides and metal materials.

The semiconductor device according to the exemplary embodiment may include the first additional transistor PAX1 and the second additional transistor PAX2 that are disposed on both sides of the first pull-up transistor PPU1 and the second pull-up transistor PPU2 so as to face the first pass gate transistor NAX1 and the second pass gate transistor NAX2, respectively. A memory cell of the semiconductor device according to an exemplary embodiment may be an SRAM cell which consists of eight transistors by adding two pass gate transistors to an SRAM cell which is implemented with six transistors. Each of the first additional transistor PAX1 and the second additional transistor PAX2 of the semiconductor device according to the exemplary embodiment may serve as a pass gate transistor along with each of the first pass gate transistor NAX1 and the second pass gate transistor NAX2. According to the exemplary embodiment, it is possible to improve the read and write performance without increasing the area as compared to an SRAM cell which is implemented with six transistors.

Hereinafter, the relationship of a plurality of memory cells adjacent in the first direction DR1 of the semiconductor device accuracy of the exemplary embodiment will be described with reference to FIG. 10 together.

Referring to FIG. 10, the semiconductor device according to the exemplary embodiment may include a first memory cell C1, a second memory cell C2, and a third memory cell C3 which are disposed along the first direction DR1. The first memory cell C1, the second memory cell C2, and the third memory cell C3 may be disposed on a single first active region PACT and a single second active region NACT extending in the first direction DR1. In respect to each of the first memory cell C1, the second memory cell C2, and the third memory cell C3, the contents of the memory cell described above with reference to FIGS. 2 to 9 may be equally applied. Each of the first memory cell C1, the second memory cell C2, and the third memory cell C3 may include a first pull-up transistor PPU1, a first pull-down transistor NPD1, a second pull-up transistor PPU2, a second pull-down transistor NPD2, a first pass gate transistor NAX1, a second pass gate transistor NAX2, a first additional transistor PAX1, and a second additional transistor PAX2.

The first memory cell C1 may be adjacent to the second memory cell C2 in the first direction DR1, and the second memory cell C2 may be adjacent to the third memory cell C3 in the first direction DR1. According to the exemplary embodiment, transistors constituting a plurality of memory cells adjacent in the first direction DR1 may be symmetrically disposed. In other words, the transistors of the first memory cell C1 and the transistors of the second memory cell C2 may be symmetrically disposed, and the transistors of the second memory cell C2 and the transistors of the third memory cell C3 may be symmetrically disposed.

The transistors which are disposed at both ends of each memory cell in the first direction DR1 may share a source/drain region with a transistor which is included in another memory cell adjacent thereto in the first direction DR1 and performs the same function.

According to the exemplary embodiment, the first additional transistor PAX1 of the first memory cell C1 and the first additional transistor PAX1 of the second memory cell C2 may share a source region PAX1s. The second additional transistor PAX2 of the second memory cell C2 and the second additional transistor PAX2 of the third memory cell C3 may share a source region PAX2s.

According to the exemplary embodiment, the first pass gate transistor NAX1 of the first memory cell C1 and the first pass gate transistor NAX1 of the second memory cell C2 may share a drain region NAX1d. The second pass gate transistor NAX2 of the second memory cell C2 and the second pass gate transistor NAX2 of the third memory cell C3 may share a drain region NAX2d.

According to the exemplary embodiment, the source region PAX1s of the first additional transistor PAX1 and the drain region NAX1d of the first pass gate transistor NAX1 of each memory cell may be connected to the bit line BL. The source region PAX2s of the second additional transistor PAX2 and the drain region NAX2d of the second pass gate transistor NAX2 may be connected to the complementary bit line BLB.

The second memory cell C2 may share the connection relationship of the source region PAX1s of the first additional transistor PAX1 and the drain region NAX1d of the first pass gate transistor NAX1 with the first memory cell C1. In other words, the second memory cell C2 may share a source drain contact SDC1 that is connected to the source region PAX1s of the first additional transistor PAX1, a sixth source drain contact SDC6 that is connected to the drain region NAX1d of the first pass gate transistor NAX1, a first connection wiring line L1 that connects the first source drain contact SDC1 and the sixth source drain contact SDC6, and a second via LV2 that connects the first connection wiring line L1 and a bit line BL, with the first memory cell C1.

The second memory cell C2 may share the connection relationship of the source region PAX2s of the second additional transistor PAX2 and the drain region NAX2d of the second pass gate transistor NAX2 with the third memory cell C3. In other words, the second memory cell C2 may share a fifth source drain contact SDC5 that is connected to the source region PAX2s of the second additional transistor PAX2, a tenth source drain contact SDC10 that is connected to the drain region NAX2d of the second pass gate transistor NAX2, a sixth connection wiring line L6 that connects the fifth source drain contact SDC5 and the tenth source drain contact SDC10, and a seventh via LV7 that connects the sixth connection wiring line L6 and a complementary bit line BLB, with the third memory cell C3.

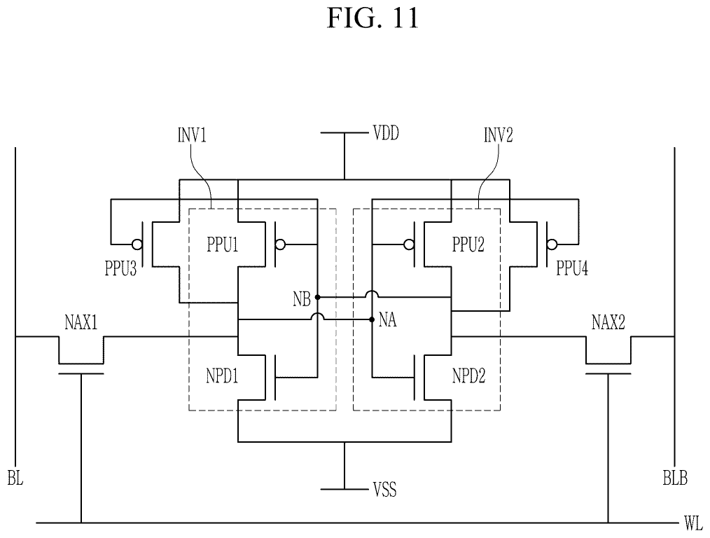

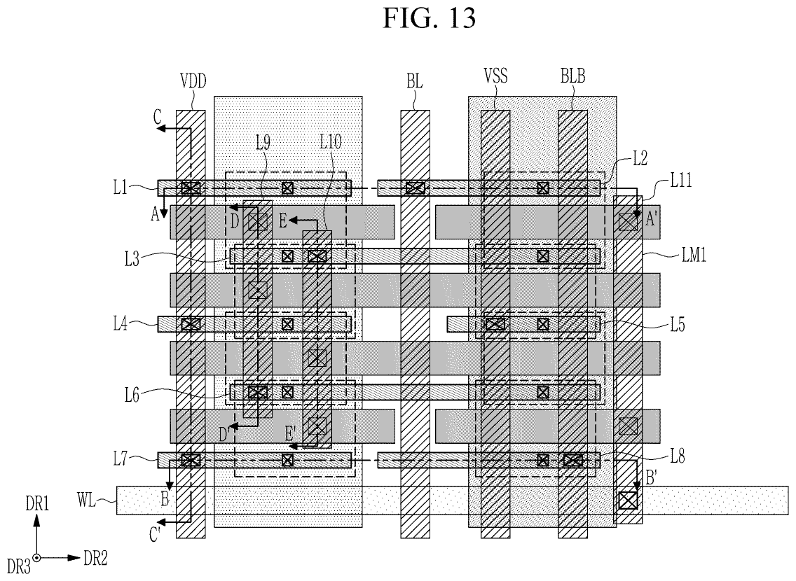

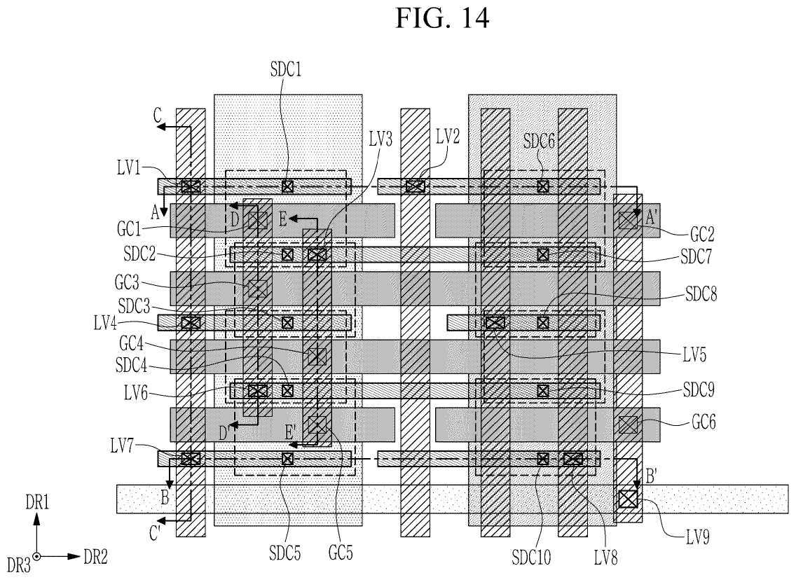

Hereinafter, a semiconductor device according to an exemplary embodiment will be described with reference to FIGS. 11 to 20. A memory cell array of the semiconductor device according to FIGS. 11 to 20 may be identical to that shown in FIG. 1.

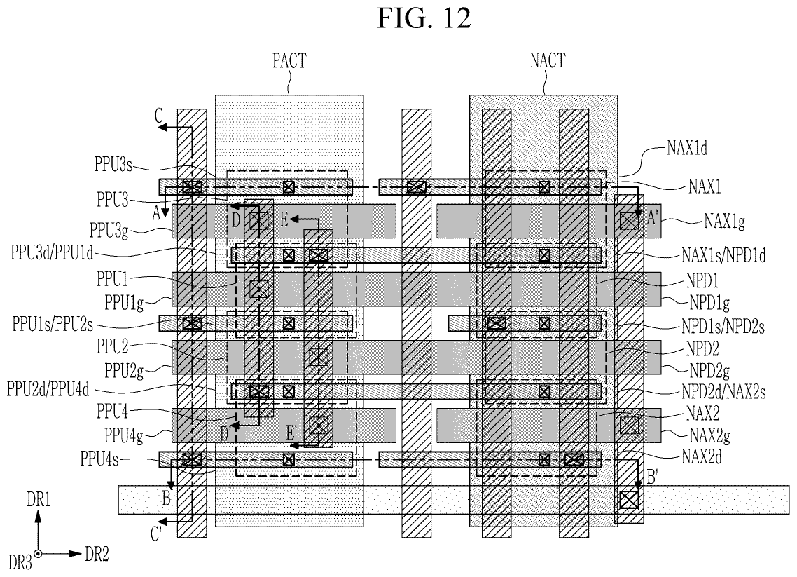

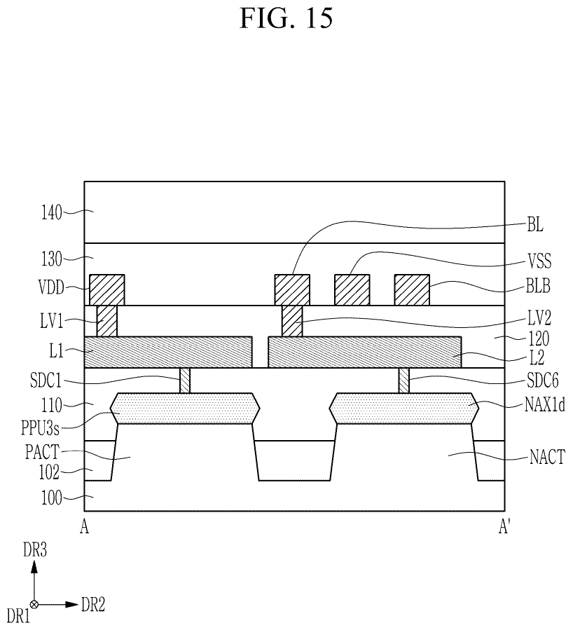

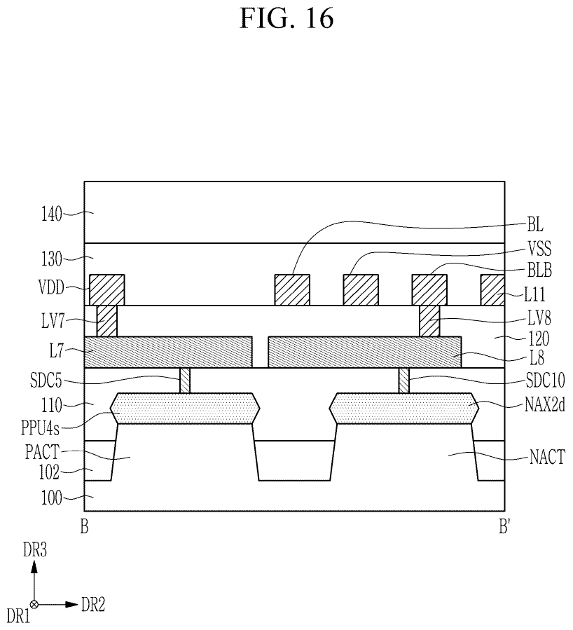

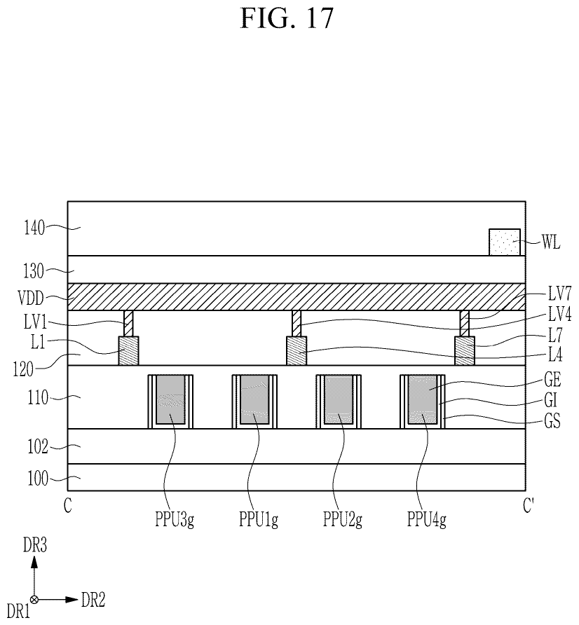

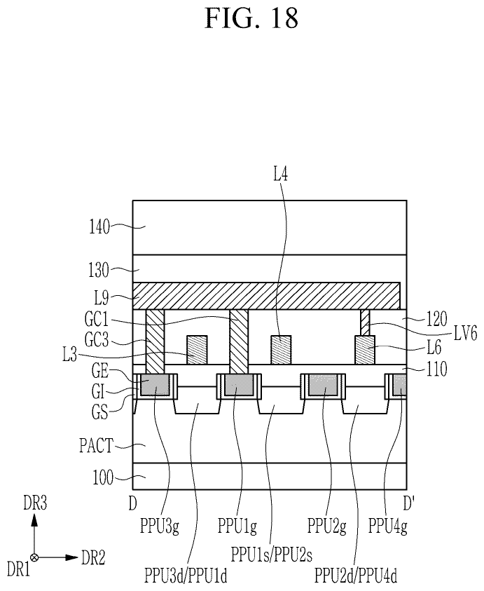

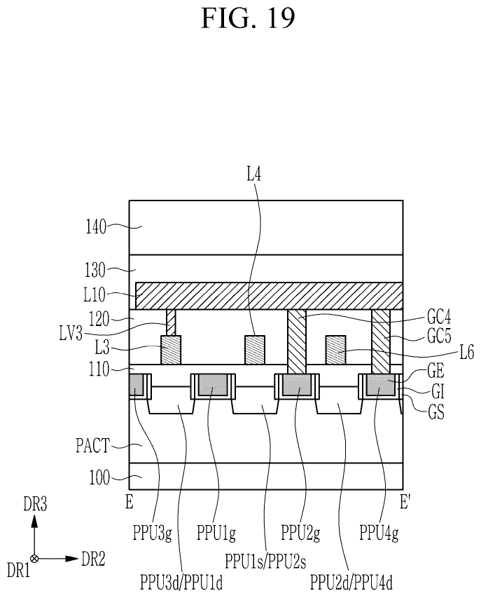

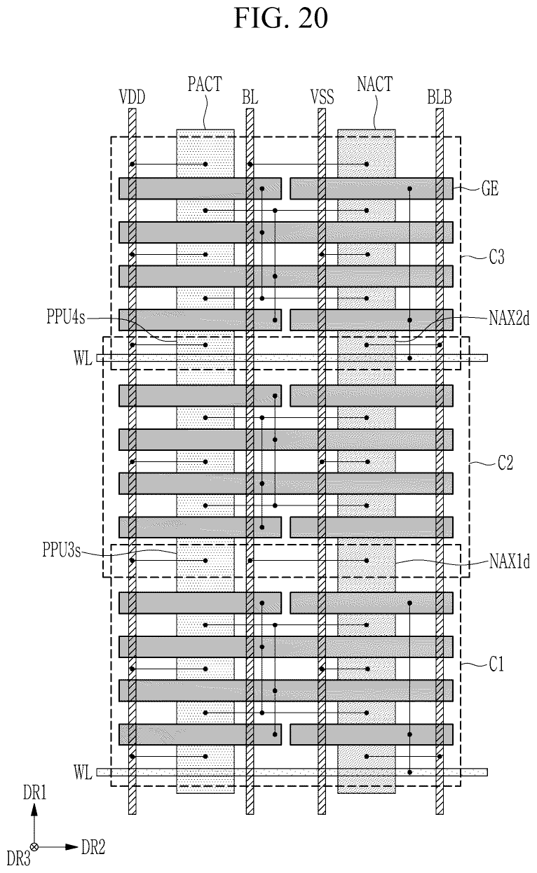

FIG. 11 is an equivalent circuit diagram of a memory cell of the semiconductor device according to the exemplary embodiment. FIGS. 12 to 14 are plan layout diagrams of a memory cell of the semiconductor device according to the exemplary embodiment. FIG. 15 is a cross-sectional view taken along line A-A′ of FIGS. 12 to 14. FIG. 16 is a cross-sectional view taken along line B-B′ of FIGS. 12 to 14. FIG. 17 is a cross-sectional view taken along line C-C′ of FIGS. 12 to 14. FIG. 18 is a cross-sectional view taken along line D-D′ of FIGS. 12 to 14. FIG. 19 is a cross-sectional view taken along line E-E′ of FIGS. 12 to 14. FIG. 20 is a view schematically illustrating a plurality of memory cells of the semiconductor device according to the exemplary embodiment.

Hereinafter, differences from the semiconductor device according to FIGS. 1 to 10 will be mainly described, and a redundant description will not be made or will be made in brief.

Referring to FIG. 11, a memory cell of the semiconductor device may include a first pull-up transistor PPU1, a first pull-down transistor NPD1, a second pull-up transistor PPU2, a second pull-down transistor NPD2, a first pass gate transistor NAX1, a second pass gate transistor NAX2, a first additional transistor PPU3, and a second additional transistor PPU4.

The first pull-up transistor PPU1 and the second pull-up transistor PPU2 may be p-type transistors. The first pull-down transistor NPD1 and the second pull-down transistor NPD2 may be n-type transistors. According to an exemplary embodiment, the first pass gate transistor NAX1 and the second pass gate transistor NAX2 may be n-type transistors, and the first additional transistor PPU3 and the second additional transistor PPU4 may be p-type transistors.

The drain of the first pull-up transistor PPU1 and the drain of the first additional transistor PPU3 may be connected to a first node NA, and the source of the first pull-up transistor PPU1 and the source of the first additional transistor PPU3 may be connected to the first power line VDD. The drain of the second pull-up transistor PPU2 and the drain of the second additional transistor PPU4 may be connected to a second node NB, and the source of the second pull-up transistor PPU2 and the source of the second additional transistor PPU4 may be connected to the first power line VDD. The gate of the first pull-up transistor PPU1 and the gate of the first additional transistor PPU3 may be connected to the second node NB. The gate of the second pull-up transistor PPU2 and the gate of the second additional transistor PPU4 may be connected to the first node NA.

Accordingly, an SRAM cell including eight transistors according to an exemplary embodiment may be implemented.

Hereinafter, the arrangement and connection relationship of eight transistors constituting the memory cell will be described with reference to FIGS. 12 to 19.

Referring to FIGS. 12 to 19, the arrangement of the first pull-up transistor PPU1, the first pull-down transistor NPD1, the second pull-up transistor PPU2, the second pull-down transistor NPD2, the first pass gate transistor NAX1, the second pass gate transistor NAX2, the first additional transistor PPU3, and the second additional transistor PPU4 may be identical to that in the exemplary embodiment of FIGS. 1 to 10.

The source drain contacts SDC1, SDC2, SDC3, SDC4, SDC5, SDC6, SDC7, SDC8, SDC9, and SDC10 may pass through the first interlayer insulating layer 110 and be connected to the source/drain regions. The source drain contacts SDC1, SDC2, SDC3, SDC4, SDC5, SDC6, SDC7, SDC8, SDC9, and SDC10 may be connected to a first wiring layer which is disposed inside the second interlayer insulating layer 120; however, the present disclosure is not necessarily limited thereto. For example, the first wiring layer may include first to eighth connection wiring lines L1, L2, L3, L4, L5, L6, L7, and L8. The first to eighth connection wiring lines L1, L2, L3, L4, L5, L6, L7, and L8 may be disposed so as to each extend in the second direction DR2 and be spaced apart in the first direction DR1. The first connection wiring line L1, the third connection wiring line L3, the fourth connection wiring line L4, the sixth connection wiring line L6, and the seventh connection wiring line L7 may be sequentially disposed along the first direction DR1. The second connection wiring line L2 may be positioned substantially at the same position as that of the first connection wiring line L1 in the first direction DR1. The first connection wiring line L1 and the second connection wiring line L2 may be disposed on the same extension line along the second direction DR2. The fifth connection wiring line L5 may be positioned substantially at the same position as that of the fourth connection wiring line L4 in the first direction DR1. The fourth connection wiring line L4 and the fifth connection wiring line L5 may be disposed on the same extension line along the second direction DR2. The eighth connection wiring line L8 may be positioned substantially at the same position as that of the seventh connection wiring line L7 in the first direction DR1. The seventh connection wiring line L7 and the eighth connection wiring line L8 may be disposed on the same extension line along the second direction DR2.

The first source drain contact SDC1 may be connected to the source region PPU3s of the first additional transistor PPU3. The first source drain contact SDC1 may be connected to the first connection wiring line L1.

The sixth source drain contact SDC6 may be connected to the drain region NAX1d of the first pass gate transistor NAX1. The sixth source drain contact SDC6 may be connected to the second connection wiring line L2.

The second source drain contact SDC2 may be connected to the drain region PPU3d of the first additional transistor PPU3 and the drain region PPU1d of the first pull-up transistor PPU1. The seventh source drain contact SDC7 may be connected to the source region NAX1s of the first pass gate transistor NAX1 and the drain region NPD1d of the first pull-down transistor NPD1. The second source drain contact SDC2 and the seventh source drain contact SDC7 may be connected to the third connection wiring line L3. The drain region PPU3d of the first additional transistor PPU3, the drain region PPU1d of the first pull-up transistor PPU1, the source region NAX1s of the first pass gate transistor NAX1, and the drain region NPD1d of the first pull-down transistor NPD1 may be electrically connected by the second source drain contact SDC2, the seventh source drain contact SDC7, and the third connection wiring line L3.

The third source drain contact SDC3 may be connected to the source region PPU1s of the first pull-up transistor PPU1 and the source region PPU2s of the second pull-up transistor PPU2. The third source drain contact SDC3 may be connected to the fourth connection wiring line L4.

The eighth source drain contact SDC8 may be connected to the source region NPD1s of the first pull-down transistor NPD1 and the source region NPD2s of the second pull-down transistor NPD2. The eighth source drain contact SDC8 may be connected to the fifth connection wiring line L5.

The fourth source drain contact SDC4 may be connected to the drain region PPU2d of the second pull-up transistor PPU2 and the drain region PPU4d of the second additional transistor PPU4. The ninth source drain contact SDC9 may be connected to the drain region NPD2d of the second pull-down transistor NPD2 and the source region NAX2s of the second pass gate transistor NAX2. The fourth source drain contact SDC4 and the ninth source drain contact SDC9 may be connected to the sixth connection wiring line L6. The drain region PPU2d of the second pull-up transistor PPU2, the drain region PPU4d of the second additional transistor PPU4, the drain region NPD2d of the second pull-down transistor NPD2, and the source region NAX2s of the second pass gate transistor NAX2 may be electrically connected by the fourth source drain contact SDC4, the ninth source drain contact SDC9, and the sixth connection wiring line L6.

The fifth source drain contact SDC5 may be connected to the source region PPU4s of the second additional transistor PPU4. The fifth source drain contact SDC5 may be connected to the seventh connection wiring line L7.

The tenth source drain contact SDC10 may be connected to the drain region NAX2d of the second pass gate transistor NAX2. The tenth source drain contact SDC10 may be connected to the eighth connection wiring line L8.

The gate contacts GC1, GC2, GC3, GC4, GC5, and GC6 may pass through the second interlayer insulating layer 120 and the first interlayer insulating layer 110 and be connected to the gate electrodes GE. The gate contacts GC1, GC2, GC3, GC4, GC5, and GC6 which are disposed inside the third interlayer insulating layer 130; however, the present disclosure is not necessarily limited thereto. For example, the second wiring layer may include ninth to eleventh connection wiring lines L9, L10, and L11, the bit line BL, the complementary bit line BLB, the first power line VDD, and the second power line VSS. The ninth to eleventh connection wiring lines L9, L10, and L11, the bit line BL, the complementary bit line BLB, the first power line VDD, and the second power line VSS may be disposed so as to each extend in the first direction DR1 and be spaced apart in the second direction DR2. For example, they may be disposed in the order of the first power line VDD, the ninth connection wiring line L9, the tenth connection wiring line L10, the bit line BL, the second power line VSS, the complementary bit line BLB, and the eleventh connection wiring line L11; however, the exemplary embodiment is not necessarily limited thereto. The arrangement order of the wiring lines in the second wiring layer may be variously changed.

The first gate contact GC1 may be connected to the gate electrode PPU3g of the first additional transistor PPU3. The third gate contact GC3 may be connected to the gate electrode PPU1g of the first pull-up transistor PPU1. The first gate contact GC1 and the third gate contact GC3 may be connected to the ninth connection wiring line L9. The gate electrode PPU3g of the first additional transistor PPU3 and the gate electrode PPU1g of the first pull-up transistor PPU1 may be electrically connected by the first gate contact GC1, the third gate contact GC3, and the ninth connection wiring line L9.

The fifth gate contact GC5 may be connected to the gate electrode PPU4g of the second additional transistor PPU4. The fourth gate contact GC4 may be connected to the gate electrode PPU2g of the second pull-up transistor PPU2. The fifth gate contact GC5 and the fourth gate contact GC4 may be connected to the tenth connection wiring line L10. The gate electrode PPU4g of the second additional transistor PPU4 and the gate electrode PPU2g of the second pull-up transistor PPU2 may be electrically connected by the fifth gate contact GC5, the fourth gate contact GC4, and the tenth connection wiring line L10.

The second gate contact GC2 may be connected to the gate electrode NAX1g of the first pass gate transistor NAX1. The sixth gate contact GC6 may be connected to the gate electrode NAX2g of the second pass gate transistor NAX2. The second gate contact GC2 and the sixth gate contact GC6 may be connected to the eleventh connection wiring line L11. The gate electrode NAX1g of the first pass gate transistor NAX1 and the gate electrode NAX2g of the second pass gate transistor NAX2 may be electrically connected by the second gate contact GC2, the sixth gate contact GC6, and the eleventh connection wiring line L11.

The third wiring layer which is disposed inside the fourth interlayer insulating layer 140 may include the word line WL. For example, the word line WL may be positioned at the edge of the memory cell; however, the exemplary embodiment is not limited thereto. Unlike in the exemplary embodiment of FIGS. 1 to 10, the complementary word line WLB may be omitted.

Vias LV1, LV2, LV3, LV4, LV5, LV6, LV7, LV8, and LV9 may connect the first wiring layer, the second wiring layer, and the third wiring layer. The ninth via LV9 may pass through the third interlayer insulating layer 130 and connect the second wiring layer and the third wiring layer. The first to eighth vias LV1, LV2, LV3, LV4, LV5, LV6, LV7, and LV8 may pass through the second interlayer insulating layer 120 and connect the first wiring layer and the second wiring layer.

The ninth via LV9 may connect the word line WL and the eleventh connection wiring line L11. In other words, the gate electrode NAX1g of the first pass gate transistor NAX1 and the gate electrode NAX2g of the second pass gate transistor NAX2 may be electrically connected to the word line WL by the second gate contact GC2, the sixth gate contact GC6, the eleventh connection wiring line L11, and the ninth via LV9.

The second via LV2 may connect the bit line BL and the second connection wiring line L2. In other words, the drain region NAX1d of the first pass gate transistor NAX1 may be electrically connected to the bit line BL by the sixth source drain contact SDC6, the second connection wiring line L2, and the second via LV2.

The eighth via LV8 may connect the complementary bit line BLB and the eighth connection wiring line L8. In other words, the drain region NAX2d of the second pass gate transistor NAX2 may be electrically connected to the bit line BL by the tenth source drain contact SDC10, the eighth connection wiring line L8, and the eighth via LV8.

The third via LV3 may connect the tenth connection wiring line L10 and the third connection wiring line L3. In other words, the drain region PPU3d of the first additional transistor PPU3, the drain region PPU1d of the first pull-up transistor PPU1, the source region NAX1s of the first pass gate transistor NAX1, and the drain region NPD1d of the first pull-down transistor NPD1 may be electrically connected to the gate electrode PPU2g of the second pull-up transistor PPU2, the gate electrode NPD2g of the second pull-down transistor NPD2, and the gate electrode PPU4g of the second additional transistor PPU4 by the second source drain contact SDC2, the seventh source drain contact SDC7, the third connection wiring line L3, the fourth gate contact GC4, the fifth gate contact GC5, the third via LV3, and the tenth connection wiring line L10.

The sixth via LV6 may connect the ninth connection wiring line L9 and the sixth connection wiring line L6. In other words, the drain region PPU4d of the second additional transistor PPU4, the drain region PPU2d of the second pull-up transistor PPU2, the drain region PPU4d of the second additional transistor PPU4, the source region NAX2s of the second pass gate transistor NAX2, and the drain region NPD2d of the second pull-down transistor NPD2 may be electrically connected to the gate electrode PPU1g of the first pull-up transistor PPU1, the gate electrode NPD1g of the first pull-down transistor NPD1, and the gate electrode PPU3g of the first additional transistor PPU3 by the fourth source drain contact SDC4, the ninth source drain contact SDC9, the sixth connection wiring line L6, the third gate contact GC3, the first gate contact GC1, the sixth via LV6, and the ninth connection wiring line L9.

The fifth via LV5 may connect the fifth connection wiring line L5 and the second power line VSS. In other words, the source region NPD1s of the first pull-down transistor NPD1 and the source region PPU2s of the second pull-up transistor PPU2 may be electrically connected to the second power line VSS by the eighth source drain contact SDC8, the fifth connection wiring line L5, and the fifth via LV5.

The fourth via LV4 may connect the fourth connection wiring line L4 and the first power line VDD. In other words, the source region PPU1s of the first pull-up transistor PPU1 and the source region PPU2s of the second pull-up transistor PPU2 may be electrically connected to the first power line VDD by the third source drain contact SDC3, the fourth connection wiring line L4, and the fourth via LV4.

The first via LV1 may connect the first connection wiring line L1 and the first power line VDD. In other words, the source region PPU3s of the first additional transistor PPU3 may be electrically connected to the first power line VDD by the first source drain contact SDC1, the first connection wiring line L1, and the first via LV1.

The seventh via LV7 may connect the seventh connection wiring line L7 and the first power line VDD. In other words, the source region PPU4s of the second additional transistor PPU4 may be electrically connected to the first power line VDD by the fifth source drain contact SDC5, the seventh connection wiring line L7, and the seventh via LV7.

Hereinafter, the relationship of a plurality of memory cells adjacent in the first direction DR1 of the semiconductor device accuracy of the exemplary embodiment will be described with reference to FIG. 20 together.

Referring to FIG. 20, the semiconductor device according to the exemplary embodiment may include a first memory cell C1, a second memory cell C2, and a third memory cell C3 which are disposed along the first direction DR1. In respect to each of the first memory cell C1, the second memory cell C2, and the third memory cell C3, the contents of the memory cell described above with reference to FIGS. 11 to 19 may be equally applied. Each of the first memory cell C1, the second memory cell C2, and the third memory cell C3 may include a first pull-up transistor PPU1, a first pull-down transistor NPD1, a second pull-up transistor PPU2, a second pull-down transistor NPD2, a first pass gate transistor NAX1, a second pass gate transistor NAX2, a first additional transistor PPU3, and a second additional transistor PPU4.

The transistors which are disposed at both ends of each memory cell in the first direction DR1 may share a source/drain region with a transistor which is included in another memory cell adjacent thereto in the first direction DR1 and performs the same function.

According to the exemplary embodiment, the first additional transistor PPU3 of the first memory cell C1 and the first additional transistor PPU3 of the second memory cell C2 may share a source region PPU3s. The second additional transistor PPU4 of the second memory cell C2 and the second additional transistor PPU4 of the third memory cell C3 may share a source region PPU4s.

According to the exemplary embodiment, the first pass gate transistor NAX1 of the first memory cell C1 and the first pass gate transistor NAX1 of the second memory cell C2 may share a drain region NAX1d. The second pass gate transistor NAX2 of the second memory cell C2 and the second pass gate transistor NAX2 of the third memory cell C3 may share a drain region NAX2d.

According to the exemplary embodiment, the source region PPU3s of the first additional transistor PPU3 of each memory cell may be connected to the first power line VDD, and the drain region NAX1d of the first pass gate transistor NAX1 may be connected to the bit line BL. The source region PPU4s of the second additional transistor PPU4 of each memory cell may be connected to the first power line VDD, and the drain region NAX2d of the second pass gate transistor NAX2 may be connected to the complementary bit line BLB.

The second memory cell C2 may share the connection relationship of the source region PPU3s of the first additional transistor PPU3 with the first memory cell C1. In other words, the second memory cell C2 may share the first source drain contact SDC1 that is connected to the source region PPU3s of the first additional transistor PPU3, the first connection wiring line L1 to which the first source drain contact SDC1 is connected, and the first via LV1 that connects the first connection wiring line L1 and the first power line VDD, with the first memory cell C1.

The second memory cell C2 may share the connection relationship of the drain region NAX1d of the first pass gate transistor NAX1 with the first memory cell C1. In other words, the second memory cell C2 may share the sixth source drain contact SDC6 that is connected to the drain region NAX1d of the first pass gate transistor NAX1, the second connection wiring line L2 to which the sixth source drain contact SDC6 is connected, and the second via LV2 that connects the second connection wiring line L2 and the bit line BL, with the first memory cell C1.

The second memory cell C2 may share the connection relationship of the source region PPU4s of the second additional transistor PPU4 with the third memory cell C3. In other words, the second memory cell C2 may share the fifth source drain contact SDC5 that is connected to the source region PPU4s of the second additional transistor PPU4, the seventh connection wiring line L7 to which the fifth source drain contact SDC5 is connected, and the seventh via LV7 that connects the seventh connection wiring line L7 and the first power line VDD, with the third memory cell C3.

The second memory cell C2 may share the connection relationship of the drain region NAX2d of the second pass gate transistor NAX2 with the third memory cell C3. In other words, the second memory cell C2 may share the tenth source drain contact SDC10 that is connected to the drain region NAX2d of the second pass gate transistor NAX2, the eighth connection wiring line L8 to which the tenth source drain contact SDC10 is connected, and the eighth via LV8 that connects the eighth connection wiring line L8 and the complementary bit line BLB, with the third memory cell C3.

The process of forming the transistors of the semiconductor device according to the exemplary embodiment of FIGS. 11 to 20 may be identical to the process of forming the transistors of the semiconductor device according to the exemplary embodiment of FIGS. 1 to 10. The semiconductor device according to the exemplary embodiment of FIGS. 11 to 20 may be formed by changing etch masks for forming contact holes, via holes, and wiring lines of the semiconductor device according to the exemplary embodiment of FIGS. 1 to 10.

The semiconductor device according to the exemplary embodiment may include the first additional transistor PPU3 and the second additional transistor PPU4 that are disposed on both sides of the first pull-up transistor PPU1 and the second pull-up transistor PPU2 so as to face the first pass gate transistor NAX1 and the second pass gate transistor NAX2, respectively. A memory cell of the semiconductor device according to an exemplary embodiment may be an SRAM cell which consists of eight transistors by adding two pull-up transistors to an SRAM cell which is implemented with six transistors. Each of the first additional transistor PPU3 and the second additional transistor PPU4 of the semiconductor device according to the exemplary embodiment may serve as a pull-up transistor along with each of the first pull-up transistor PPU1 and the second pull-up transistor PPU2. According to the exemplary embodiment, it is possible to improve the read and write performance without increasing the area as compared to an SRAM cell which is implemented with six transistors.

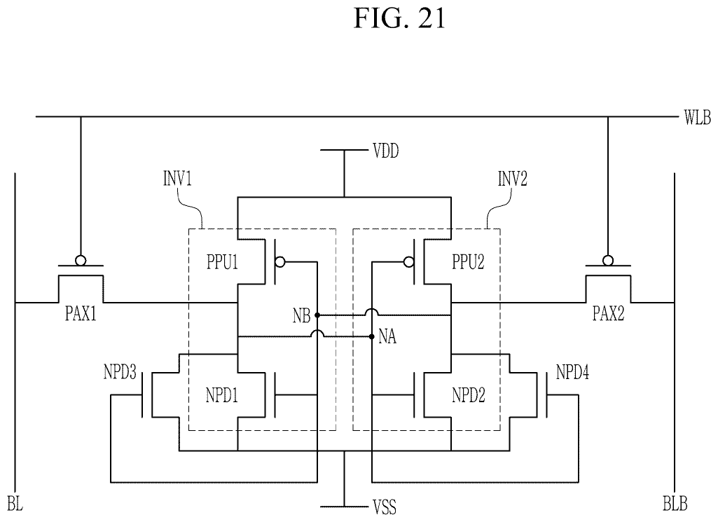

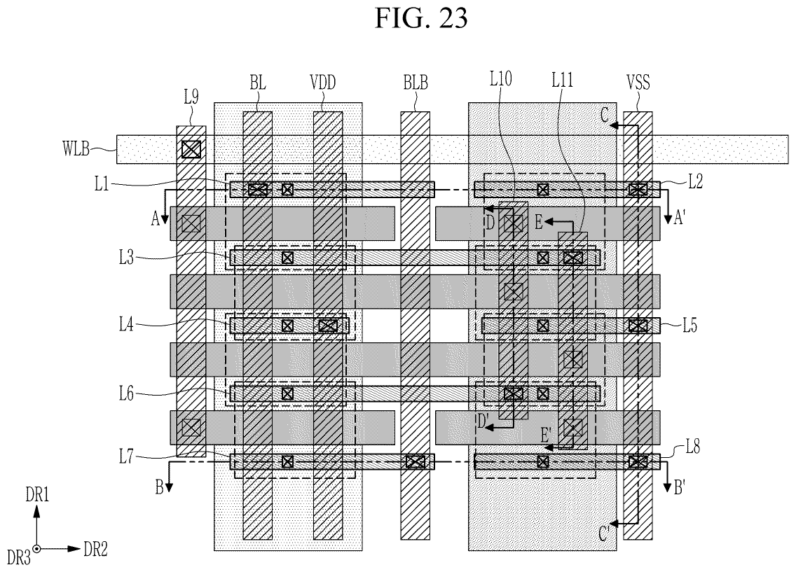

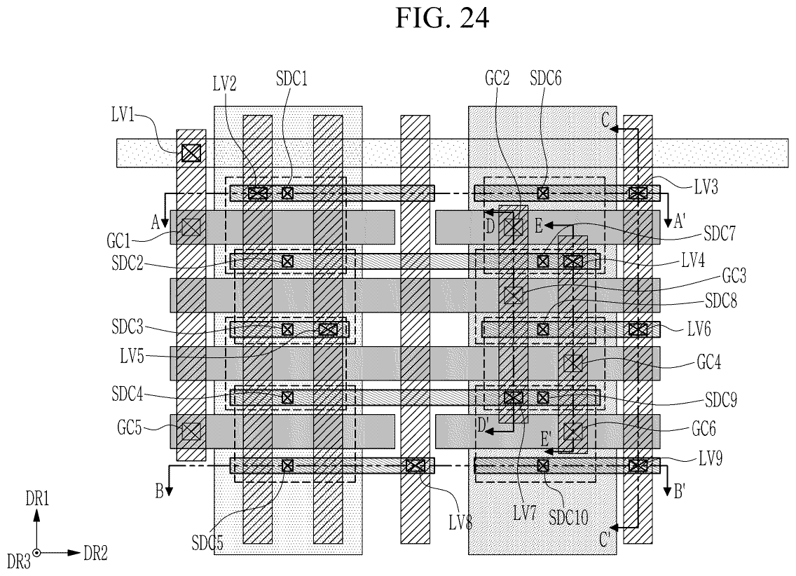

Hereinafter, a semiconductor device according to an exemplary embodiment will be described with reference to FIGS. 21 to 30. A memory cell array of the semiconductor device according to FIGS. 21 to 30 may be identical to that shown in FIG. 1.

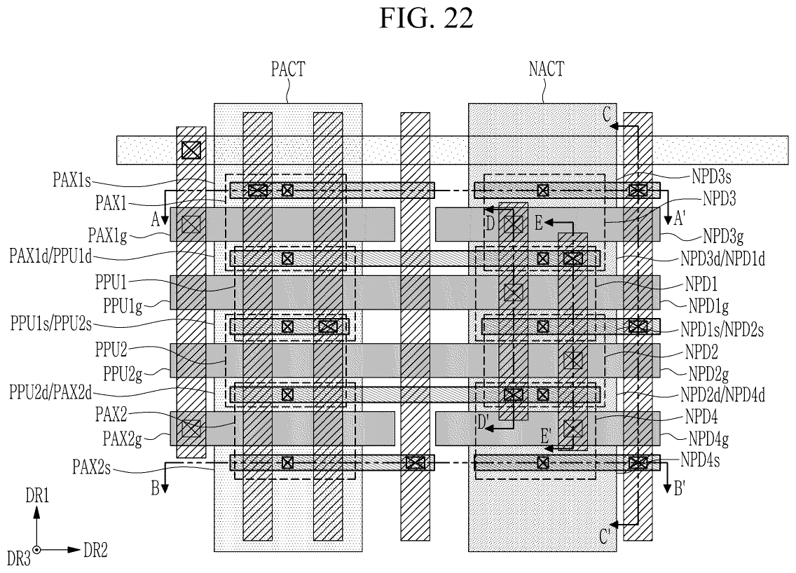

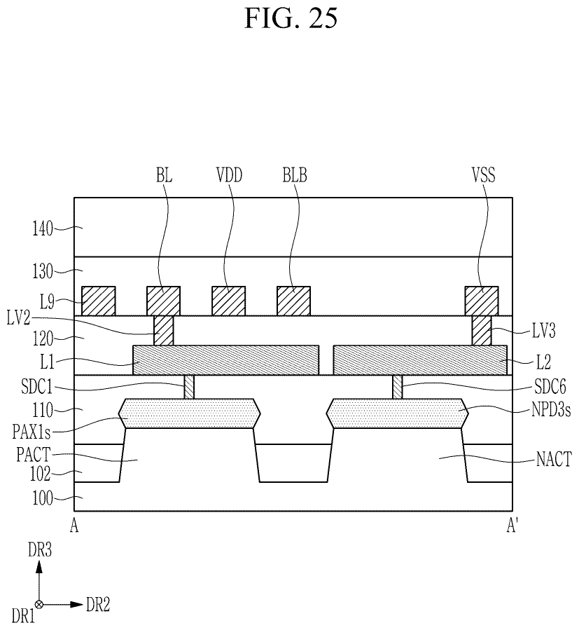

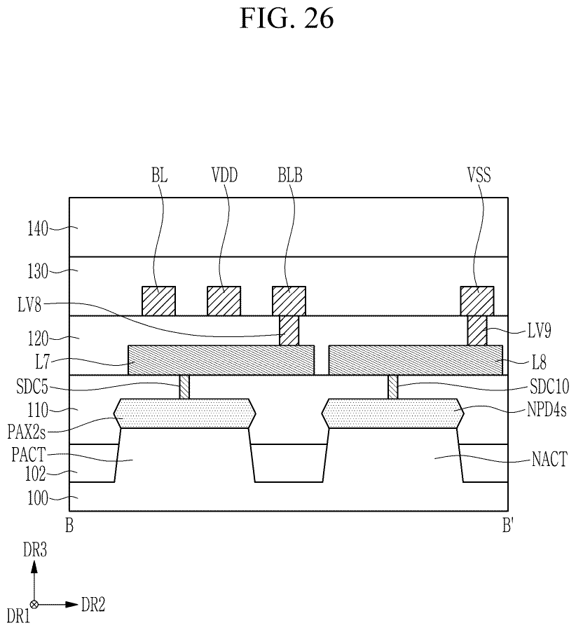

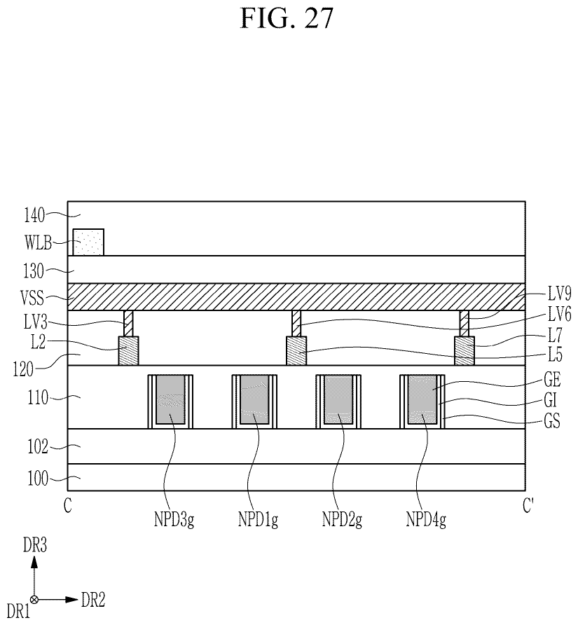

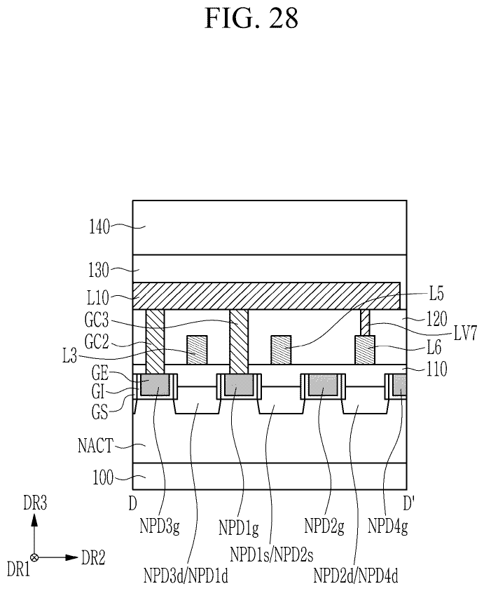

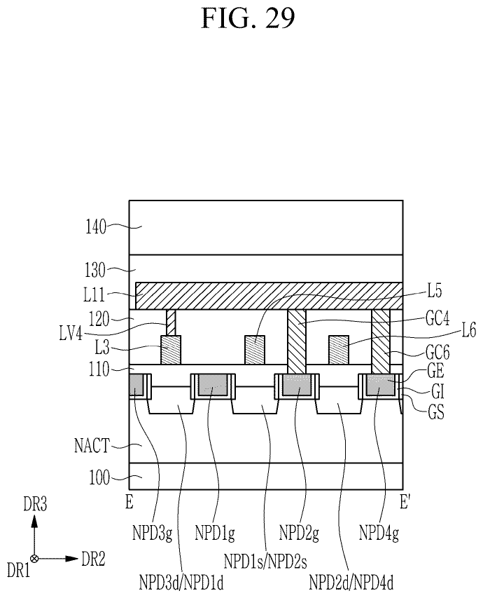

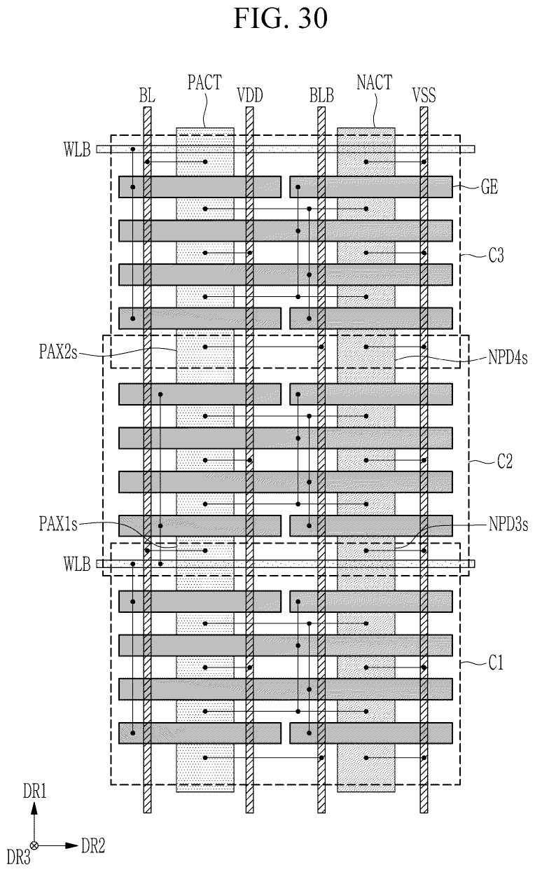

FIG. 21 is an equivalent circuit diagram of a memory cell of the semiconductor device according to the exemplary embodiment. FIGS. 22 to 24 are plan layout diagrams of a memory cell of the semiconductor device according to the exemplary embodiment. FIG. 25 is a cross-sectional view taken along line A-A′ of FIGS. 22 to 24. FIG. 26 is a cross-sectional view taken along line B-B′ of FIGS. 22 to 24. FIG. 27 is a cross-sectional view taken along line C-C′ of FIGS. 22 to 24. FIG. 28 is a cross-sectional view taken along line D-D′ of FIGS. 22 to 24. FIG. 29 is a cross-sectional view taken along line E-E′ of FIGS. 22 to 24. FIG. 30 is a view schematically illustrating a plurality of memory cells of the semiconductor device according to the exemplary embodiment.

Hereinafter, differences from the semiconductor device according to FIGS. 1 to 10 will be mainly described, and a redundant description will not be made or will be made in brief.

Referring to FIG. 21, a memory cell of the semiconductor device may pull-up transistor PPU2, a second pull-down transistor NPD2, a first pass gate transistor PAX1, a second pass gate transistor PAX2, a first additional transistor NPD3, and a second additional transistor NPD4.

The first pull-up transistor PPU1 and the second pull-up transistor PPU2 may be p-type transistors. The first pull-down transistor NPD1 and the second pull-down transistor NPD2 may be n-type transistors. According to the exemplary embodiment, the first pass gate transistor PAX1 and the second pass gate transistor PAX2 may be p-type transistors, and the first additional transistor NPD3 and the second additional transistor NPD4 may be n-type transistors.

The source of the first pass gate transistor PAX1 may be connected to the bit line BL, and the drain of the first pass gate transistor PAX1 may be connected to the first node NA. The source of the second pass gate transistor PAX2 may be connected to a complementary bit line BLB, and the drain of the second pass gate transistor PAX2 may be connected to the second node NB. The gate of the first pass gate transistor PAX1 and the gate of the second pass gate transistor PAX2 may be connected to the complementary word line WLB.

The drain of the first additional transistor NPD3 may be connected to the first node NA, and the source of the first additional transistor NPD3 may be connected to the second power line VSS. The drain of the second additional transistor NPD4 may be connected to the second node NB, and the source of the second additional transistor NPD4 may be connected to the second power line VSS. The gate of the first pull-down transistor NPD1 and the gate of the first additional transistor NPD3 may be connected to the second node NB. The gate of the second pull-down transistor NPD2 and the gate of the second additional transistor NPD4 may be connected to the first node NA.

Accordingly, an SRAM cell including eight transistors according to an exemplary embodiment may be implemented.

Hereinafter, the arrangement and connection relationship of eight transistors constituting the memory cell will be described with reference to FIGS. 22 to 29.

Referring to FIGS. 22 to 29, the first pull-up transistor PPU1, the second pull-up transistor PPU2, the first pass gate transistor PAX1, and the second pass gate transistor PAX2 may be positioned on the first active region PACT, and the first pull-down transistor NPD1, the second pull-down transistor NPD2, the first additional transistor NPD3, and the second additional transistor NPD4 may be positioned on the second active region NACT.

The first pull-up transistor PPU1 and the second pull-up transistor PPU2 may be disposed adjacent in the first direction DR1. The first pass gate transistor PAX1 and the second pass gate transistor PAX2 may be positioned on both sides of the first pull-up transistor PPU1 and the second pull-up transistor PPU2, respectively. The first pull-up transistor PPU1 and the second pull-up transistor PPU2 may be positioned between the first pass gate transistor PAX1 and the second pass gate transistor PAX2. For example, the first pass gate transistor PAX1, the first pull-up transistor PPU1, the second pull-up transistor PPU2, and the second pass gate transistor PAX2 may be sequentially disposed along the first direction DR1; however, the present disclosure is not necessarily limited thereto. As another example, they may be disposed in the order of the first pass gate transistor PAX1, the second pull-up transistor PPU2, the first pull-up transistor PPU1, and the second pass gate transistor PAX2.

The first pull-down transistor NPD1 and the second pull-down transistor NPD2 may be disposed adjacent in the first direction DR1. The first additional transistor NPD3 and the second additional transistor NPD4 may be positioned on both sides of the first pull-down transistor NPD1 and the second pull-down transistor NPD2, respectively. The first pull-down transistor NPD1 and the second pull-down transistor NPD2 may be positioned between the first additional transistor NPD3 and the second additional transistor NPD4. For example, the first additional transistor NPD3, the first pull-down transistor NPD1, the second pull-down transistor NPD2, and the second additional transistor NPD4 may be sequentially disposed along the first direction DR1; however, the present disclosure is not necessarily limited thereto. As another example, they may be disposed in the order of the first additional transistor NPD3, the second pull-down transistor NPD2, the first pull-down transistor NPD1, and the second additional transistor NPD4.

In the first active region PACT on both sides of the gate electrode PAX1g of the first pass gate transistor PAX1, the source region PAX1s and drain region PAX1d of the first pass gate transistor PAX1 may be disposed. In the first active region PACT on both sides of the gate electrode PPU1g of the first pull-up transistor PPU1, the source region PPU1s and drain region PPU1d of the first pull-up transistor PPU1 may be disposed. In the first active region PACT on both sides of the gate electrode PPU2g of the second pull-up transistor PPU2, the source region PPU2s and drain region PPU2d of the second pull-up transistor PPU2 may be disposed. In the first active region PACT on both sides of the gate electrode PAX2g of the second pass gate transistor PAX2, the source region PAX2s and drain region PAX2d of the second pass gate transistor PAX2 may be disposed.

In the second active region NACT on both sides of the gate electrode NPD3g of the first additional transistor NPD3, the source region NPD3s and drain region NPD3d of the first additional transistor NPD3 may be disposed. In the first active region PACT on both sides of the gate electrode NPD1g of the first pull-down transistor NPD1, the source region NPD1s and drain region NPD1d of the first pull-down transistor NPD1 may be disposed. In the second active region NACT on both sides of the gate electrode NPD2g of the second pull-down transistor NPD2, the source region NPD2s and drain region NPD2d of the second pull-down transistor NPD2 may be disposed. In the second active region NACT on both sides of the gate electrode NPD4g of the second additional transistor NPD4, the source region NPD4s and drain region NPD4d of the second additional transistor NPD4 may be disposed.

The drain region PAX1d of the first pass gate transistor PAX1 and the drain region PPU1d of the first pull-up transistor PPU1 may be integrally formed. The source region PPU1s of the first pull-up transistor PPU1 and the source region PPU2s of the second pull-up transistor PPU2 may be integrally formed. The drain region PPU2d of the second pull-up transistor PPU2 and the drain region PAX2d of the second pass gate transistor PAX2 may be integrally formed.

The drain region NPD3d of the first additional transistor NPD3 and the drain region NPD1d of the first pull-down transistor NPD1 may be integrally formed. The source region NPD1s of the first pull-down transistor NPD1 and the source region NPD2s of the second pull-down transistor NPD2 may be integrally formed. The drain region NPD2d of the second pull-down transistor NPD2 and the drain region NPD4d of the second additional transistor NPD4 may be integrally formed.

The source drain contacts SDC1, SDC2, SDC3, SDC4, SDC5, SDC6, SDC7, SDC8, SDC9, and SDC10 may pass through the first interlayer insulating layer 110 and be connected to the source/drain regions. The source drain contacts SDC1, SDC2, SDC3, SDC4, SDC5, SDC6, SDC7, SDC8, SDC9, and SDC10 may be connected to a first wiring layer which is disposed inside the second interlayer insulating layer 120; however, the present disclosure is not necessarily limited thereto. For example, the first wiring layer may include first to eighth connection wiring lines L1, L2, L3, L4, L5, L6, L7, and L8. The first to eighth connection wiring lines L1, L2, L3, L4, L5, L6, L7, and L8 may be disposed so as to each extend in the second direction DR2 and be spaced apart in the first direction DR1. The first connection wiring line L1, the third connection wiring line L3, the fourth connection wiring line L4, the sixth connection wiring line L6, and the seventh connection wiring line L7 may be sequentially disposed along the first direction DR1. The second connection wiring line L2 may be positioned substantially at the same position as that of the first connection wiring line L1 in the first direction DR1. The first connection wiring line L1 and the second connection wiring line L2 may be disposed on the same extension line along the second direction DR2. The fifth connection wiring line L5 may be positioned substantially at the same position as that of the fourth connection wiring line L4 in the first direction DR1. The fourth connection wiring line L4 and the fifth connection wiring line L5 may be disposed on the same extension line along the second direction DR2. The eighth connection wiring line L8 may be positioned substantially at the same position as that of the seventh connection wiring line L7 in the first direction DR1. The seventh connection wiring line L7 and the eighth connection wiring line L8 may be disposed on the same extension line along the second direction DR2.

The first source drain contact SDC1 may be connected to the source region PAX1s of the first pass gate transistor PAX1. The first source drain contact SDC1 may be connected to the first connection wiring line L1.

The sixth source drain contact SDC6 may be connected to the source region NPD3s of the first additional transistor NPD3. The sixth source drain contact SDC6 may be connected to the second connection wiring line L2.

The second source drain contact SDC2 may be connected to the drain region PAX1d of the first pass gate transistor PAX1 and the drain region PPU1d of the first pull-up transistor PPU1. The seventh source drain contact SDC7 may be connected to the drain region NPD3d of the first additional transistor NPD3 and the drain region NPD1d of the first pull-down transistor NPD1. The second source drain contact SDC2 and the seventh source drain contact SDC7 may be connected to the third connection wiring line L3. The drain region PAX1d of the first pass gate transistor PAX1, the drain region PPU1d of the first pull-up transistor PPU1, the drain region NPD3d of the first additional transistor NPD3, and the drain region NPD1d of the first pull-down transistor NPD1 may be electrically connected by the second source drain contact SDC2, the seventh source drain contact SDC7, and the third connection wiring line L3.

The third source drain contact SDC3 may be connected to the source region PPU1s of the first pull-up transistor PPU1 and the source region PPU2s of the second pull-up transistor PPU2. The third source drain contact SDC3 may be connected to the fourth connection wiring line L4.

The eighth source drain contact SDC8 may be connected to the source region NPD1s of the first pull-down transistor NPD1 and the source region NPD2s of the second pull-down transistor NPD2. The eighth source drain contact SDC8 may be connected to the fifth connection wiring line L5.

The fourth source drain contact SDC4 may be connected to the drain region PPU2d of the second pull-up transistor PPU2 and the drain region PAX2d of the second pass gate transistor PAX2. The ninth source drain contact SDC9 may be connected to the drain region NPD2d of the second pull-down transistor NPD2 and the drain region NPD4d of the second additional transistor NPD4. The fourth source drain contact SDC4 and the ninth source drain contact SDC9 may be connected to the sixth connection wiring line L6. The drain region PPU2d of the second pull-up transistor PPU2, the drain region PAX2d of the second pass gate transistor PAX2, the drain region NPD2d of the second pull-down transistor NPD2, and the drain region NPD4d of the second additional transistor NPD4 may be electrically connected by the fourth source drain contact SDC4, the ninth source drain contact SDC9, and the sixth connection wiring line L6.

The fifth source drain contact SDC5 may be connected to the source region PAX2s of the second pass gate transistor PAX2. The fifth source drain contact SDC5 may be connected to the seventh connection wiring line L7.

The tenth source drain contact SDC10 may be connected to the source region NPD4s of the second additional transistor NPD4. The tenth source drain contact SDC10 may be connected to the eighth connection wiring line L8.

The gate contacts GC1, GC2, GC3, GC4, GC5, and GC6 may pass through the second interlayer insulating layer 120 and the first interlayer insulating layer 110 and be connected to the gate electrodes GE. The gate contacts GC1, GC2, GC3, GC4, GC5, and GC6 may be connected to a second wiring layer which is disposed inside the third interlayer insulating layer 130; however, the present disclosure is not necessarily limited thereto. For example, the second wiring layer may include ninth to eleventh connection wiring lines L9, L10, and L11, the bit line BL, the complementary bit line BLB, the first power line VDD, and the second power line VSS. The ninth to eleventh connection wiring lines L9, L10, and L11, the bit line BL, the complementary bit line BLB, the first power line VDD, and the second power line VSS may be disposed so as to each extend in the first direction DR1 and be spaced apart in the second direction DR2. For example, they may be disposed in the order of the ninth connection wiring line L9, the bit line BL, the first power line VDD, the complementary bit line BLB, the tenth connection wiring line L10, the eleventh connection wiring line L11, and the second power line VSS along the second direction DR2; however, the exemplary embodiment is not necessarily limited thereto. The arrangement order of the wiring lines in the second wiring layer may be variously changed.

The second gate contact GC2 may be connected to the gate electrode NPD3g of the first additional transistor NPD3. The third gate contact GC3 may be connected to the gate electrode NPD1g of the first pull-down transistor NPD1 and the gate electrode PPU1g of the first pull-up transistor PPU1. The second gate contact GC2 and the third gate contact GC3 may be connected to the tenth connection wiring line L10. The gate electrode NPD3g of the first additional transistor NPD3, the gate electrode NPD1g of the first pull-down transistor NPD1, and the gate electrode PPU1g of the first pull-up transistor PPU1 may be electrically connected by the second gate contact GC2, the third gate contact GC3, and the tenth connection wiring line L10.

The sixth gate contact GC6 may be connected to the gate electrode NPD4g of the second additional transistor NPD4. The fourth gate contact GC4 may be connected to the gate electrode NPD2g of the second pull-down transistor NPD2 and the gate electrode PPU2g of the second pull-up transistor PPU2. The sixth gate contact GC6 and the fourth gate contact GC4 may be connected to the eleventh connection wiring line L11. The gate electrode NPD4g of the second additional transistor NPD4, the gate electrode NPD2g of the second pull-down transistor NPD2, and the gate electrode PPU2g of the second pull-up transistor PPU2 may be electrically connected by the sixth gate contact GC6, the fourth gate contact GC4, and the eleventh connection wiring line L11.

The first gate contact GC1 may be connected to the gate electrode PAX1g of the first pass gate transistor PAX1. The fifth gate contact GC5 may be connected to the gate electrode PAX2g of the second pass gate transistor PAX2. The first gate contact GC1 and the fifth gate contact GC5 may be connected to the ninth connection wiring line L9. The gate electrode PAX1g of the first pass gate transistor PAX1 and the gate electrode PAX2g of the second pass gate transistor PAX2 may be electrically connected by the first gate contact GC1, the fifth gate contact GC5, and the ninth connection wiring line L9.

The third wiring layer which is disposed inside the fourth interlayer insulating layer 140 may include the complementary word line WLB. For example, the complementary word line WLB may be positioned at the edge of the memory cell; however, the exemplary embodiment is not necessarily limited thereto. Unlike in the exemplary embodiment of FIGS. 1 to 10, the word line WL may be output.

Vias LV1, LV2, LV3, LV4, LV5, LV6, LV7, LV8, and LV9 may connect the first wiring layer, the second wiring layer, and the third wiring layer. The first via LV1 may pass through the third interlayer insulating layer 130 and connect the second wiring layer and the third wiring layer. The second to ninth vias LV2, LV3, LV4, LV5, LV6, LV7, LV8, and LV9 may pass through the second interlayer insulating layer 120 and connect the first wiring layer and the second wiring layer.

The first via LV1 may connect the complementary word line WLB and the ninth connection wiring line L9. In other words, the gate electrode PAX1g of the first pass gate transistor PAX1 and the gate electrode PAX2g of the second pass gate transistor PAX2 may be electrically connected to the complementary word line WLB by the first gate contact GC1, the fifth gate contact GC5, the ninth connection wiring line L9, and the first via LV1.

The second via LV2 may connect the bit line BL and the first connection wiring line L1. In other words, the source region PAX1s of the first pass gate transistor PAX1 may be electrically connected to the bit line BL by the first source drain contact SDC1, the first connection wiring line L1, and the second via LV2.

The eighth via LV8 may connect the complementary bit line BLB and the seventh connection wiring line L7. In other words, the source region PAX2s of the second pass gate transistor PAX2 may be electrically connected to the complementary bit line BLB by the fifth source drain contact SDC5, the seventh connection wiring line L7, and the eighth via LV8.

The fourth via LV4 may connect the eleventh connection wiring line L11 and the third connection wiring line L3. In other words, the drain region NPD3d of the first additional transistor NPD3, the drain region NPD1d of the first pull-down transistor NPD1, the drain region PAX1d of the first pass gate transistor PAX1, and the drain region PPU1d of the first pull-up transistor PPU1 may be electrically connected to the gate electrode PPU2g of the second pull-up transistor PPU2, the gate electrode NPD2g of the second pull-down transistor NPD2, and the gate electrode NPD4g of the second additional transistor NPD4 by the second source drain contact SDC2, the seventh source drain contact SDC7, the third connection wiring line L3, the fourth gate contact GC4, the sixth gate contact GC6, the fourth via LV4, and the eleventh connection wiring line L11.

The seventh via LV7 may connect the tenth connection wiring line L10 and the sixth connection wiring line L6. In other words, the drain region NPD4d of the second additional transistor NPD4, the drain region NPD2d of the second pull-down transistor NPD2, the drain region PAX2d of the second pass gate transistor PAX2, and the drain region PPU2d of the second pull-up transistor PPU2 may be electrically connected to the gate electrode PPU1g of the first pull-up transistor PPU1, the gate electrode NPD1g of the first pull-down transistor NPD1, and the gate electrode NPD3g of the first additional transistor NPD3 by the fourth source drain contact SDC4, the ninth source drain contact SDC9, the sixth connection wiring line L6, the third gate contact GC3, the second gate contact GC2, the seventh via LV7, and the tenth connection wiring line L10.

The fifth via LV5 may connect the fourth connection wiring line L4 and the first power line VDD. In other words, the source region PPU1s of the first pull-up transistor PPU1 and the source region PPU2s of the second pull-up transistor PPU2 may be electrically connected to the first power line VDD by the third source drain contact SDC3, the fourth connection wiring line L4, and the fifth via LV5.

The sixth via LV6 may connect the fifth connection wiring line L5 and the second power line VSS. In other words, the source region NPD1s of the first pull-down transistor NPD1 and the source region NPD2s of the second pull-down transistor NPD2 may be electrically connected to the second power line VSS by the eighth source drain contact SDC8, the fifth connection wiring line L5, and the sixth via LV6.

The third via LV3 may connect the second connection wiring line L2 and the second power line VSS. In other words, the source region NPD3s of the first additional transistor NPD3 may be electrically connected to the second power line VSS by the sixth source drain contact SDC6, the second connection wiring line L2, and the third via LV3.

The ninth via LV9 may connect the eighth connection wiring line L8 and the second power line VSS. In other words, the source region NPD4s of the second additional transistor NPD4 may be electrically connected to the second power line VSS by the tenth source drain contact SDC10, the eighth connection wiring line L8, and the ninth via LV9.

Hereinafter, the relationship of a plurality of memory cells adjacent in the first direction DR1 of the semiconductor device accuracy of the exemplary embodiment will be described with reference to FIG. 30 together.

Referring to FIG. 30, the semiconductor device according to the exemplary embodiment may include a first memory cell C1, a second memory cell C2, and a third memory cell C3 which are disposed along the first direction DR1. In respect to each of the first memory cell C1, the second memory cell C2, and the third memory cell C3, the contents of the memory cell described above with reference to FIGS. 21 to 29 may be equally applied. Each of the first memory cell C1, the second memory cell C2, and the third memory cell C3 may include a first pull-up transistor PPU1, a first pull-down transistor NPD1, a second pull-up transistor PPU2, a second pull-down transistor NPD2, a first pass gate transistor PAX1, a second pass gate transistor PAX2, a first additional transistor NPD3, and a second additional transistor NPD4.

The transistors which are disposed at both ends of each memory cell in the first direction DR1 may share a source/drain region with a transistor which is included in another memory cell adjacent thereto in the first direction DR1 and performs the same function.

According to the exemplary embodiment, the first additional transistor NPD3 of the first memory cell C1 and the first additional transistor NPD3 of the second memory cell C2 may share a source region NPD3s. The second additional transistor NPD4 of the second memory cell C2 and the second additional transistor NPD4 of the third memory cell C3 may share a source region PPU4s.

According to the exemplary embodiment, the first pass gate transistor PAX1 of the first memory cell C1 and the first pass gate transistor PAX1 of the second memory cell C2 may share a source region PAX1s. The second pass gate transistor PAX2 of the second memory cell C2 and the second pass gate transistor PAX2 of the third memory cell C3 may share a source region PAX2s.

According to the exemplary embodiment, the source region PPU3s of the first additional transistor NPD3 of each memory cell may be connected to the second power line VSS, and the source region PAX1s of the first pass gate transistor PAX1 may be connected to the bit line BL. The source region NPD4s of the second additional transistor NPD4 of each memory cell may be connected to the second power line VSS, and the source region PAX2s of the second pass gate transistor PAX2 may be connected to the complementary bit line BLB.

The second memory cell C2 may share the connection relationship of the source region NPD3s of the first additional transistor NPD3 with the first memory cell C1. In other words, the second memory cell C2 may share the sixth source drain contact SDC6 that is connected to the source region NPD3s of the first additional transistor NPD3, the second connection wiring line L2 to which the sixth source drain contact SDC6 is connected, and the third via LV3 that connects the second connection wiring line L2 and the second power line VSS.

The second memory cell C2 may share the connection relationship of the source region PAX1s of the first pass gate transistor PAX1 with the first memory cell C1. In other words, the second memory cell C2 may share the first source drain contact SDC1 that is connected to the source region PAX1s of the first pass gate transistor PAX1, the first connection wiring line L1 to which the first source drain contact SDC1 is connected, and the second via LV2 that connects the first connection wiring line L1 and the bit line BL, with the first memory cell C1.

The second memory cell C2 may share the connection relationship of the source region NPD4s of the second additional transistor NPD4 with the third memory cell C3. In other words, the second memory cell C2 may share the tenth source drain contact SDC10 that is connected to the source region NPD4s of the second additional transistor NPD4, the eighth connection wiring line L8 to which the tenth source drain contact SDC10 is connected, and the ninth via LV9 that connects the eighth connection wiring line L8 and the second power line VSS, with the third memory cell C3.

The second memory cell C2 may share the connection relationship of the source region PAX2s of the second pass gate transistor PAX2 with the third memory cell C3. In other words, the second memory cell C2 may share the fifth source drain contact SDC5 that is connected to the source region PAX2s of the second pass gate transistor PAX2, the seventh connection wiring line L7 to which the fifth source drain contact SDC5 is connected, and the eighth via LV8 that connects the seventh connection wiring line L7 and the complementary bit line BLB, with the third memory cell C3.

The process of forming the transistors of the semiconductor device according to the exemplary embodiment of FIGS. 21 to 30 may be identical to the process of forming the transistors of the semiconductor device according to the exemplary embodiment of FIGS. 1 to 10. The semiconductor device according to the exemplary embodiment of FIGS. 21 to 30 may be formed by changing etch masks for forming contact holes, via holes, and wiring lines of the semiconductor device according to the exemplary embodiment of FIGS. 1 to 10.

The semiconductor device according to the exemplary embodiment may include the first additional transistor NPD3 and the second additional transistor NPD4 that are disposed on both sides the first pull-down transistor NPD1 and the second pull-down transistor NPD2 so as to face the first pass gate transistor PAX1 and the second pass gate transistor PAX2, respectively. A memory cell of the semiconductor device according to an exemplary embodiment may be an SRAM cell which consists of eight transistors by adding two pull-up transistors to an SRAM cell which is implemented with six transistors. Each of the first additional transistor NPD3 and the second additional transistor NPD4 of the semiconductor device according to the exemplary embodiment may serve as a pull-down transistor along with each of the first pull-down transistor NPD1 and the second pull-down transistor NPD2. According to the exemplary embodiment, it is possible to improve the read and write performance without increasing the area as compared to an SRAM cell which is implemented with six transistors.

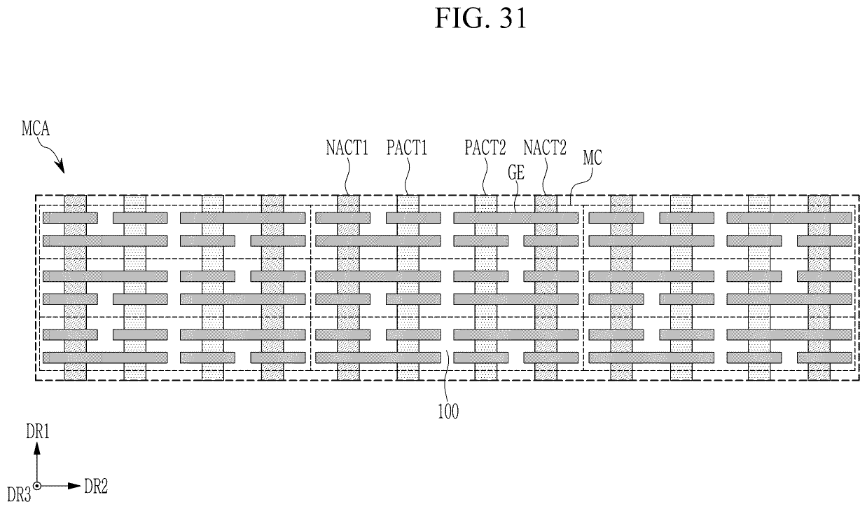

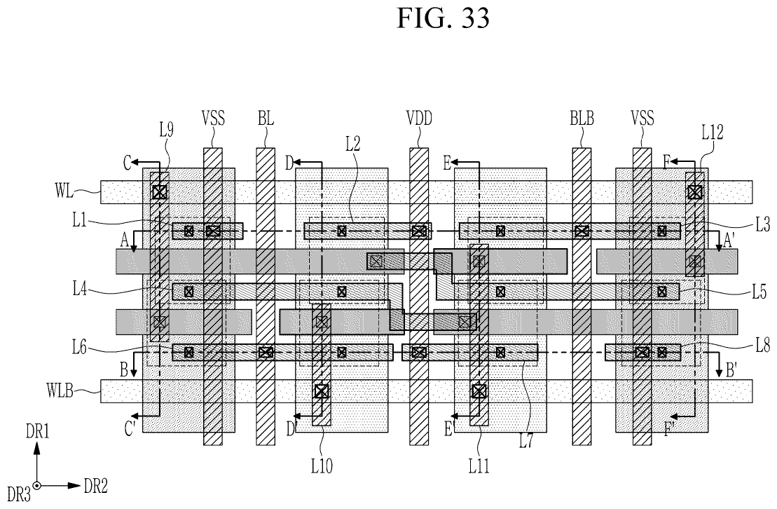

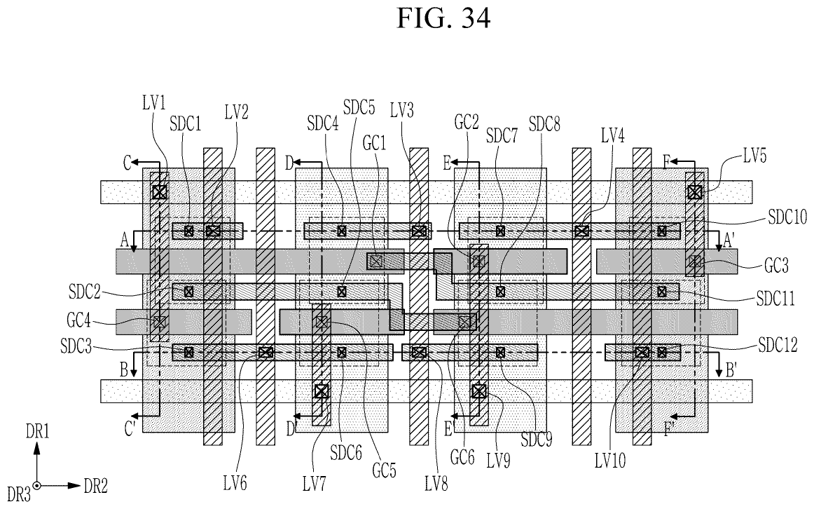

Hereinafter, a semiconductor device according to an exemplary embodiment will be described with reference to FIGS. 31 to 41.

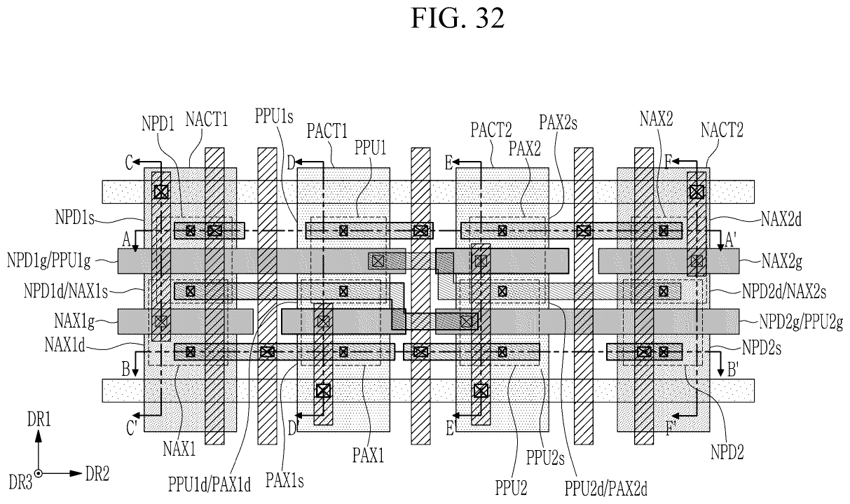

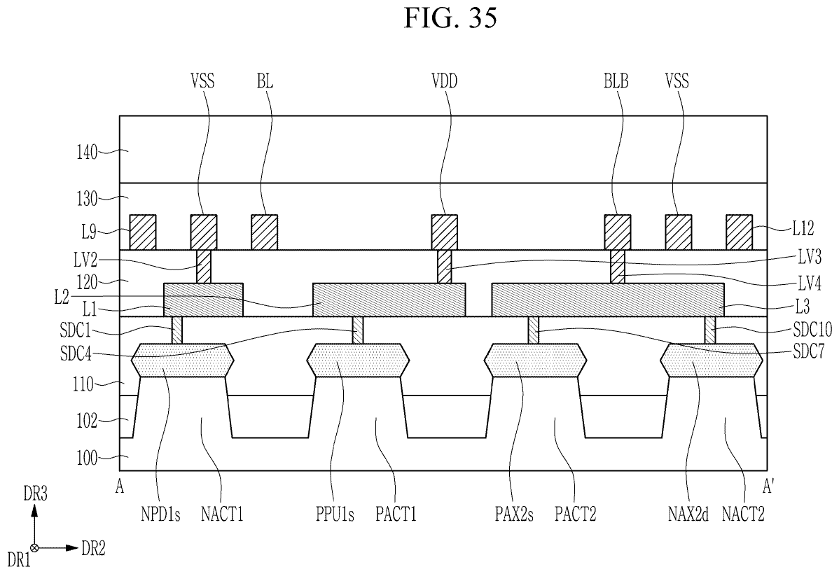

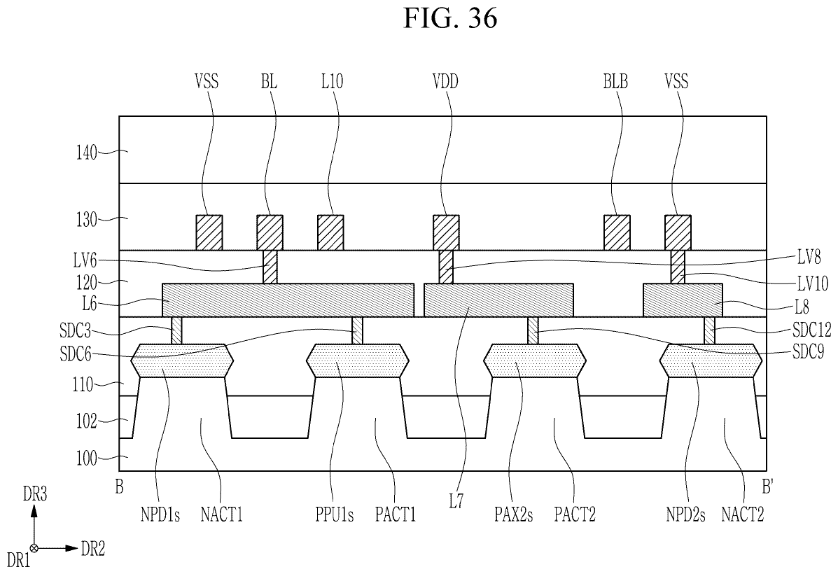

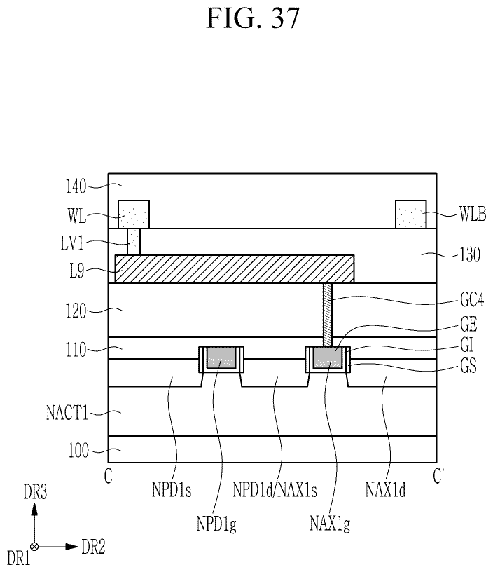

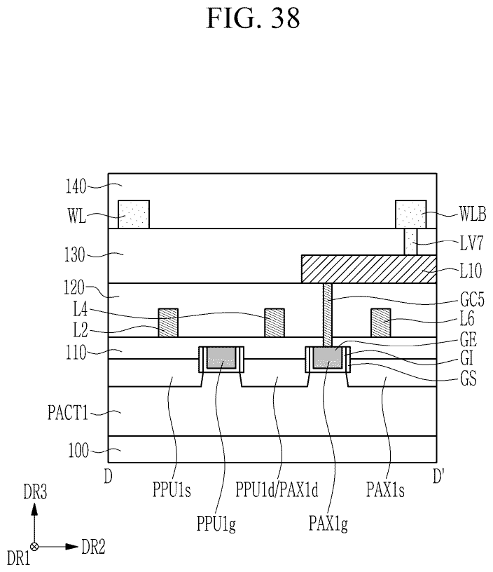

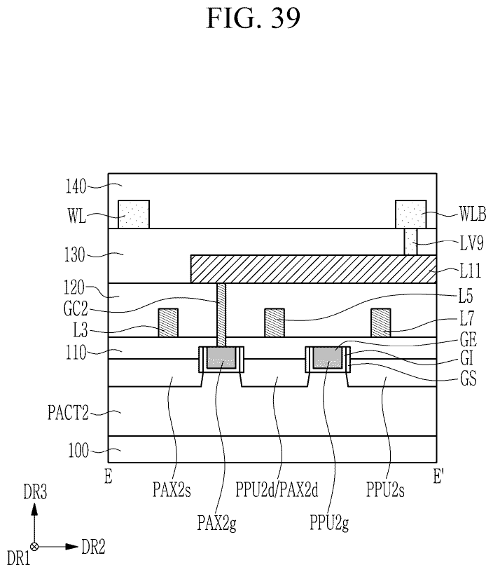

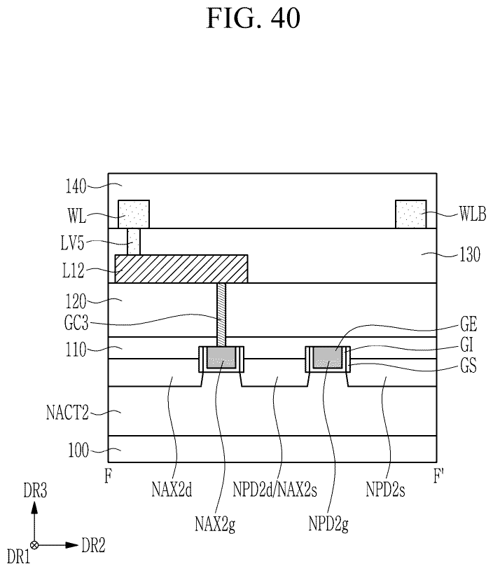

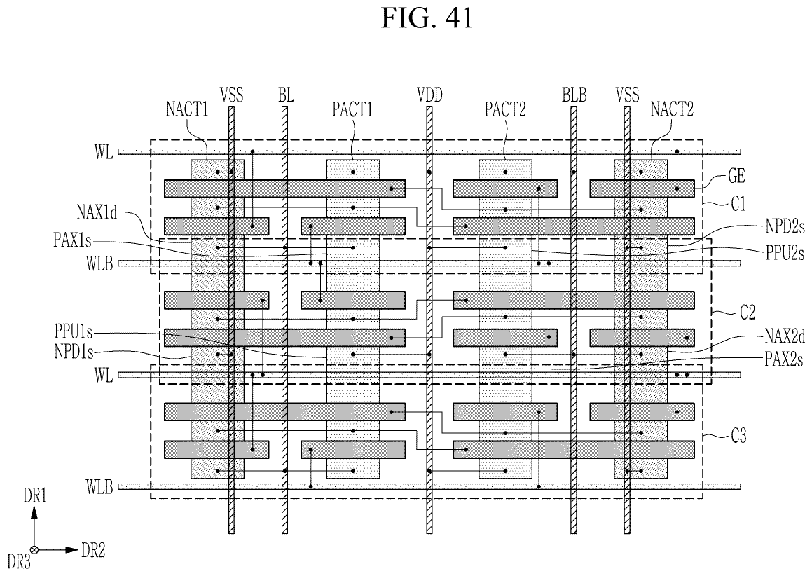

FIG. 31 is a view schematically illustrating a memory cell array of a semiconductor device according to an exemplary embodiment. FIGS. 32 to 34 are plan layout diagrams of a memory cell of the semiconductor device according to the exemplary embodiment. FIG. 35 is a cross-sectional view taken along line A-A′ of FIGS. 32 to 34. FIG. 36 is a cross-sectional view taken along line B-B′ of FIGS. 32 to 34. FIG. 37 is a cross-sectional view taken along line C-C′ of FIGS. 32 to 34. FIG. 38 is a cross-sectional view taken along line D-D′ of FIGS. 32 to 34. FIG. 39 is a cross-sectional view taken along line E-E′ of FIGS. 32 to 34. FIG. 40 is a cross-sectional view taken along line F-F′ of FIGS. 32 to 34. FIG. 41 is a view schematically illustrating a plurality of memory cells of the semiconductor device according to the exemplary embodiment.

Hereinafter, differences from the semiconductor device according to FIGS. 1 to 10 will be mainly described, and a redundant description will not be made or will be made in brief.

Referring to FIG. 31, a semiconductor device may include a substrate 100, and a memory cell array MCA including a plurality of memory cells MC on the substrate 100. The substrate 100 may include a first active region PACT1 and a third active region PACT2 where transistors of a first conductivity type are disposed, and a second active region NACT1 and a fourth active region NACT2 where transistors of a second conductivity type are disposed.

In an exemplary embodiment, the first conductivity type may be a p-type, and the second conductivity type may be an n-type. A portion of the first active region PACT1 and a portion of the third active region PACT2 may contain a p-type impurity, and a region containing the p-type impurity may be provided as a source region or a drain region. A portion of the second active region NACT1 and a portion of the fourth active region NACT2 may contain an n-type impurity, and a region containing the n-type impurity may be provided as a source region or a drain region.

The first active region PACT1, the second active region NACT1, the third active region PACT2, and the fourth active region NACT2 NACT may extend in the first direction DR1 parallel with the upper surface of the substrate 100. The first active region PACT1, the second active region NACT1, the third active region PACT2, and the fourth active region NACT2 may be disposed so as to be parallel with the upper surface of the substrate 100 and be spaced apart in the second direction DR2 perpendicular to the first direction DR1.

According to an exemplary embodiment, the third active region PACT2 may be disposed adjacent to the first active region PACT1. Inside one memory cell MC, the second active region NACT1 and the fourth active region NACT2 may be disposed on both sides of the first active region PACT1 and the third active region PACT2, respectively. The first active region PACT1 and the third active region PACT2 may be disposed between the second active region NACT1 and the fourth active region NACT2.

The substrate 100 may include a plurality of first active regions PACT1, a plurality of second active regions NACT1, a plurality of third active regions PACT2, and a plurality of fourth active regions NACT2. According to an exemplary embodiment, they may be disposed repeatedly in the order of a second active region NACT1, a first active region PACT1, a third active region PACT2, and a fourth active region NACT2 along the second direction DR2.

The semiconductor device may include gate electrodes GE which extend the second direction DR2 while crossing the first active region PACT1, the second active region NACT1, the third active region PACT2, and a fourth active region NACT2. The gate electrodes GE may include a first gate electrode that crosses the first active region PACT1, a second gate electrode that crosses the second active region NACT1, and a third gate electrode that crosses the first active region PACT1 and the second active region NACT1. The gate electrodes GE may include a fourth gate electrode that crosses the third active region PACT2, a fifth gate electrode that crosses the fourth active region NACT2, and a sixth gate electrode that crosses the third active region PACT2 and the fourth active region NACT2.

According to an exemplary embodiment, a plurality of memory cells MC may be disposed in an array form along the first direction DR1 and the second direction DR2. Each of the plurality of memory cells MC may be disposed on the first active region PACT1, the second active region NACT1, the third active region PACT2, and the fourth active region NACT2. A plurality of memory cells MC which is disposed along the first direction DR1 may be disposed on the same first active region PACT1, the same second active region NACT1, the same third active region PACT2, and the same fourth active region NACT2. A plurality of memory cells MC which is disposed along the second direction DR2 may be disposed on different first active regions PACT1, different second active regions NACT1, different third active regions PACT2, and different fourth active regions NACT2.

According to an exemplary embodiment, each of the plurality of memory cells MC may include one first gate electrode that crosses a first active region PACT1, one second gate electrode that crosses a second active region NACT1, one third gate electrode that crosses the first active region PACT1 and the second active region NACT1, one fourth gate electrode that crosses a third active region PACT2, one fifth gate electrode that crosses a fourth active region NACT2, and one sixth gate electrode that crosses the third active region PACT2 and the fourth active region NACT2. In this case, the second gate electrode, the first gate electrode, and the sixth gate electrode may be disposed on the same extension line along the second direction DR2. The third gate electrode, the fourth gate electrode, and the fifth gate electrode may be disposed on the same extension line along the second direction DR2. The second gate electrode and the first gate electrode may be disposed one side of the third gate electrode in the first direction DR1. The fourth gate electrode and the fifth gate electrode may be disposed on one side of the sixth gate electrode in the first direction DR1.

On both sides of a gate electrode GE, a source region and a drain region may be provided, respectively. The gate electrode GE, and the source region and the drain electrode that are positioned on both sides of the gate electrode GE may constitute a transistor. For example, in the first active region PACT1 on both sides of a gate electrode GE and the third active region PACT2 of the gate electrode GE, a source region and a drain region doped with a p-type impurity may be provided. In the second active region NACT1 on both sides of a gate electrode GE and the fourth active region NACT2 on both sides of the gate electrode GE, a source region and a drain region doped with an n-type impurity may be provided.

In an exemplary embodiment, each of the plurality of memory cells MC may include at least eight transistors. For example, each of the plurality of memory cells MC may include two transistors that are positioned on a first active region PACT1, two transistors that are positioned on the second active region NACT1, two transistors that are positioned on a third active region PACT2, and two transistors that are positioned on a fourth active region NACT2. According to an exemplary embodiment, the transistors that are positioned on the first active region PACT1 and the third active region PACT2 may be p-type transistors, and the transistors that are positioned on the second active region NACT1 and the fourth active region NACT2 may be n-type transistors. In other words, each of the plurality of memory cells MC may include four p-type transistors and four n-type transistors.

The circuit of each of the plurality of memory cells MC of the semiconductor device according to FIGS. 31 to 41 may be identical to that shown in FIG. 2. Each of the plurality of memory cells MC of the semiconductor device according to the exemplary embodiment may be an SRAM cell which is implemented with eight transistors. Each of the plurality of memory cells MC may include a first pull-up transistor PPU1, a first pull-down transistor NPD1, a second pull-up transistor PPU2, a second pull-down transistor NPD2, a first pass gate transistor NAX1, a second pass gate transistor NAX2, a first additional transistor PAX1, and a second additional transistor PAX2.

The first pull-up transistor PPU1 and the second pull-up transistor PPU2 may be p-type transistors. The first pull-down transistor NPD1 and the second pull-down transistor NPD2 may be n-type transistors. According to an exemplary embodiment, the first pass gate transistor NAX1 and the second pass gate transistor NAX2 may be n-type transistors, and the first additional transistor PAX1 and the second additional transistor PAX2 may be p-type transistors.

Hereinafter, the arrangement and connection relationship of eight transistors constituting each of the plurality of memory cells MC will be described with reference to FIGS. 32 to 40.

Referring to FIGS. 32 to 40, the first pull-up transistor PPU1 and the first additional transistor PAX1 may be positioned on the first active region PACT1, and the first pull-down transistor NPD1 and the first pass gate transistor NAX1 may be positioned on the second active region NACT1. The second pull-up transistor PPU2 and the second additional transistor PAX2 may be positioned on the third active region PACT2. The second pull-down transistor NPD2 and the second pass gate transistor NAX2 may be positioned on the fourth active region NACT2.

The first additional transistor PAX1 may be disposed on one side of the first pull-up transistor PPU1 on the first active region PACT1. The first pass gate transistor NAX1 may be disposed on one side of the first pull-down transistor NPD1 on the second active region NACT1. The second additional transistor PAX2 may be positioned on one side of the second pull-up transistor PPU2 on the third active region PACT2. The second pass gate transistor NAX2 may be disposed on one side of the second pull-down transistor NPD2 on the fourth active region NACT2.

The first pull-up transistor PPU1 and the first additional transistor PAX1 may be disposed along the first direction DR1. The second pull-up transistor PPU2 and the second additional transistor PAX2 may be disposed along the first direction DR1. The first pull-up transistor PPU1 may be disposed so as to face the second additional transistor PAX2 in the second direction DR2. The second pull-up transistor PPU2 may be disposed so as to face the first additional transistor PAX1 in the second direction DR2.

The first pull-down transistor NPD1 and the first pass gate transistor NAX1 may be disposed along the first direction DR1. The first pull-down transistor NPD1 may be disposed so as to face the first pull-up transistor PPU1 in the second direction DR2. The first pass gate transistor NAX1 may be disposed so as to face the first additional transistor PAX1 in the second direction DR2.

The second pull-down transistor NPD2 and the second pass gate transistor NAX2 may be disposed along the first direction DR1. The second pull-down transistor NPD2 may be disposed so as to face the second pull-up transistor PPU2 in the second direction DR2. The second pass gate transistor NAX2 may be disposed so as to face the second additional transistor PAX2 in the second direction DR2.

The gate electrode PPU1g of the first pull-up transistor PPU1 may be formed integrally with the gate electrode NPD1g of the first pull-down transistor NPD1. The gate electrode PPU2g of the second pull-up transistor PPU2 may be formed integrally with the gate electrode NPD2g of the second pull-down transistor NPD2.

The gate electrode PAX1g of the first additional transistor PAX1 and the gate electrode NAX1g of the first pass gate transistor NAX1 may be arranged in the second direction DR2. The gate electrode PAX1g of the first additional transistor PAX1 and the gate electrode PPU2g of the second pull-up transistor PPU2 may be arranged in the second direction DR2.

The gate electrode PAX2g of the second additional transistor PAX2 and the gate electrode NAX2g of the second pass gate transistor NAX2 may be arranged in the second direction DR2. The gate electrode PAX2g of the second additional transistor PAX2 and the gate electrode PPU1g of the first pull-up transistor PPU1 may be arranged in the second direction DR2.

Between the gate electrode PAX1g of the first additional transistor PAX1 and the gate electrode NAX1g of the first pass gate transistor NAX1, an insulating pattern may be interposed. The insulating pattern may isolate the gate electrode PAX1g of the first additional transistor PAX1 and the gate electrode NAX1g of the first pass gate transistor NAX1. Between the gate electrode PAX1g of the first additional transistor PAX1 and the gate electrode PPU2g of the second pull-up transistor PPU2, an insulating pattern may be interposed. The insulating pattern may isolate the gate electrode PAX1g of the first additional transistor PAX1 and the gate electrode PPU2g of the second pull-up transistor PPU2.

Between the gate electrode PAX2g of the second additional transistor PAX2 and the gate electrode NAX2g of the second pass gate transistor NAX2, an insulating pattern may be interposed. The insulating pattern may isolate the gate electrode PAX2g of the second additional transistor PAX2 and the gate electrode NAX2g of the second pass gate transistor NAX2. Between the gate electrode PAX2g of the second additional transistor PAX2 and the gate electrode PPU2g of the second pull-up transistor PPU2, an insulating pattern may be interposed. The insulating pattern may isolate the gate electrode PAX2g of the second additional transistor PAX2 and the gate electrode PPU1g of the first pull-up transistor PPU1.

In the first active region PACT1 on both sides of the gate electrode PAX1g of the first additional transistor PAX1, the source region PAX1s and drain region PAX1d of the first additional transistor PAX1 may be disposed. In the first active region PACT1 on both sides of the gate electrode PPU1g of the first pull-up transistor PPU1, the source region PPU1s and drain region PPU1d of the first pull-up transistor PPU1 may be disposed. The drain region PAX1d of the first additional transistor PAX1 and the drain region PPU1d of the first pull-up transistor PPU1 may be integrally formed.

In the third active region PACT2 on both sides of the gate electrode PPU2g of the second pull-up transistor PPU2, the source region PPU2s and drain region PPU2d of the second pull-up transistor PPU2 may be disposed. In the third active region PACT2 on both sides of the gate electrode PAX2g of the second additional transistor PAX2, the source region PAX2s and drain region PAX2d of the second additional transistor PAX2 may be disposed. The drain region PAX2d of the second additional transistor PAX2 and the drain region PPU2d of the second pull-up transistor PPU2 may be integrally formed.

In the second active region NACT1 on both sides of the gate electrode NAX1g of the first pass gate transistor NAX1, the source region NAX1s and drain region NAX1d of the first pass gate transistor NAX1 may be disposed. In the second active region NACT1 on both sides of the gate electrode NPD1g of the first pull-down transistor NPD1, the source region NPD1s and drain region NPD1d of the first pull-down transistor NPD1 may be disposed. The source region NAX1s of the first pass gate transistor NAX1 and the drain region NPD1d of the first pull-down transistor NPD1 may be integrally formed.

In the fourth active region NACT2 on both sides of the gate electrode NAX2g of the second pass gate transistor NAX2, the source region NAX2s and drain region NAX2d of the second pass gate transistor NAX2 may be disposed. In the fourth active region NACT2 on both sides of the gate electrode NPD2g of the second pull-down transistor NPD2, the source region NPD2s and drain region NPD2d of the second pull-down transistor NPD2 may be disposed. The source region NAX2s of the second pass gate transistor NAX2 and the drain region NPD2d of the second pull-down transistor NPD2 may be integrally formed.

Source drain contacts SDC1, SDC2, SDC3, SDC4, SDC5, SDC6, SDC7, SDC8, SDC9, SDC10, SDC11, and SDC12 may pass through the first interlayer insulating layer 110 and be connected to the source/drain regions. The source drain contacts SDC1, SDC2, SDC3, SDC4, SDC5, SDC6, SDC7, SDC8, SDC9, SDC10, SDC11, and SDC12 may be connected to a first wiring layer which is disposed inside the second interlayer insulating layer 120; however, the present disclosure is not necessarily limited thereto. The first wiring layer may include first to eighth connection wiring lines L1, L2, L3, L4, L5, L6, L7, and L8. The first to eighth connection wiring lines L1, L2, L3, L4, L5, L6, L7, and L8 may be disposed so as to each extend in the second direction DR2 and be spaced apart in the first direction DR1. The second connection wiring line L2, the fifth connection wiring line L5, the fourth connection wiring line L4, and the seventh DR1. The first connection wiring line L1 and the third connection wiring line L3 may be positioned substantially at the same position as that of the second connection wiring line L2 in the first direction DR1. The first connection wiring line L1, the second connection wiring line L2, and the third connection wiring line L3 may be disposed on the same extension line along the second direction DR2. The sixth connection wiring line L6 and the eighth connection wiring line L8 may be positioned substantially at the same position as that of the seventh connection wiring line L7 in the first direction DR1. The sixth connection wiring line L6, the seventh connection wiring line L7, and the eighth connection wiring line L8 may be disposed on the same extension line along the second direction DR2. The fourth connection wiring line L4 and the fifth connection wiring line L5 may include portions curved in the first direction DR1.

The sixth source drain contact SDC6 may be connected to the source region PAX1s of the first additional transistor PAX1. The third source drain contact SDC3 may be connected to the drain region NAX1d of the first pass gate transistor NAX1. The sixth source drain contact SDC6 and the third source drain contact SDC3 may be connected to the sixth connection wiring line L6. The source region PAX1s of the first additional transistor PAX1 and the drain region NAX1d of the first pass gate transistor NAX1 may be electrically connected by the sixth source drain contact SDC6, the third source drain contact SDC3, and the sixth connection wiring line L6.

The fifth source drain contact SDC5 may be connected to the drain region PAX1d of the first additional transistor PAX1 and the drain region PPU1d of the first pull-up transistor PPU1. The second source drain contact SDC2 may be connected to the source region NAX1s of the first pass gate transistor NAX1 and the drain region NPD1d of the first pull-down transistor NPD1. The fifth source drain contact SDC5 and the second source drain contact SDC2 may be connected to the fourth connection wiring line L4. The drain region PAX1d of the first additional transistor PAX1, the drain region PPU1d of the first pull-up transistor PPU1, the source region NAX1s of the first pass gate transistor NAX1, and the drain region NPD1d of the first pull-down transistor NPD1 may be electrically connected by the fifth source drain contact SDC5, the second source drain contact SDC2, and the fourth connection wiring line L4.

The fourth source drain contact SDC4 may be connected to the source region PPU1s of the first pull-up transistor PPU1. The fourth source drain contact SDC4 may be connected to the second connection wiring line L2.

The ninth source drain contact SDC9 may be connected to the source region PPU2s of the second pull-up transistor PPU2. The ninth source drain contact SDC9 may be connected to the seventh connection wiring line L7.

The seventh source drain contact SDC7 may be connected to the source region PAX2s of the second additional transistor PAX2. The tenth source drain contact SDC10 may be connected to the drain region NAX2d of the second pass gate transistor NAX2. The seventh source drain contact SDC7 and the tenth source drain contact SDC10 may be connected to the third connection wiring line L3. The source region PAX2s of the second additional transistor PAX2 and the drain region NAX2d of the second pass gate transistor NAX2 may be electrically connected by the seventh source drain contact SDC7, the tenth source drain contact SDC10, and the third connection wiring line L3.

The eighth source drain contact SDC8 may be connected to the drain region PAX2d of the second additional transistor PAX2 and the drain region PPU2d of the second pull-up transistor PPU2. The eleventh source drain contact SDC11 may be connected to the source region NAX2s of the second pass gate transistor NAX2 and the drain region NPD2d of the second pull-down transistor NPD2. The eighth source drain contact SDC8 and the eleventh source drain contact SDC11 may be connected to the fifth connection wiring line L5. The drain region PAX2d of the second additional transistor PAX2, the drain region PPU2d of the second pull-up transistor PPU2, the source region NAX2s of the second pass gate transistor NAX2, and the drain region NPD2d of the second pull-down transistor NPD2 may be electrically connected by the eighth source drain contact SDC8, the eleventh source drain contact SDC11, and the fifth connection wiring line L5.

The first source drain contact SDC1 may be connected to the source region NPD1s of the first pull-down transistor NPD1. The first source drain contact SDC1 may be connected to the first connection wiring line L1.

The twelfth source drain contact SDC12 may be connected to the source region NPD2s of the second pull-down transistor NPD2. The twelfth source drain contact SDC12 may be connected to the eighth connection wiring line L8.

Gate contacts GC1, GC2, GC3, GC4, GC5, and GC6 may pass through the second interlayer insulating layer 120 and the first interlayer insulating layer 110 and be connected to the gate electrodes GE. The first gate contact GC1 and the sixth gate contact GC6 may be connected to the first wiring layer which is disposed inside the second interlayer insulating layer 120, and the second to fifth gate contacts GC2, GC3, GC4, and GC5 may be connected to the second wiring layer which is disposed inside the third interlayer insulating layer 130; however, the present disclosure is not necessarily limited thereto. For example, the second wiring layer may include ninth to eleventh connection wiring lines L9, L10, L11, and L12, the bit line BL, the complementary bit line BLB, the first power line VDD, and the second power line VSS. Although it is shown in FIGS. 32 to 40 that two second power lines VSS are disposed for one memory cell, the present disclosure is not necessarily limited thereto. The numbers of first power lines VDD and second power lines VSS which are connected to one memory cell may be variously changed.

The ninth to twelfth connection wiring lines L9, L10, L11, and L12, the bit line BL, the complementary bit line BLB, the first power line VDD, and the second power line VSS may be disposed so as to each extend in the first direction DR1 and be spaced apart in the second direction DR2. For example, the ninth connection wiring line L9, a second power line VSS, the bit line BL, the tenth connection wiring line L10, a first power line VDD, the eleventh connection wiring line L11, the complementary bit line BLB, another second power line VSS, and the twelfth connection wiring line L12 may be sequentially disposed along the second direction DR2; however, the exemplary embodiment is not necessarily limited thereto. The arrangement order of the wiring lines in the second wiring layer may be variously changed.

In an exemplary embodiment, the ninth to twelfth connection wiring lines L9, L10, L11, and L12, the bit line BL, the complementary bit line BLB, the first power line VDD, and the second power line VSS may be positioned in the same layer; however, the exemplary embodiment is not limited thereto. At least some of the ninth to twelfth connection wiring lines L9, L10, L11, and L12, the bit line BL, the complementary bit line BLB, the first power line VDD, and the second power line VSS may be positioned in different layers. For example, the ninth to twelfth connection wiring lines L9, L10, L11, and L12 may be positioned in a layer different from that of the bit line BL, the complementary bit line BLB, the first power line VDD, and the second power line VSS. As another example, the first power line VDD and the second power line VSS may be positioned in a layer different from that of the bit line BL and the complementary bit line BLB.

The fifth gate contact GC5 may be connected to the gate electrode PAX1g of the first additional transistor PAX1. The fifth gate contact GC5 may be connected to the tenth connection wiring line L10. The second gate contact GC2 may be connected to the gate electrode PAX2g of the second additional transistor PAX2. The second gate contact GC2 may be connected to the eleventh connection wiring line L11.

The fourth gate contact GC4 may be connected to the gate electrode NAX1g of the first pass gate transistor NAX1. The fourth gate contact GC4 may be connected to the ninth connection wiring line L9. The third gate contact GC3 may be connected to the gate electrode NAX2g of the second pass gate transistor NAX2. The third gate contact GC3 may be connected to the twelfth connection wiring line L12.

The first gate contact GC1 may be connected to the gate electrode PPU1g of the first pull-up transistor PPU1 and the gate electrode NPD1g of the first pull-down transistor NPD1. The first gate contact GC1 may be connected to the fifth connection wiring line L5. The gate electrode PPU1g of the first pull-up transistor PPU1 and the gate electrode NPD1g of the first pull-down transistor NPD1 may be electrically connected to the drain region PAX2d of the second additional transistor PAX2 and the source region NAX2s of the second pass gate transistor NAX2 by the first gate contact GC1, the eighth source drain contact SDC8, the eleventh source drain contact SDC11, and the fifth connection wiring line L5.

The sixth gate contact GC6 may be connected to the gate electrode PPU2g of the second pull-up transistor PPU2 and the gate electrode NPD2g of the second pull-down transistor NPD2. The sixth gate contact GC6 may be connected to the fourth connection wiring line L4. The gate electrode PPU2g of the second pull-up transistor PPU2 and the gate electrode NPD2g of the second pull-down transistor NPD2 may be electrically connected to the drain region PAX1d of the first additional transistor PAX1 and the source region NAX1s of the first pass gate transistor NAX1 by the sixth gate contact GC6, the fifth source drain contact SDC5, the second source drain contact SDC2, and the fourth connection wiring line L4.

Inside the fourth interlayer insulating layer 140, a third wiring layer may be disposed. The third wiring layer may include the word line WL and the complementary word line WLB

The word line WL and the complementary word line WLB may be disposed so as to each extend in the second direction DR2 and be spaced apart in the first direction DR1. For example, the word line WL and the complementary word line WLB may be positioned at the edge of the memory cell; however, the exemplary embodiment is not necessarily limited thereto.

In an exemplary embodiment, the word line WL and the complementary word line WLB may be positioned in a higher layer (a wiring layer farther from the upper surface of the substrate 100) than the bit line BL and the complementary bit line BLB; however, the exemplary embodiment is not limited thereto. The bit line BL and the complementary bit line BLB may be positioned in a higher layer than the word line WL and the complementary word line WLB.

Vias LV1, LV2, LV3, LV4, LV5, LV6, LV7, LV8, LV9, and LV10 may connect the first wiring layer, the second wiring layer, and the third wiring layer. The first via LV1, the fifth via LV5, the seventh via LV7, and the ninth via LV9 may pass through the third interlayer insulating layer 130 and connect the second wiring layer and the third wiring layer. The second via LV2, the third via LV3, the fourth via LV4, the sixth via LV6, the eighth via LV8, and the tenth via LV10 LV7 may pass through the second interlayer insulating layer 120 and connect the first wiring layer and the second wiring layer.

The first via LV1 may connect the word line WL and the ninth connection wiring line L9. In other words, the gate electrode NAX1g of the first pass gate transistor NAX1 may be electrically connected to the word line WL by the fourth gate contact GC4, the ninth connection wiring line L9, and the first via LV1.

The fifth via LV5 may connect the word line WL and the twelfth connection wiring line L12. In other words, the gate electrode NAX2g of the second pass gate transistor NAX2 may be electrically connected to the word line WL by the third gate contact GC3, the twelfth connection wiring line L12, and the fifth via LV5.

The seventh via LV7 may connect the complementary word line WLB and the tenth connection wiring line L10. In other words, the gate electrode PAX1g of the first additional transistor PAX1 may be electrically connected to the complementary word line WLB by the fifth gate contact GC5, the tenth connection wiring line L10, and the seventh via LV7.

The ninth via LV9 may connect the complementary word line WLB and the eleventh connection wiring line L11. In other words, the gate electrode PAX2g of the second additional transistor PAX2 may be electrically connected to the complementary word line WLB by the second gate contact GC2, the eleventh connection wiring line L11, and the ninth via LV9.

The sixth via LV6 may connect the bit line BL and the sixth connection wiring line L6. In other words, the source region PAX1s of the first additional transistor PAX1 and the drain region NAX1d of the first pass gate transistor NAX1 may be electrically connected to the bit line BL by the sixth source drain contact SDC6, the third source drain contact SDC3, the sixth connection wiring line L6, and the sixth via LV6.

The fourth via LV4 may connect the complementary bit line BLB and the third connection wiring line L3. In other words, the source region PAX2s of the second additional transistor PAX2 and the drain region NAX2d of the second pass gate transistor NAX2 may be electrically connected to the complementary bit line BLB by the seventh source drain contact SDC7, the tenth source drain contact SDC10, the third connection wiring line L3, and the fourth via LV4.

The third via LV3 may connect the first power line VDD and the second connection wiring line L2. In other words, the source region PPU1s of the first pull-up transistor PPU1 may be electrically connected to the first power line VDD by the fourth source drain contact SDC4, the second connection wiring line L2, and the third via LV3.

The eighth via LV8 may connect the first power line VDD and the seventh connection wiring line L7. In other words, the source region PPU2s of the second pull-up transistor PPU2 may be electrically connected to the first power line VDD by the ninth source drain contact SDC9, the seventh via LV7, and the eighth via LV8.

The second via LV2 may connect the second power line VSS and the first connection wiring line L1. In other words, the source region NPD1s of the first pull-down transistor NPD1 may be electrically connected to the second power line VSS by the first source drain contact SDC1, the first connection wiring line L1, and the second via LV2.

The tenth via LV10 may connect the second power line VSS and the eighth connection wiring line L8. In other words, the source region NPD2s of the second pull-down transistor NPD2 may be electrically connected to the second power line VSS by the twelfth source drain contact SDC12, the eighth connection wiring line L8, and the tenth via LV10.

The semiconductor device according to the exemplary embodiment may include the first additional transistor PAX1 and the second additional transistor PAX2 that are disposed on one side of each of the first pull-up transistor PPU1 and the second pull-up transistor PPU2 so as to face the first pass gate transistor NAX1 and the second pass gate transistor NAX2, respectively. A memory cell of the semiconductor device according to an exemplary embodiment may be an SRAM cell which consists of eight transistors by adding two pass gate transistors to an SRAM cell which is implemented with six transistors. Each of the first additional transistor PAX1 and the second additional transistor PAX2 of the semiconductor device according to the exemplary embodiment may serve as a pass gate transistor along with each of the first pass gate transistor NAX1 and the second pass gate transistor NAX2. According to the exemplary embodiment, it is possible to improve the read and write performance without increasing the area as compared to an SRAM cell which is implemented with six transistors.

Hereinafter, the relationship of a plurality of memory cells adjacent in the first direction DR1 of the semiconductor device accuracy of the exemplary embodiment will be described with reference to FIG. 41 together.

Referring to FIG. 41, the semiconductor device according to the exemplary embodiment may include a first memory cell C1, a second memory cell C2, and a third memory cell C3 which are disposed along the first direction DR1. The first memory cell C1, the second memory cell C2, and the third memory cell C3 may be disposed on a single first active region PACT1, a single second active region NACT1, a single third active region PACT2, and a single fourth active region NACT2. In respect to each of the first memory cell C1, the second memory cell C2, and the third memory cell C3, the contents of the memory cell described above with reference to FIGS. 32 to 40 may be equally applied. Each of the first memory cell C1, the second memory cell C2, and the third memory cell C3 may include a first pull-up transistor PPU1, a first pull-down transistor NPD1, a second pull-up transistor PPU2, a second pull-down transistor NPD2, a first pass gate transistor NAX1, a second pass gate transistor NAX2, a first additional transistor PAX1, and a second additional transistor PAX2.

The first memory cell C1 may be adjacent to the second memory cell C2 in the first direction DR1, and the second memory cell C2 may be adjacent to the third memory cell C3 in the first direction DR1. According to the exemplary embodiment, transistors constituting a plurality of memory cells adjacent in the first direction DR1 may be symmetrically disposed. In other words, the transistors of the first memory cell C1 and the transistors of the second memory cell C2 may be symmetrically disposed, and the transistors of the second memory cell C2 and the transistors of the third memory cell C3 may be symmetrically disposed.

The transistors which are disposed at both ends of each memory cell in the first direction DR1 may share a source/drain region with a transistor which is included in another memory cell adjacent thereto in the first direction DR1 and performs the same function.

According to the exemplary embodiment, the first additional transistor PAX1 of the first memory cell C1 and the first additional transistor PAX1 of the second memory cell C2 may share a source region PAX1s. The second additional transistor PAX2 of the second memory cell C2 and the second additional transistor PAX2 of the third memory cell C3 may share a source region PAX2s.

According to the exemplary embodiment, the first pass gate transistor NAX1 of the first memory cell C1 and the first pass gate transistor NAX1 of the second memory cell C2 may share a drain region NAX1d. The second pass gate transistor NAX2 of the second memory cell C2 and the second pass gate transistor NAX2 of the third memory cell C3 may share a drain region NAX2d.

According to the exemplary embodiment, the second pull-up transistor PPU2 of the first memory cell C1 and the second pull-up transistor PPU2 of the second memory cell C2 may share a source region PPU2s. The first pull-up transistor PPU1 of the second memory cell C2 and the first pull-up transistor PPU1 of the third memory cell C3 may share a source region PPU1s.

According to the exemplary embodiment, the second pull-down transistor NPD2 of the first memory cell C1 and the second pull-down transistor NPD2 of the second memory cell C2 may share a source region NPD2s. The first pull-down transistor NPD1 of the second memory cell C2 and the first pull-down transistor NPD1 of the third memory cell C3 may share a source region NPD1s.

According to the exemplary embodiment, the source region PAX1s of the first additional transistor PAX1 and the drain region NAX1d of the first pass gate transistor NAX1 of each memory cell may be connected to the bit line BL. The source region PAX2s of the second additional transistor PAX2 and the drain region NAX2d of the second pass gate transistor NAX2 may be connected to the complementary bit line BLB.

The second memory cell C2 may share the connection relationship of the source region PAX1s of the first additional transistor PAX1 and the drain region NAX1d of the first pass gate transistor NAX1 with the first memory cell C1. In other words, the second memory cell C2 may share the sixth source drain contact SDC6 that is connected to the source region PAX1s of the first additional transistor PAX1, the third source drain contact SDC3 that is connected to the drain region NAX1d of the first pass gate transistor NAX1, the sixth connection wiring line L6 that connects the sixth source drain contact SDC6 and the third source drain contact SDC3, and the sixth via LV6 that connects the sixth connection wiring line L6 and the bit line BL, with the first memory cell C1.

The second memory cell C2 may share the connection relationship of the source region PAX2s of the second additional transistor PAX2 and the drain region NAX2d of the second pass gate transistor NAX2 with the third memory cell C3. In other words, the second memory cell C2 may share the seventh source drain contact SDC7 that is connected to the source region PAX2s of the second additional transistor PAX2, the tenth source drain contact SDC10 that is connected to the drain region NAX2d of the second pass gate transistor NAX2, the third connection wiring line L3 that connects the seventh source drain contact SDC7 and the tenth source drain contact SDC10, and the fourth via LV4 that connects the third connection wiring line L3 and the complementary bit line BLB, with the third memory cell C3.

The second memory cell C2 may share the connection relationship of the source region PPU2s of the second pull-up transistor PPU2 with the first memory cell C1. In other words, the second memory cell C2 may share the ninth source drain contact SDC9 that is connected to the source region PPU2s of the second pull-up transistor PPU2, the seventh connection wiring line L7 to which the ninth source drain contact SDC9 is connected, and the eighth via LV8 that connects the seventh connection wiring line L7 and the first power line VDD, with the first memory cell C1.

The second memory cell C2 may share the connection relationship of the source region NPD2s of the second pull-down transistor NPD2 with the first memory cell C1. In other words, the second memory cell C2 may share the twelfth source drain contact SDC12 that is connected to the source region NPD2s of the second pull-down transistor NPD2, the eighth connection wiring line L8 to which the twelfth source drain contact SDC12 is connected, and the tenth via LV10 that connects the eighth connection wiring line L8 and the second power line VSS, with the first memory cell C1.

The second memory cell C2 may share the connection relationship of the source region PPU1s of the first pull-up transistor PPU1 with the third memory cell C3. In other words, the second memory cell C2 may share the fourth source drain contact SDC4 that is connected to the source region PPU1s of the first pull-up transistor PPU1, the second connection wiring line L2 to which the fourth source drain contact SDC4 is connected, and the third via LV3 that connects the second connection wiring line L2 and the first power line VDD, with the third memory cell C3.

The second memory cell C2 may share the connection relationship of the source region NPD1s of the first pull-down transistor NPD1 with the third memory cell C3. In other words, the second memory cell C2 may share the first source drain contact SDC1 that is connected to the source region NPD1s of the first pull-down transistor NPD1, the first connection wiring line L1 to which the first source drain contact SDC1 is connected, and the second via LV2 that connects the first connection wiring line L1 and the second power line VSS, with the third memory cell C3.

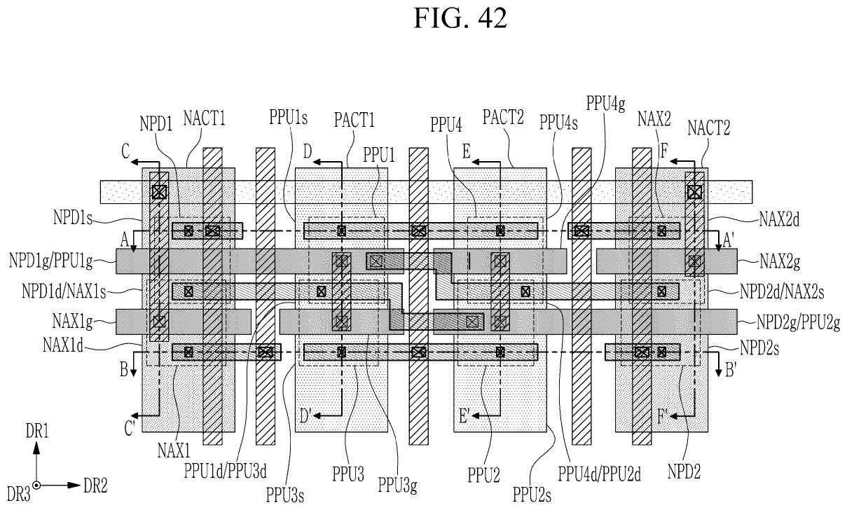

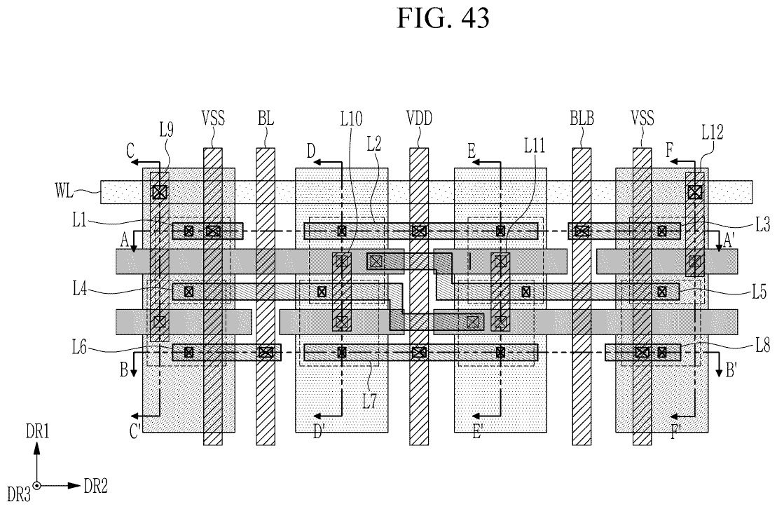

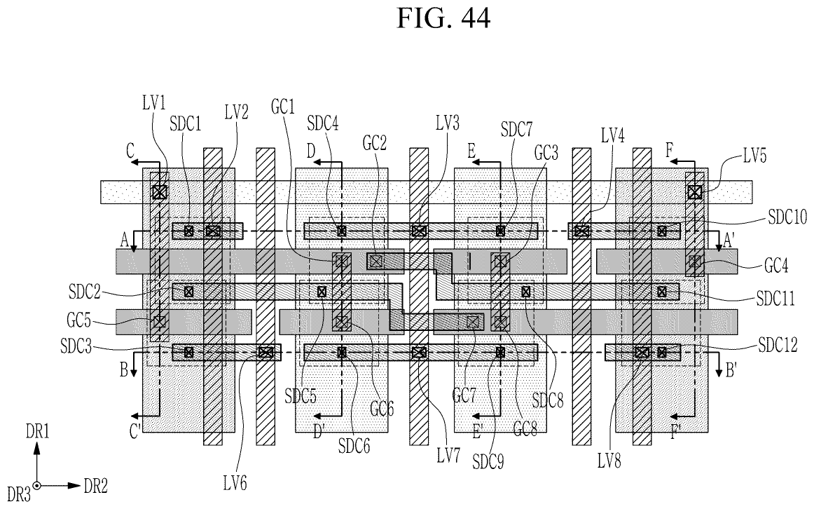

Hereinafter, a semiconductor device according to an exemplary embodiment will be described with reference to FIGS. 42 to 51. A memory cell array of the semiconductor device according to FIGS. 42 to 51 may be identical to that shown in FIG. 31.

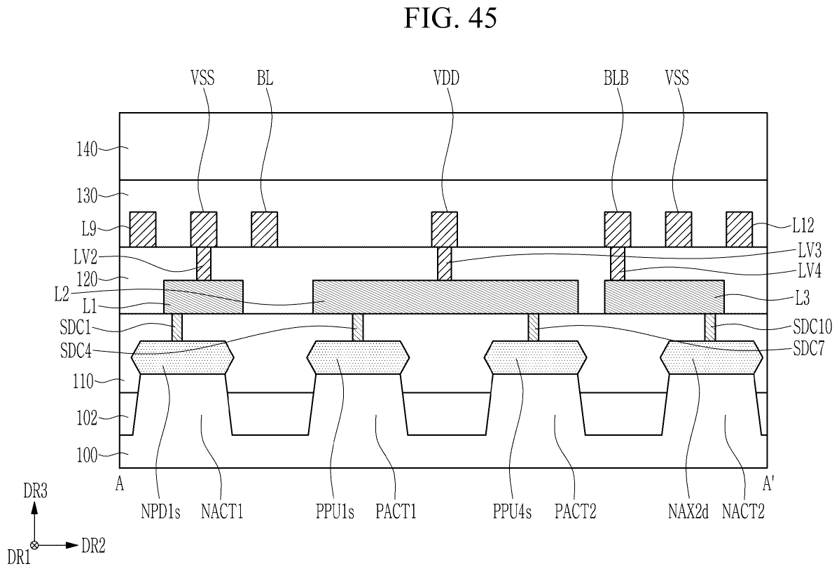

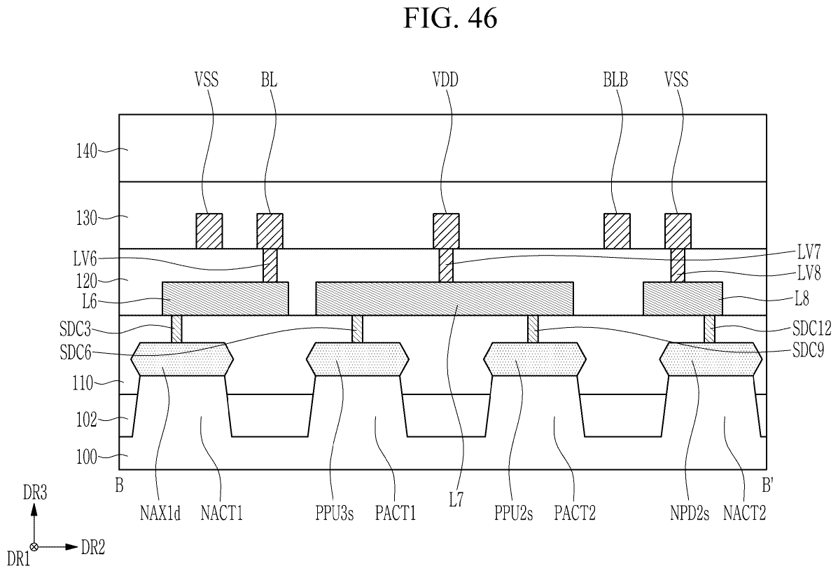

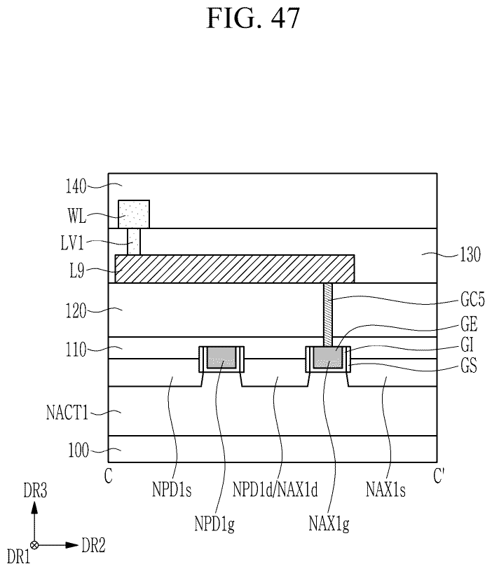

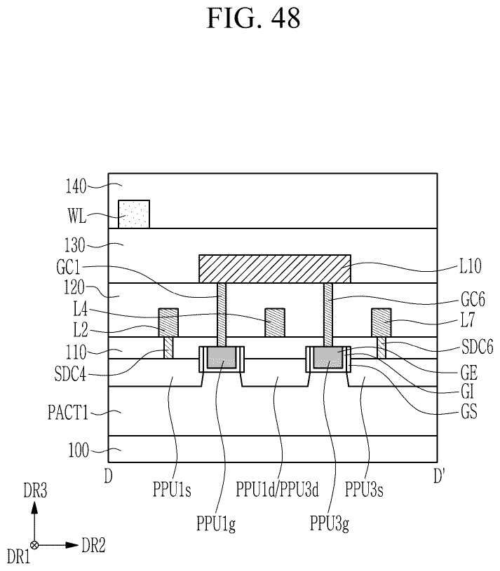

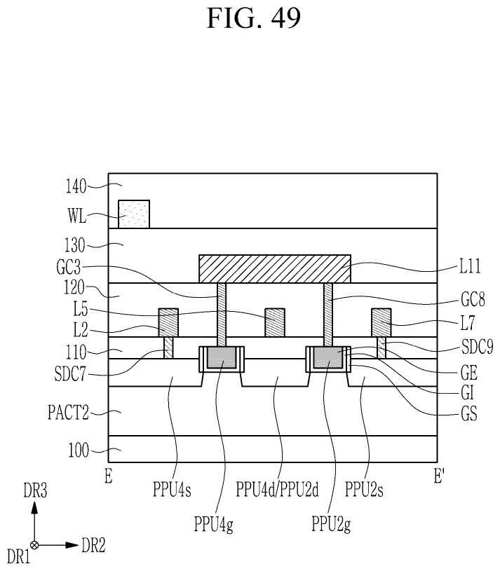

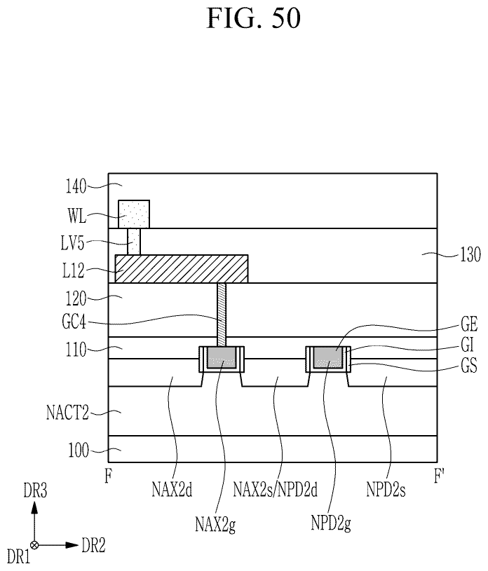

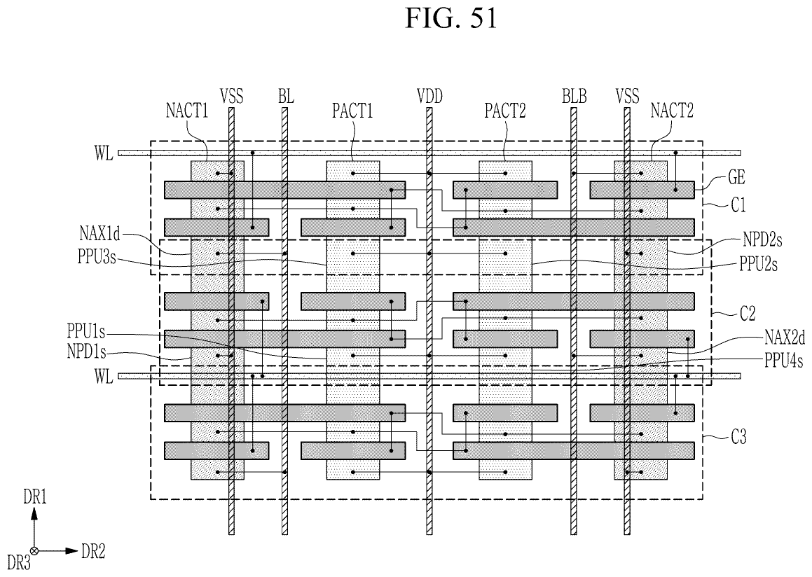

FIGS. 42 to 44 are plan layout diagrams of a memory cell of the semiconductor device according to the exemplary embodiment. FIG. 45 is a cross-sectional view taken along line A-A′ of FIGS. 42 to 44. FIG. 46 is a cross-sectional view taken along line B-B′ of FIGS. 42 to 44. FIG. 47 is a cross-sectional view taken along line C-C′ of FIGS. 42 to 44. FIG. 48 is a cross-sectional view taken along line D-D′ of FIGS. 42 to 44. FIG. 49 is a cross-sectional view taken along line E-E′ of FIGS. 42 to 44. FIG. 50 is a cross-sectional view taken along line F-F′ of FIGS. 42 to 44. FIG. 51 is a view schematically illustrating a plurality of memory cells of the semiconductor device according to the exemplary embodiment.

Hereinafter, differences from the semiconductor device according to FIGS. 31 to 41 will be mainly described, and a redundant description will not be made or will be made in brief.

The circuit of each of the plurality of memory cells MC of the semiconductor device according to FIGS. 42 to 51 may be identical to that shown in FIG. 11. Each of the plurality of memory cells MC of the semiconductor device according to the exemplary embodiment may be an SRAM cell which is implemented with eight transistors. Each of the plurality of memory cells MC may include a first pull-up transistor PPU1, a first pull-down transistor NPD1, a second pull-up transistor PPU2, a second pull-down transistor NPD2, a first pass gate transistor NAX1, a second pass gate transistor NAX2, a first additional transistor PPU3, and a second additional transistor PPU4.

The first pull-up transistor PPU1 and the second pull-up transistor PPU2 may be p-type transistors. The first pull-down transistor NPD1 and the second pull-down transistor NPD2 may be n-type transistors. According to an exemplary embodiment, the first pass gate transistor NAX1 and the second pass gate transistor NAX2 may be n-type transistors, and the first additional transistor PPU3 and the second additional transistor PPU4 may be p-type transistors.

Hereinafter, the arrangement and connection relationship of eight transistors constituting each of the plurality of memory cells MC will be described with reference to FIGS. 42 to 50.

Referring to FIGS. 42 to 50, the arrangement of the first pull-up transistor PPU1, the first pull-down transistor NPD1, the second pull-up transistor PPU2, the second pull-down transistor NPD2, the first pass gate transistor NAX1, the second pass gate transistor NAX2, the first additional transistor PPU3, and the second additional transistor PPU4 may be identical to that in the exemplary embodiment of FIGS. 31 to 41.

Source drain contacts SDC1, SDC2, SDC3, SDC4, SDC5, SDC6, SDC7, SDC8, SDC9, SDC10, SDC11, and SDC12 may pass through the first interlayer insulating layer 110 and be connected to the source/drain regions. The source drain contacts SDC1, SDC2, SDC3, SDC4, SDC5, SDC6, SDC7, SDC8, SDC9, SDC10, SDC11, and SDC12 may be connected to a first wiring layer which is disposed inside the second interlayer insulating layer 120; however, the present disclosure is not necessarily limited thereto. The first wiring layer may include first to eighth connection wiring lines L1, L2, L3, L4, L5, L6, L7, and L8. The first to eighth connection wiring lines L1, L2, L3, L4, L5, L6, L7, and L8 may be disposed so as to each extend in the second direction DR2 and be spaced apart in the first direction DR1. The second connection wiring line L2, the fifth connection wiring line L5, the fourth connection wiring line L4, and the seventh DR1. The first connection wiring line L1 and the third connection wiring line L3 may be positioned substantially at the same position as that of the second connection wiring line L2 in the first direction DR1. The first connection wiring line L1, the second connection wiring line L2, and the third connection wiring line L3 may be disposed on the same extension line along the second direction DR2. The sixth connection wiring line L6 and the eighth connection wiring line L8 may be positioned substantially at the same position as that of the seventh connection wiring line L7 in the first direction DR1. The sixth connection wiring line L6, the seventh connection wiring line L7, and the eighth connection wiring line L8 may be disposed on the same extension line along the second direction DR2. The fourth connection wiring line L4 and the fifth connection wiring line L5 may include portions curved in the first direction DR1.

The sixth source drain contact SDC6 may be connected to the source region PPU3s of the first additional transistor PPU3. The ninth source drain contact SDC9 may be connected to the source region PPU2s of the second pull-up transistor PPU2. The sixth source drain contact SDC6 and the ninth source drain contact SDC9 may be connected to the seventh connection wiring line L7. The source region PPU3s of the first additional transistor PPU3 and the source region PPU2s of the second pull-up transistor PPU2 may be electrically connected by the sixth source drain contact SDC6, the ninth source drain contact SDC9, and the seventh connection wiring line L7.

The fifth source drain contact SDC5 may be connected to the drain region PPU3d of the first additional transistor PPU3 and the drain region PPU1d of the first pull-up transistor PPU1. The second source drain contact SDC2 may be connected to the source region NAX1s of the first pass gate transistor NAX1 and the drain region NPD1d of the first pull-down transistor NPD1. The fifth source drain contact SDC5 and the second source drain contact SDC2 may be connected to the fourth connection wiring line L4. The drain region PPU3d of the first additional transistor PPU3, the drain region PPU1d of the first pull-up transistor PPU1, the source region NAX1s of the first pass gate transistor NAX1, and the drain region NPD1d of the first pull-down transistor NPD1 may be electrically connected by the fifth source drain contact SDC5, the second source drain contact SDC2, and the fourth connection wiring line L4.

The fourth source drain contact SDC4 may be connected to the source region PPU1s of the first pull-up transistor PPU1. The seventh source drain contact SDC7 may be connected to the source region PPU4s of the second additional transistor PPU4. The fourth source drain contact SDC4 and the seventh source drain contact SDC7 may be connected to the second connection wiring line L2. The source region PPU1s of the first pull-up transistor PPU1 and the source region PPU4s of the second additional transistor PPU4 may be electrically connected by the fourth source drain contact SDC4, the seventh source drain contact SDC7, and the second connection wiring line L2.

The first source drain contact SDC1 may be connected to the source region NPD1s of the first pull-down transistor NPD1. The first source drain contact SDC1 may be connected to the first connection wiring line L1.

The twelfth source drain contact SDC12 may be connected to the source region NPD2s of the second pull-down transistor NPD2. The twelfth source drain contact SDC12 may be connected to the eighth connection wiring line L8.

The eighth source drain contact SDC8 may be connected to the drain region PPU2d of the second pull-up transistor PPU2 and the drain region PPU4d of the second additional transistor PPU4. The eleventh source drain contact SDC11 may be connected to the drain region NPD2d of the second pull-down transistor NPD2 and the source region NAX2s of the second pass gate transistor NAX2. The eighth source drain contact SDC8 and the eleventh source drain contact SDC11 may be connected to the fifth connection wiring line L5. The drain region PPU2d of the second pull-up transistor PPU2, the drain region PPU4d of the second additional transistor PPU4, the drain region NPD2d of the second pull-down transistor NPD2, and the source region NAX2s of the second pass gate transistor NAX2 may be electrically connected by the eighth source drain contact SDC8, the eleventh source drain contact SDC11, and the fifth connection wiring line L5.

The third source drain contact SDC3 may be connected to the drain region NAX2d of the first pass gate transistor NAX1. The third source drain contact SDC3 may be connected to the sixth connection wiring line L6.

The tenth source drain contact SDC10 may be connected to the drain region NAX2d of the second pass gate transistor NAX2. The tenth source drain contact SDC10 may be connected to the third connection wiring line L3. Gate contacts GC1, GC2, GC3, GC4, GC5, GC6, GC7, and GC8 may pass through the second interlayer insulating layer 120 and the first interlayer insulating layer 110 and be connected to the gate electrodes GE. The second gate contact GC2 and the seventh gate contact GC7 may be connected to the first wiring layer which is disposed inside the second interlayer insulating layer 120, and the first gate contact GC1, the third gate contact GC3, the fourth gate contact GC4, the fifth gate contact GC5, the sixth gate contact GC6, and the eighth gate contact GC8 may be connected to a second wiring layer which is disposed inside the third interlayer insulating layer 130; however, the present disclosure is not necessarily limited thereto. For example, the second wiring layer may include ninth to twelfth connection wiring lines L9, L10, L11, and L12, the bit line BL, the complementary bit line BLB, the first power line VDD, and the second power line VSS. The ninth to twelfth connection wiring lines L9, L10, L11, and L12, the bit line BL, the complementary bit line BLB, the first power line VDD, and the second power line VSS may be disposed so as to each extend in the first direction DR1 and be spaced apart in the second direction DR2. For example, the ninth connection wiring line L9, a second power line VSS, the bit line BL, the tenth connection wiring line L10, a first power line VDD, the eleventh connection wiring line L11, the complementary bit line BLB, another second power line VSS, and the twelfth connection wiring line L12 L10 may be sequentially disposed along the second direction DR2; however, the exemplary embodiment is not necessarily limited thereto. The arrangement order of the wiring lines in the second wiring layer may be variously changed.

The sixth gate contact GC6 may be connected to the gate electrode PPU3g of the first additional transistor PPU3. The first gate contact GC1 may be connected to the gate electrode PPU1g of the first pull-up transistor PPU1 and the gate electrode NPD1g of the first pull-down transistor NPD1. The sixth gate contact GC6 and the first gate contact GC1 may be connected to the tenth connection wiring line L10. The gate electrode PPU3g of the first additional transistor PPU3 may be connected to the gate electrode PPU1g of the first pull-up transistor PPU1 and the gate electrode NPD1g of the first pull-down transistor NPD1 by the sixth gate contact GC6, the first gate contact GC1, and the tenth connection wiring line L10.

The third gate contact GC3 may be connected to the gate electrode PPU4g of the second additional transistor PPU4. The eighth gate contact GC8 may be connected to the gate electrode PPU2g of the second pull-up transistor PPU2 and the gate electrode NPD2g of the second pull-down transistor NPD2. The third gate contact GC3 and the eighth gate contact GC8 may be connected to the eleventh connection wiring line L11. The gate electrode PPU4g of the second additional transistor PPU4 may be electrically connected to the gate electrode PPU2g of the second pull-up transistor PPU2 and the gate electrode NPD2g of the second pull-down transistor NPD2 by the third gate contact GC3, the eighth gate contact GC8, and the eleventh connection wiring line L11.

The fifth gate contact GC5 may be connected to the gate electrode NAX1g of the first pass gate transistor NAX1. The fifth gate contact GC5 may be connected to the ninth connection wiring line L9. The fourth gate contact GC4 may be connected to the gate electrode NAX2g of the second pass gate transistor NAX2. The fourth gate contact GC4 may be connected to the twelfth connection wiring line L12.

The second gate contact GC2 may be connected to the gate electrode PPU1g of the first pull-up transistor PPU1 and the gate electrode NPD1g of the first pull-down transistor NPD1. The second gate contact GC2 may be connected to the fifth connection wiring line L5. The gate electrode PPU1g of the first pull-up transistor PPU1 and the gate electrode NPD1g of the first pull-down transistor NPD1 may be electrically connected to the drain region PPU4d of the second additional transistor PPU4 and the source region NAX2s of the second pass gate transistor NAX2 by the second gate contact GC2, the eighth source drain contact SDC8, the eleventh source drain contact SDC11, and the fifth connection wiring line L5.

The seventh gate contact GC7 may be connected to the gate electrode PPU2g of the second pull-up transistor PPU2 and the gate electrode NPD2g of the second pull-down transistor NPD2. The seventh gate contact GC7 may be connected to the fourth connection wiring line L4. The gate electrode PPU2g of the second pull-up transistor PPU2 and the gate electrode NPD2g of the second pull-down transistor NPD2 may be electrically connected to the drain region PPU3d of the first additional transistor PPU3 and the source region NAX1s of the first pass gate transistor NAX1 by the seventh gate contact GC7, the fifth source drain contact SDC5, the second source drain contact SDC2, and the fourth connection wiring line L4.

The third wiring layer which is disposed inside the fourth interlayer insulating layer 140 may include the word line WL. For example, the word line WL may be positioned at the edge of the memory cell; however, the exemplary embodiment is not limited thereto. Unlike in the exemplary embodiment of FIGS. 31 to 41, the complementary word line WLB may be omitted.

Vias LV1, LV2, LV3, LV4, LV5, LV6, LV7, and LV8 may connect the first wiring layer, the second wiring layer, and the third wiring layer. The first via LV1 and the fifth via LV5 may pass through the third interlayer insulating layer 130 and connect the second wiring layer and the third wiring layer. The second via LV2, the third via LV3, the fourth via LV4, the sixth via LV6, the seventh via LV7, and the eighth via LV8 may pass through the second interlayer insulating layer 120 and connect the first wiring layer and the second wiring layer.

The first via LV1 may connect the word line WL and the ninth connection wiring line L9. In other words, the gate electrode NAX1g of the first pass gate transistor NAX1 may be electrically connected to the word line WL by the fifth gate contact GC5, the ninth connection wiring line L9, and the first via LV1.

The fifth via LV5 may connect the word line WL and the eleventh connection wiring line L11. In other words, the gate electrode NAX2g of the second pass gate transistor NAX2 may be electrically connected to the word line WL by the fourth gate contact GC4, the twelfth connection wiring line L12, and the fifth via LV5.

The sixth via LV6 may connect the bit line BL and the sixth connection wiring line L6. In other words, the drain region NAX1d of the first pass gate transistor NAX1 may be electrically connected to the bit line BL by the third source drain contact SDC3, the sixth connection wiring line L6, and the sixth via LV6.

The fourth via LV4 may connect the complementary bit line BLB and the third connection wiring line L3. In other words, the drain region NAX2d of the second pass gate transistor NAX2 may be electrically connected to the complementary bit line BLB by the tenth source drain contact SDC10, the third connection wiring line L3, and the fourth via LV4.

The third via LV3 may connect the first power line VDD and the second connection wiring line L2. In other words, the source region PPU1s of the first pull-up transistor PPU1 and the source region PPU4s of the second additional transistor PPU4 may be electrically connected to the first power line VDD by the fourth source drain contact SDC4, the seventh source drain contact SDC7, the second connection wiring line L2, and the third via LV3.

The seventh via LV7 may connect the first power line VDD and the seventh connection wiring line L7. In other words, the source region PPU2s of the second pull-up transistor PPU2 and the source region PPU3s of the first additional transistor PPU3 may be electrically connected to the first power line VDD by the ninth source drain contact SDC9, the sixth source drain contact SDC6, the seventh connection wiring line L7, and the seventh via LV7.

The second via LV2 may connect the second power line VSS and the first connection wiring line L1. In other words, the source region NPD1s of the first pull-down transistor NPD1 may be electrically connected to the second power line VSS by the first source drain contact SDC1, the first connection wiring line L1, and the second via LV2.

The eighth via LV8 may connect the second power line VSS and the eighth connection wiring line L8. In other words, the source region NPD2s of the second pull-down transistor NPD2 may be electrically connected to the second power line VSS by the twelfth source drain contact SDC12, the eighth connection wiring line L8, and the eighth via LV8.

Hereinafter, the relationship of a plurality of memory cells adjacent in the first direction DR1 of the semiconductor device accuracy of the exemplary embodiment will be described with reference to FIG. 51 together.

Referring to FIG. 51, the semiconductor device according to the exemplary embodiment may include a first memory cell C1, a second memory cell C2, and a third memory cell C3 which are disposed along the first direction DR1. In respect to each of the first memory cell C1, the second memory cell C2, and the third memory cell C3, the contents of the memory cell described above with reference to FIGS. 42 to 50 may be equally applied. Each of the first memory cell C1, the second memory cell C2, and the third memory cell C3 may include a first pull-up transistor PPU1, a first pull-down transistor NPD1, a second pull-up transistor PPU2, a second pull-down transistor NPD2, a first pass gate transistor NAX1, a second pass gate transistor NAX2, a first additional transistor PPU3, and a second additional transistor PPU4.

The transistors which are disposed at both ends of each memory cell in the first direction DR1 may share a source/drain region with a transistor which is included in another memory cell adjacent thereto in the first direction DR1 and performs the same function.

According to the exemplary embodiment, the first additional transistor PPU3 of the first memory cell C1 and the first additional transistor PPU3 of the second memory cell C2 may share a source region PPU3s. The second additional transistor PPU4 of the second memory cell C2 and the second additional transistor PPU4 of the third memory cell C3 may share a source region PPU4s.

According to the exemplary embodiment, the first pass gate transistor NAX1 of the first memory cell C1 and the first pass gate transistor NAX1 of the second memory cell C2 may share a drain region NAX1d. The second pass gate transistor NAX2 of the second memory cell C2 and the second pass gate transistor NAX2 of the third memory cell C3 may share a drain region NAX2d.

According to the exemplary embodiment, the second pull-up transistor PPU2 of the first memory cell C1 and the second pull-up transistor PPU2 of the second memory cell C2 may share a source region PPU2s. The first pull-up transistor PPU1 of the second memory cell C2 and the first pull-up transistor PPU1 of the third memory cell C3 may share a source region PPU1s.

According to the exemplary embodiment, the second pull-down transistor NPD2 of the first memory cell C1 and the second pull-down transistor NPD2 of the second memory cell C2 may share a source region NPD2s. The first pull-down transistor NPD1 of the second memory cell C2 and the first pull-down transistor NPD1 of the third memory cell C3 may share a source region NPD1s.

According to the exemplary embodiment, the source region PPU3s of the first additional transistor PPU3 and the source region PPU2s of the second pull-up transistor PPU2 of each memory cell may be connected to the first power line VDD. The source region PPU4s of the second additional transistor PPU4 and the source region PPU1s of the first pull-up transistor PPU1 of each memory cell may be connected to the first power line VDD.

The second memory cell C2 may share the connection relationship of the source region PPU3s of the first additional transistor PPU3 and the source region PPU2s of the second pull-up transistor PPU2 with the first memory cell C1. In other words, the second memory cell C2 may share the sixth source drain contact SDC6 that is connected to the source region PPU3s of the first additional transistor PPU3, the ninth source drain contact SDC9 that is connected to the source region PPU2s of the second pull-up transistor PPU2, the seventh connection wiring line L7 that connects the sixth source drain contact SDC6 and the ninth source drain contact SDC9, and the seventh via LV7 that connects the seventh connection wiring line L7 and the first power line VDD, with the first memory cell C1.

The second memory cell C2 may share the connection relationship of the source region PPU4s of the second additional transistor PPU4 and the source region PPU1s of the first pull-up transistor PPU1 with the third memory cell C3. In other words, the second memory cell C2 may share the seventh source drain contact SDC7 that is connected to the source region PPU4s of the second additional transistor PPU4, the fourth source drain contact SDC4 that is connected to the source region PPU1s of the first pull-up transistor PPU1, the second connection wiring line L2 that connects the seventh source drain contact SDC7 and the fourth source drain contact SDC4, and the third via LV3 that connects the second connection wiring line L2 and the first power line VDD, with the third memory cell C3.

The second memory cell C2 may share the connection relationship of the source region NPD2s of the second pull-down transistor NPD2 with the first memory cell C1. In other words, the second memory cell C2 may share the twelfth source drain contact SDC12 that is connected to the source region NPD2s of the second pull-down transistor NPD2, the eighth connection wiring line L8 to which the twelfth source drain contact SDC12 is connected, and the eighth via LV8 that connects the eighth connection wiring line L8 and the second power line VSS, with the first memory cell C1.

The second memory cell C2 may share the connection relationship of the source region NPD1s of the first pull-down transistor NPD1 with the third memory cell C3. In other words, the second memory cell C2 may share the first source drain contact SDC1 that is connected to the source region NPD1s of the first pull-down transistor NPD1, the first connection wiring line L1 to which the first source drain contact SDC1 is connected, and the second via LV2 that connects the first connection wiring line L1 and the second power line VSS, with the third memory cell C3.

The second memory cell C2 may share the connection relationship of the drain region NAX1d of the first pass gate transistor NAX1 with the first memory cell C1. In other words, the second memory cell C2 may share the third source drain contact SDC3 that is connected to the drain region NAX1d of the first pass gate transistor NAX1, the sixth connection wiring line L6 that is connected to the third source drain contact SDC3, and the sixth via LV6 that connects the sixth connection wiring line L6 and the bit line BL, with the first memory cell C1.

The second memory cell C2 may share the connection relationship of the drain region NAX2d of the second pass gate transistor NAX2 with the third memory cell C3. In other words, the second memory cell C2 may share the tenth source drain contact SDC10 that is connected to the drain region NAX2d of the second pass gate transistor NAX2, the third connection wiring line L3 that is connected to the tenth source drain contact SDC10, and the fourth via LV4 that connects the third connection wiring line L3 and the complementary bit line BLB, with the third memory cell C3.

The process of forming the transistors of the semiconductor device according to the exemplary embodiment of FIGS. 42 to 51 may be identical to the process of forming the transistors of the semiconductor device according to the exemplary embodiment of FIGS. 31 to 41. The semiconductor device according to the exemplary embodiment of FIGS. 42 to 51 may be formed by changing etch masks for forming contact holes, via holes, and wiring lines of the semiconductor device according to the exemplary embodiment of FIGS. 31 to 40.

The semiconductor device according to the exemplary embodiment may include the first additional transistor PPU3 and the second additional transistor PPU4 that are disposed on one side of each of the first pull-up transistor PPU1 and the second pull-up transistor PPU2 so as to face the first pass gate transistor NAX1 and the second pass gate transistor NAX2, respectively. A memory cell of the semiconductor device according to an exemplary embodiment may be an SRAM cell which consists of eight transistors by adding two pass gate transistors to an SRAM cell which is implemented with six transistors. Each of the first additional transistor PPU3 and the second additional transistor PPU4 of the semiconductor device according to the exemplary embodiment may serve as a pull-up transistor along with each of the first pull-up transistor PPU1 and the second pull-up transistor PPU2. According to the exemplary embodiment, it is possible to improve the read and write performance without increasing the area as compared to an SRAM cell which is implemented with six transistors.

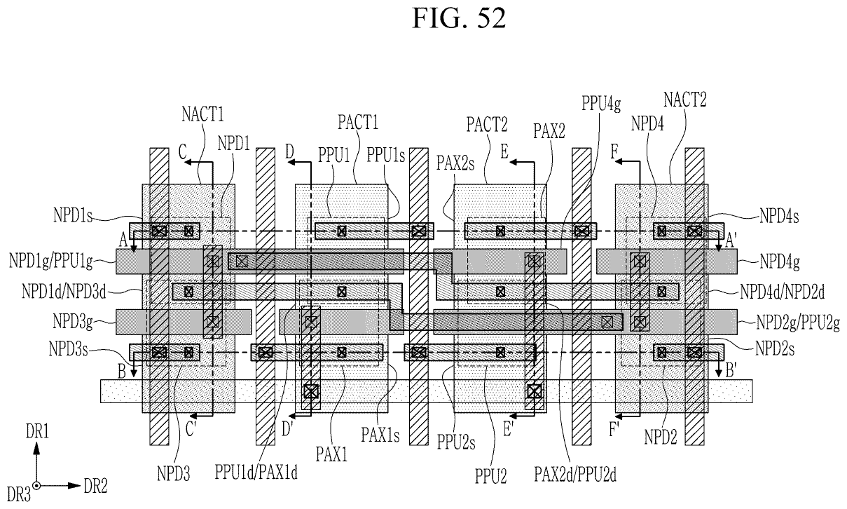

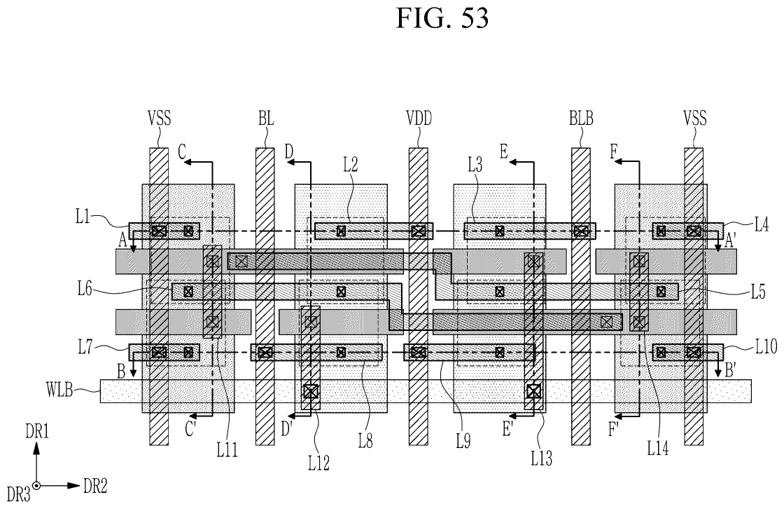

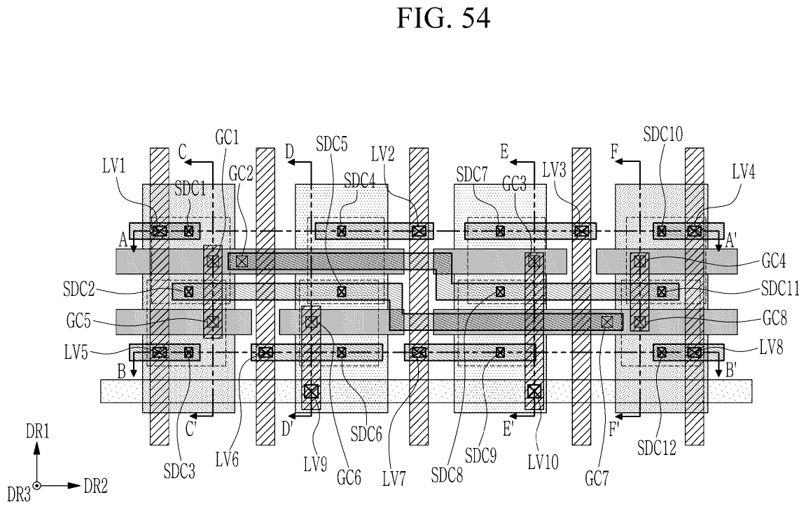

Hereinafter, a semiconductor device according to an exemplary embodiment will be described with reference to FIGS. 52 to 61. A memory cell array of the semiconductor device according to FIGS. 52 to 61 may be identical to that shown in FIG. 31.

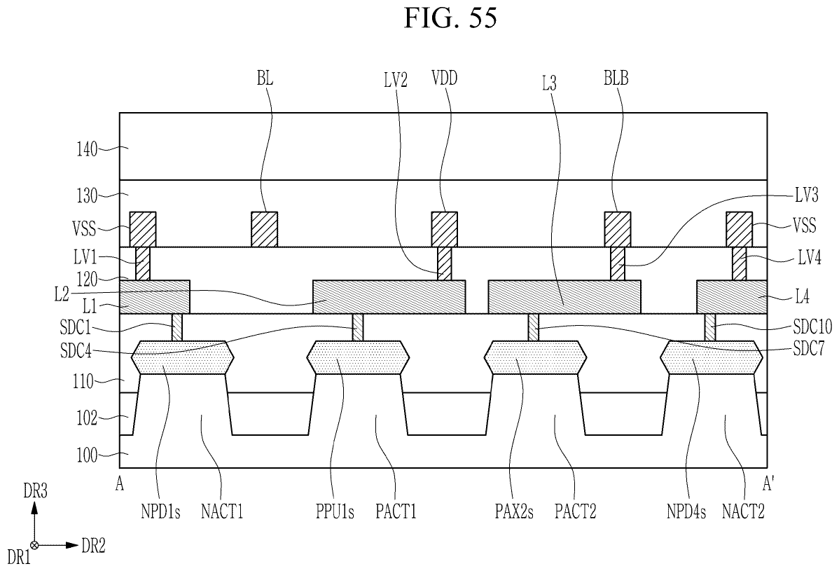

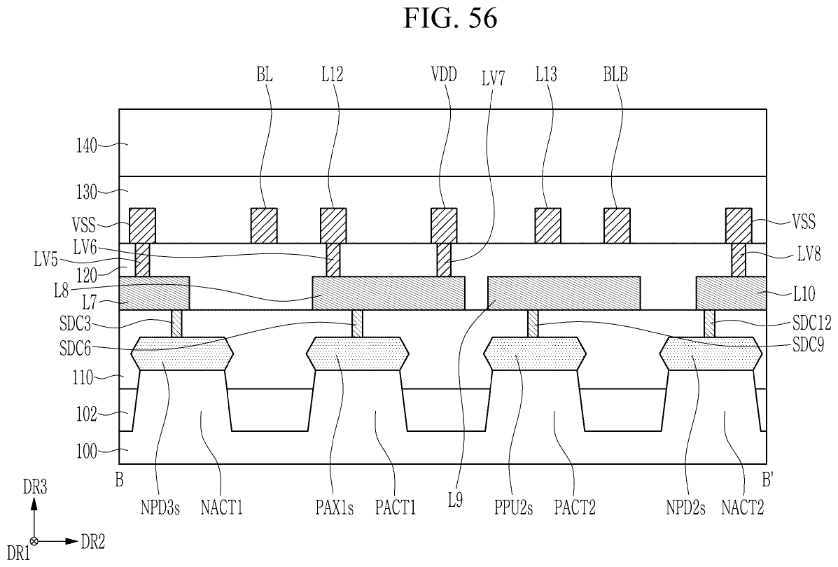

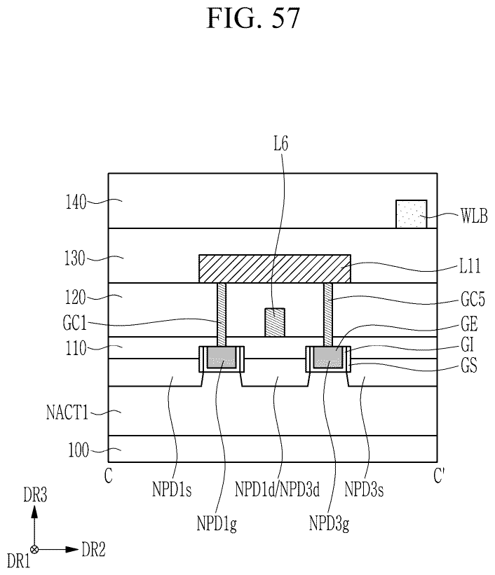

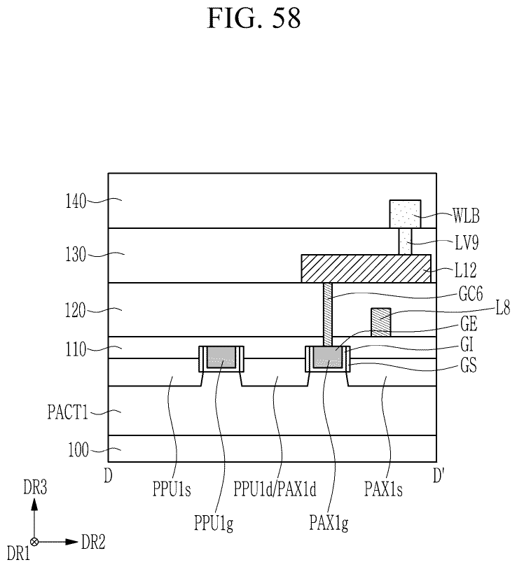

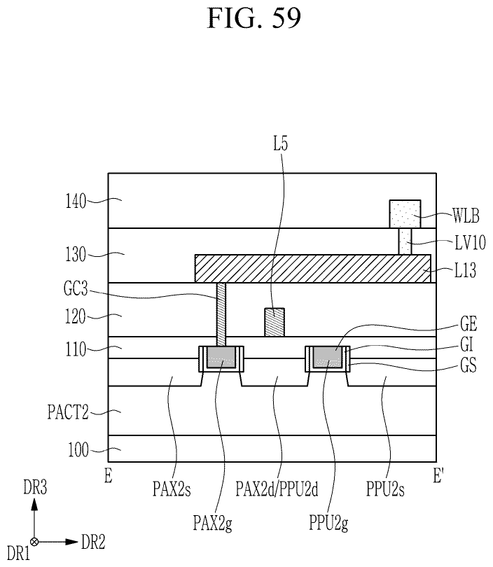

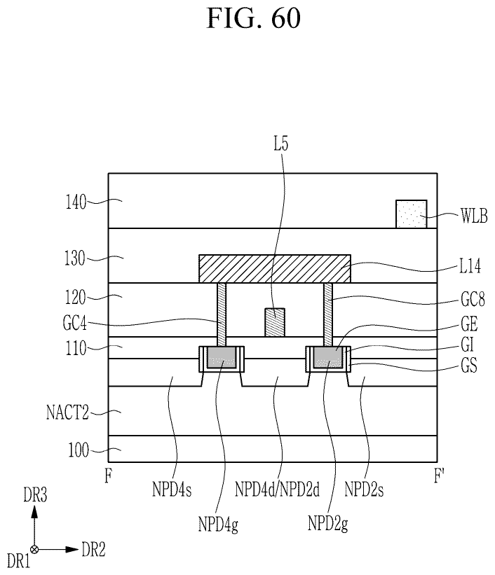

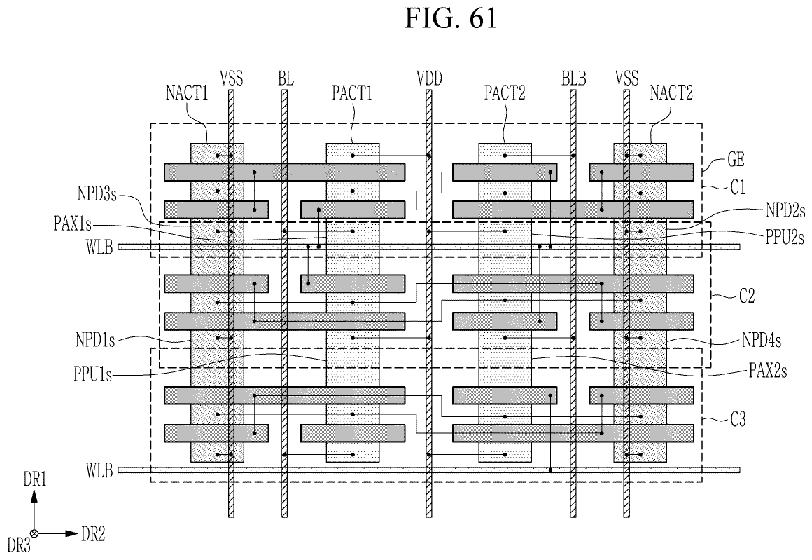

FIGS. 52 to 54 are plan layout diagrams of a memory cell of the semiconductor device according to the exemplary embodiment. FIG. 55 is a cross-sectional view taken along line A-A′ of FIGS. 52 to 54. FIG. 56 is a cross-sectional view taken along line B-B′ of FIGS. 52 to 54. FIG. 57 is a cross-sectional view taken along line C-C′ of FIGS. 52 to 54. FIG. 58 is a cross-sectional view taken along line D-D′ of FIGS. 52 to 54. FIG. 59 is a cross-sectional view taken along line E-E′ of FIGS. 52 to 54. FIG. 60 is a cross-sectional view taken along line F-F′ of FIGS. 52 to 54. FIG. 61 is a view schematically illustrating a plurality of memory cells of the semiconductor device according to the exemplary embodiment.

Hereinafter, differences from the semiconductor device according to FIGS. 31 to 41 will be mainly described, and a redundant description will not be made or will be made in brief.

The circuit of each of the plurality of memory cells MC of the semiconductor device according to FIGS. 52 to 61 may be identical to that shown in FIG. 21. Each of the plurality of memory cells MC of the semiconductor device according to the exemplary embodiment may be an SRAM cell which is implemented with eight transistors. Each of the plurality of memory cells MC may include a first pull-up transistor PPU1, a first pull-down transistor NPD1, a second pull-up transistor PPU2, a second pull-down transistor NPD2, a first pass gate transistor NAX1, a second pass gate transistor NAX2, a first additional transistor NPD3, and a second additional transistor NPD4.

The first pull-up transistor PPU1 and the second pull-up transistor PPU2 may be p-type transistors. The first pull-down transistor NPD1 and the second pull-down transistor NPD2 may be n-type transistors. According to the exemplary embodiment, the first pass gate transistor PAX1 and the second pass gate transistor PAX2 may be p-type transistors, and the first additional transistor NPD3 and the second additional transistor NPD4 may be n-type transistors.

Hereinafter, the arrangement and connection relationship of eight transistors constituting each of the plurality of memory cells MC will be described with reference to FIGS. 52 to 60.

Referring to FIGS. 52 to 60, the first pull-up transistor PPU1 and the first pass gate transistor PAX1 may be positioned on a first active region PACT1, and the first pull-down transistor NPD1 and the first additional transistor NPD3 may be positioned on a second active region NACT1. The second pull-up transistor PPU2 and the second pass gate transistor PAX2 may be positioned on a third active region PACT2. The second pull-down transistor NPD2 and the second additional transistor NPD4 may be positioned on a fourth active region NACT2.

The first pass gate transistor PAX1 may be disposed on one side of the first pull-up transistor PPU1 on the first active region PACT1. The first additional transistor NPD3 may be positioned on one side of the first pull-down transistor NPD1 on the second active region NACT1. The second pass gate transistor PAX2 may be positioned on one side of the second pull-up transistor PPU2 on the third active region PACT2. The second additional transistor NPD4 may be positioned on one side of the second pull-down transistor NPD2 on the fourth active region NACT2.

The first pull-up transistor PPU1 and the first pass gate transistor PAX1 may be disposed along the first direction DR1. The second pull-up transistor PPU2 and the second pass gate transistor PAX2 may be disposed along the first direction DR1. The first pull-up transistor PPU1 may be disposed so as to face the second pass gate transistor PAX2 in the second direction DR2. The second pull-up transistor PPU2 may be disposed so as to face the first pass gate transistor PAX1.

The first pull-down transistor NPD1 and the first additional transistor NPD3 may be disposed along the first direction DR1. The first pull-down transistor NPD1 may be disposed so as to face the first pull-up transistor PPU1 in the second direction DR2. The first additional transistor NPD3 may be disposed so as to face the first pass gate transistor PAX1 in the second direction DR2.

The second pull-down transistor NPD2 and the second additional transistor NPD4 may be disposed along the first direction DR1. The second pull-down transistor NPD2 may be disposed so as to face the second pull-up transistor PPU2 in the second direction DR2. The second additional transistor NPD4 may be disposed so as to face the second pass gate transistor PAX2 in the second direction DR2.

In the first active region PACT1 on both sides of the gate electrode PAX1g of the first pass gate transistor PAX1, the source region PAX1s and drain region PAX1d of the first pass gate transistor PAX1 may be disposed. In the first active region PACT1 on both sides of the gate electrode PPU1g of the first pull-up transistor PPU1, the source region PPU1s and drain region PPU1d of the first pull-up transistor PPU1 may be disposed. The drain region PAX1d of the first additional transistor PAX1 and the drain region PPU1d of the first pull-up transistor PPU1 may be integrally formed.

In the third active region PACT2 on both sides of the gate electrode PPU2g of the second pull-up transistor PPU2, the source region PPU2s and drain region PPU2d of the second pull-up transistor PPU2 may be disposed. In the third active region PACT2 on both sides of the gate electrode PAX2g of the second pass gate transistor PAX2, the source region PAX2s and drain region PAX2d of the second pass gate transistor PAX2 may be disposed. The drain region PAX2d of the second pass gate transistor PAX2 and the drain region PPU2d of the second pull-up transistor PPU2 may be integrally formed.

In the second active region NACT1 on both sides of the gate electrode NPD3g of the first additional transistor NPD3, the source region NPD3s and drain region NPD3d of the first additional transistor NPD3 may be disposed. In the second active region NACT1 on both sides of the gate electrode NPD1g of the first pull-down transistor NPD1, the source region NPD1s and drain region NPD1d of the first pull-down transistor NPD1 may be disposed. The drain region NPD3d of the first additional transistor NPD3 and the drain region NPD1d of the first pull-down transistor NPD1 may be integrally formed.

In the fourth active region NACT2 on both sides of the gate electrode NPD4g of the second additional transistor NPD4, the source region NPD4s and drain region NPD4d of the second additional transistor NPD4 may be disposed. In the fourth active region NACT2 on both sides of the gate electrode NPD2g of the second pull-down transistor NPD2, the source region NPD2s and drain region NPD2d of the second pull-down transistor NPD2 may be disposed. The drain region NPD4d of the second additional transistor NPD4 and the drain region NPD2d of the second pull-down transistor NPD2 may be integrally formed. Source drain contacts SDC1, SDC2, SDC3, SDC4, SDC5, SDC6, SDC7, SDC8, SDC9, SDC10, SDC11, and SDC12 may pass through the first interlayer insulating layer 110 and be connected to the source/drain regions. The source drain contacts SDC1, SDC2, SDC3, SDC4, SDC5, SDC6, SDC7, SDC8, SDC9, SDC10, SDC11, and SDC12 may be connected to a first wiring layer which is disposed inside the second interlayer insulating layer 120; however, the present disclosure is not necessarily limited thereto. The first wiring layer may include first to tenth connection wiring lines L1, L2, L3, L4, L5, L6, L7, L8, L9, and L10. Each of the first to tenth connection wiring lines L1, L2, L3, L4, L5, L6, L7, L8, L9, and L10 may be disposed so as to each extend in the second direction DR2 and be spaced apart in the first direction DR1. The second connection wiring line L2, the fifth connection wiring line L5, the sixth connection wiring line L6, and the eighth connection wiring line L8 may be sequentially disposed along the first direction DR1. The first connection wiring line L1, the third connection wiring line L3, and the fourth connection wiring line L4 may be positioned substantially at the same position as that of the second connection wiring line L2 in the first direction DR1. The first connection wiring line L1, the second connection wiring line L2, the third connection wiring line L3, and the fourth connection wiring line L4 may be disposed on the same extension line along the second direction DR2. The sixth connection wiring line L6, the seventh connection wiring line L7, the ninth connection wiring line L9, and the tenth connection wiring line L10 may be positioned substantially at the same position as that of the eighth connection wiring line L8 in the first direction DR1. The sixth connection wiring line L6, the seventh connection wiring line L7, the eighth connection wiring line L8, the ninth connection wiring line L9, and the tenth connection wiring line L10 may be disposed on the same extension line along the second direction DR2. The fifth connection wiring line L5 and the sixth connection wiring line L6 may include portions curved in the first direction DR1.

The third source drain contact SDC3 may be connected to the source region NPD3s of the first additional transistor NPD3. The third source drain contact SDC3 may be connected to the seventh connection wiring line L7.

The first source drain contact SDC1 may be connected to the source region NPD1s of the first pull-down transistor NPD1. The first source drain contact SDC1 may be connected to the first connection wiring line L1.

The tenth source drain contact SDC10 may be connected to the source region NPD4s of the second additional transistor NPD4. The tenth source drain contact SDC10 may be connected to the fourth connection wiring line L4.

The twelfth source drain contact SDC12 may be connected to the source region NPD2s of the second pull-down transistor NPD2. The twelfth source drain contact SDC12 may be connected to the tenth connection wiring line L10.

The sixth source drain contact SDC6 may be connected to the source region PAX1s of the first pass gate transistor PAX1. The sixth source drain contact SDC6 may be connected to the eighth connection wiring line L8.

The seventh source drain contact SDC7 may be connected to the source region PAX2s of the second pass gate transistor PAX2. The seventh source drain contact SDC7 may be connected to the third connection wiring line L3.

The fourth source drain contact SDC4 may be connected to the source region PPU1s of the first pull-up transistor PPU1. The fourth source drain contact SDC4 may be connected to the second connection wiring line L2.

The ninth source drain contact SDC9 may be connected to the source region PPU2s of the second pull-up transistor PPU2. The ninth source drain contact SDC9 may be connected to the ninth connection wiring line L9.

The second source drain contact SDC2 may be connected to the drain region NPD3d of the first additional transistor NPD3 and the drain region NPD1d of the first pull-down transistor NPD1. The fifth source drain contact SDC5 may be connected to the drain region PAX1d of the first pass gate transistor PAX1 and the drain region PPU1d of the first pull-up transistor PPU1. The second source drain contact SDC2 and the fifth source drain contact SDC5 may be connected to the sixth connection wiring line L6.

The eleventh source drain contact SDC11 may be connected to the drain region NPD4d of the second additional transistor NPD4 and the drain region NPD2d of the second pull-down transistor NPD2. The eighth source drain contact SDC8 may be connected to the drain region PAX2d of the second pass gate transistor PAX2 and the drain region PPU2d of the second pull-up transistor PPU2. The eleventh source drain contact SDC11 and the eighth source drain contact SDC8 may be connected to the fifth connection wiring line L5.

Gate contacts GC1, GC2, GC3, GC4, GC5, GC6, GC7, and GC8 may pass through the second interlayer insulating layer 120 and the first interlayer insulating layer 110 and be connected to the gate electrodes GE. The second gate contact GC2 and the seventh gate contact GC7 may be connected to the first wiring layer which is disposed inside the second interlayer insulating layer 120, and the first gate contact GC1, the third gate contact GC3, the fourth gate contact GC4, the fifth gate contact GC5, the sixth gate contact GC6, and the eighth gate contact GC8 may be connected to a second wiring layer which is disposed inside the third interlayer insulating layer 130; however, the present disclosure is not necessarily limited thereto. For example, the second wiring layer may include eleventh to fourteenth connection wiring lines L11, L12, L13, and L14, the bit line BL, the complementary bit line BLB, the first power line VDD, and the second power line VSS. The eleventh to fourteenth connection wiring lines L11, L12, L13, and L14, the bit line BL, the complementary bit line BLB, the first power line VDD, and the second power line VSS may be disposed so as to each extend in the first direction DR1 and be spaced apart in the second direction DR2. For example, a second power line VSS, the eleventh connection wiring line L11, the bit line BL, the twelfth connection wiring line L12, the first power line VDD, the thirteenth connection wiring line L13, the complementary bit line BLB, the fourteenth connection wiring line L14, and another second power line VSS may be sequentially disposed along the second direction DR2; however, the exemplary embodiment is not necessarily limited thereto. The arrangement order of the wiring lines in the second wiring layer may be variously changed. The fifth gate contact GC5 may be connected to the gate electrode NPD3g of the first additional transistor NPD3. The first gate contact GC1 may be connected to the gate electrode NPD1g of the first pull-down transistor NPD1 and the gate electrode PPU1g of the first pull-up transistor PPU1. The fifth gate contact GC5 and the first gate contact GC1 may be connected to the eleventh connection wiring line L11. The gate electrode NPD3g of the first additional transistor NPD3 may be electrically connected to the gate electrode NPD1g of the first pull-down transistor NPD1 and the gate electrode PPU1g of the first pull-up transistor PPU1 by the fifth gate contact GC5, the first gate contact GC1, and the eleventh connection wiring line L11.

The fourth gate contact GC4 may be connected to the gate electrode NPD4g of the second additional transistor NPD4. The eighth gate contact GC8 may be connected to the gate electrode NPD2g of the second pull-down transistor NPD2 and the gate electrode PPU2g of the second pull-up transistor PPU2. The fourth gate contact GC4 and the eighth gate contact GC8 may be connected to the fourteenth connection wiring line L14. The gate electrode NPD4g of the second additional transistor NPD4 may be electrically connected to the gate electrode NPD2g of the second pull-down transistor NPD2 and the gate electrode PPU2g of the second pull-up transistor PPU2 by the fourth gate contact GC4, the eighth gate contact GC8, and the fourteenth connection wiring line L14.

The sixth gate contact GC6 may be connected to the gate electrode PAX1g of the first pass gate transistor PAX1. The sixth gate contact GC6 may be connected to the twelfth connection wiring line L12. The third gate contact GC3 may be connected to the gate electrode PAX2g of the second pass gate transistor PAX2. The third gate contact GC3 may be connected to the thirteenth connection wiring line L13.

The second gate contact GC2 may be connected to the gate electrode PPU1g of the first pull-up transistor PPU1 and the gate electrode NPD1g of the first pull-down transistor NPD1. The second gate contact GC2 may be connected to the fifth connection wiring line L5. The gate electrode PPU1g of the first pull-up transistor PPU1 and the gate electrode NPD1g of the first pull-down transistor NPD1 may be electrically connected to the drain region NPD4d of the second additional transistor NPD4 and the drain region PAX2d of the second pass gate transistor PAX2 by the second gate contact GC2, the eighth source drain contact SDC8, the eleventh source drain contact SDC11, and the fifth connection wiring line L5.

The seventh gate contact GC7 may be connected to the gate electrode PPU2g of the second pull-up transistor PPU2 and the gate electrode NPD2g of the second pull-down transistor NPD2. The seventh gate contact GC7 may be connected to the sixth connection wiring line L6. The gate electrode PPU2g of the second pull-up transistor PPU2 and the gate electrode NPD2g of the second pull-down transistor NPD2 may be electrically connected to the drain region NPD3d of the first additional transistor NPD3 and the drain region PAX1d of the first pass gate transistor PAX1 by the seventh gate contact GC7, the fifth source drain contact SDC5, the second source drain contact SDC2, and the sixth connection wiring line L6.

The third wiring layer which is disposed inside the fourth interlayer insulating layer 140 may include the complementary word line WLB. For example, the complementary word line WLB may be positioned at the edge of the memory cell; however, the exemplary embodiment is not necessarily limited thereto. Unlike in the exemplary embodiment of FIGS. 31 to 41, the word line WL may be omitted.

Vias LV1, LV2, LV3, LV4, LV5, LV6, LV7, LV8, LV9, and LV10 may connect the first wiring layer, the second wiring layer, and the third wiring layer. The ninth via LV9 and the tenth via LV10 may pass through the third interlayer insulating layer 130 and connect the second wiring layer and the third wiring layer. The first to eighth vias LV1, LV2, LV3, LV4, LV5, LV6, LV7, and LV8 may pass through the second interlayer insulating layer 120 and connect the first wiring layer and the second wiring layer.

The ninth via LV9 may connect the complementary word line WLB and the twelfth connection wiring line L12. In other words, the gate electrode PAX1g of the first pass gate transistor PAX1 may be electrically connected to the complementary word line WLB by the sixth gate contact GC6, the twelfth connection wiring line L12, and the ninth via LV9.

The tenth via LV10 may connect the word line WL and the thirteenth connection wiring line L13. In other words, the gate electrode PAX2g of the second pass gate transistor PAX2 may be electrically connected to the complementary word line WLB by the third gate contact GC3, the thirteenth connection wiring line L13, and the tenth via LV10.

The sixth via LV6 may connect the bit line BL and the eighth connection wiring line L8. In other words, the source region PAX1s of the first pass gate transistor PAX1 may be electrically connected to the bit line BL by the sixth source drain contact SDC6, the eighth connection wiring line L8, and the sixth via LV6.

The third via LV3 may connect the complementary bit line BLB and the third connection wiring line L3. In other words, the source region PAX2s of the second pass gate transistor PAX2 may be electrically connected to the complementary bit line BLB by the seventh source drain contact SDC7, the third connection wiring line L3, and the third via LV3.

The second via LV2 may connect the first power line VDD and the second connection wiring line L2. In other words, the source region PPU1s of the first pull-up transistor PPU1 may be electrically connected to the first power line VDD by the fourth source drain contact SDC4, the second connection wiring line L2, and the second via LV2.

The seventh via LV7 may correspond to the first power line VDD and the ninth connection wiring line L9. In other words, the source region PPU2s of the second pull-up transistor PPU2 may be electrically connected to the first power line VDD by the ninth source drain contact SDC9, the ninth connection wiring line L9, and the seventh via LV7.

The first via LV1 may connect the second power line VSS and the first connection wiring line L1. In other words, the source region NPD1s of the first pull-down transistor NPD1 may be electrically connected to the second power line VSS by the first source drain contact SDC1, the first connection wiring line L1, and the first via LV1.

The fifth via LV5 may connect the second power line VSS and the seventh connection wiring line L7. In other words, the source region NPD3s of the first additional transistor NPD3 may be electrically connected to the second power line VSS by the third source drain contact SDC3, the seventh connection wiring line L7, and the fifth via LV5.

The eighth via LV8 may connect the second power line VSS and the tenth connection wiring line L10. In other words, the source region NPD2s of the second pull-down transistor NPD2 may be electrically connected to the second power line VSS by the twelfth source drain contact SDC12, the tenth connection wiring line L10, and the eighth via LV8.

The fourth via LV4 may connect the second power line VSS and the fourth connection wiring line L4. In other words, the source region NPD4s of the second additional transistor NPD4 may be electrically connected to the second power line VSS by the tenth source drain contact SDC10, the fourth connection wiring line L4, and the fourth via LV4.

Hereinafter, the relationship of a plurality of memory cells adjacent in the first direction DR1 of the semiconductor device accuracy of the exemplary embodiment will be described with reference to FIG. 61 together.

Referring to FIG. 61, the semiconductor device according to the exemplary embodiment may include a first memory cell C1, a second memory cell C2, and a third memory cell C3 which are disposed along the first direction DR1. In respect to each of the first memory cell C1, the second memory cell C2, and the third memory cell C3, the contents of the memory cell described above with reference to FIGS. 52 to 60 may be equally applied. Each of the first memory cell C1, the second memory cell C2, and the third memory cell C3 may include a first pull-up transistor PPU1, a first pull-down transistor NPD1, a second pull-up transistor PPU2, a second pull-down transistor NPD2, a first pass gate transistor PAX1, a second pass gate transistor PAX2, a first additional transistor NPD3, and a second additional transistor NPD4.

The transistors which are disposed at both ends of each memory cell in the first direction DR1 may share a source/drain region with a transistor which is included in another memory cell adjacent thereto in the first direction DR1 and performs the same function.

According to the exemplary embodiment, the first additional transistor NPD3 of the first memory cell C1 and the first additional transistor NPD3 of the second memory cell C2 may share a source region NPD3s. The second additional transistor NPD4 of the second memory cell C2 and the second additional transistor NPD4 of the third memory cell C3 may share a source region NPD4s.

According to the exemplary embodiment, the first pass gate transistor PAX1 of the first memory cell C1 and the first pass gate transistor PAX1 of the second memory cell C2 may share a source region PAX1s. The second pass gate transistor PAX2 of the second memory cell C2 and the second pass gate transistor PAX2 of the third memory cell C3 may share a source region PAX2s.

According to the exemplary embodiment, the second pull-down transistor NPD2 of the first memory cell C1 and the second pull-down transistor NPD2 of the second memory cell C2 may share a source region NPD2s. The first pull-down transistor NPD1 of the second memory cell C2 and the first pull-down transistor NPD1 of the third memory cell C3 may share a source region NPD1s.

According to the exemplary embodiment, the second pull-up transistor PPU2 of the first memory cell C1 and the second pull-up transistor PPU2 of the second memory cell C2 may share a source region PPU2s. The first pull-up transistor PPU1 of the second memory cell C2 and the first pull-up transistor PPU1 of the third memory cell C3 may share a source region PPU1s.

According to the exemplary embodiment, the source region NPD3s of the first additional transistor NPD3 of each memory cell may be connected to the second power line VSS. The source region NPD4s of the second additional transistor NPD4 of each memory cell may be connected to the second power line VSS.

The second memory cell C2 may share the connection relationship of the source region NPD3s of the first additional transistor NPD3 with the first memory cell C1. In other words, the second memory cell C2 may share the third source drain contact SDC3 that is connected to the source region NPD3s of the first additional transistor NPD3, the seventh connection wiring line L7 to which the third source drain contact SDC3 is connected, and the fifth via LV5 that connects the seventh connection wiring line L7 and the second power line VSS, with the first memory cell C1.

The second memory cell C2 may share the connection relationship of the source region NPD4s of the second additional transistor NPD4 with the third memory cell C3. In other words, the second memory cell C2 may share the tenth source drain contact SDC10 that is connected to the source region NPD4s of the second additional transistor NPD4, the fourth connection wiring line L4 to which the tenth source drain contact SDC10 is connected, and the fourth via LV4 that connect the fourth connection wiring line L4 and the second power line VSS, with the third memory cell C3.

The second memory cell C2 may share the connection relationship of the source region NPD2s of the second pull-down transistor NPD2 with the first memory cell C1. In other words, the second memory cell C2 may share the twelfth source drain contact SDC12 that is connected to the source region NPD2s of the second pull-down transistor NPD2, the tenth connection wiring line L10 to which the twelfth source drain contact SDC12 is connected, and the eighth via LV8 that connects the tenth connection wiring line L10 and the second power line VSS, with the first memory cell C1.

The second memory cell C2 may share the connection relationship of the source region NPD1s of the first pull-down transistor NPD1 with the third memory cell C3. In other words, the second memory cell C2 may share the first source drain contact SDC1 that is connected to the source region NPD1s of the first pull-down transistor NPD1, the first connection wiring line L1 to which the first source drain contact SDC1 is connected, and the first via LV1 that connects the first connection wiring line L1 and the second power line VSS, with the first memory cell C1.

The second memory cell C2 may share the connection relationship of the source region PPU2s of the second pull-up transistor PPU2 with the first memory cell C1. In other words, the second memory cell C2 may share the ninth source drain contact SDC9 that is connected to the source region PPU2s of the second pull-up transistor PPU2, the ninth connection wiring line L9 to which the ninth source drain contact SDC9 is connected, and the seventh via LV7 that connects the ninth connection wiring line L9 and the first power line VDD, with the first memory cell C1.

The second memory cell C2 may share the connection relationship of the source region PPU1s of the first pull-up transistor PPU1 with the third memory cell C3. In other words, the second memory cell C2 may share the fourth source drain contact SDC4 that is connected to the source region PPU1s of the first pull-up transistor PPU1, the second connection wiring line L2 to which the fourth source drain contact SDC4 is connected, and the second via LV2 that connects the second connection wiring line L2 and the first power line VDD, with the first memory cell C1.

The second memory cell C2 may share the connection relationship of the source region PAX1s of the first pass gate transistor PAX1 with the first memory cell C1. In other words, the second memory cell C2 may share the sixth source drain contact SDC6 that is connected to the source region PAX1s of the first pass gate transistor PAX1, the eighth connection wiring line L8 to which the sixth source drain contact SDC6 is connected, and the sixth via LV6 that connects the eighth connection wiring line L8 and the bit line BL, with the first memory cell C1.

The second memory cell C2 may share the connection relationship of the source region PAX2s of the second pass gate transistor PAX2 with the third memory cell C3. In other words, the second memory cell C2 may share the seventh source drain contact SDC7 that is connected to the source region PAX2s of the second pass gate transistor PAX2, the third connection wiring line L3 to which the seventh source drain contact SDC7 is connected, and the third via LV3 that connects the third connection wiring line L3 and the complementary bit line BLB, with the third memory cell C3.

The process of forming the transistors of the semiconductor device according to the exemplary embodiment of FIGS. 52 to 61 may be identical to the process of forming the transistors of the semiconductor device according to the exemplary embodiment of FIGS. 31 to 41. The semiconductor device according to the exemplary embodiment of FIGS. 52 to 61 may be formed by changing etch masks for forming contact holes, via holes, and wiring lines of the semiconductor device according to the exemplary embodiment of FIGS. 31 to 40.

The semiconductor device according to the exemplary embodiment may include the first additional transistor NPD3 and the second additional transistor NPD4 that are displayed on one side of each of the first pull-down transistor NPD1 and the second pull-down transistor NPD2 so as to face the first pass gate transistor PAX1 and the second pass gate transistor PAX2, respectively. A memory cell of the semiconductor device according to an exemplary embodiment may be an SRAM cell which consists of eight transistors by adding two pass gate transistors to an SRAM cell which is implemented with six transistors. Each of the first additional transistor NPD3 and the second additional transistor NPD4 of the semiconductor device according to the exemplary embodiment may serve as a pull-down transistor along with each of the first pull-down transistor NPD1 and the second pull-down transistor NPD2. According to the exemplary embodiment, it is possible to improve the read and write performance without increasing the area as compared to an SRAM cell which is implemented with six transistors.

While this disclosure has been described in connection with what is presently considered to be practical exemplary embodiments, it is to be understood that the invention is not limited to the disclosed embodiments. On the contrary, it is intended to cover various modifications and equivalent arrangements included within the spirit and scope of the appended claims.

What is claimed is:

1. A semiconductor device comprising:
a substrate having an upper surface;
a memory cell array that includes a plurality of memory cells which is disposed on the substrate; and
a bit line and a complementary bit line that extend in a first direction parallel with the upper surface of the substrate,
wherein each of at least some of the plurality of memory cells includes a first inverter, a second inverter, a first pass gate transistor that is connected between the bit line and the second inverter, a second pass gate transistor that is connected between the complementary bit line and the first inverter, a first additional transistor that is connected between the first pass gate transistor and the second inverter, and a second additional transistor that is connected between the second pass gate transistor and the first inverter,
wherein the plurality of memory cells includes a first memory cell, a second memory cell, and a third memory cell which are sequentially disposed in the first direction,
wherein the first additional transistor of the second memory cell and the first additional transistor of the first memory cell share a source region, and
wherein the second additional transistor of the second memory cell and the second additional transistor of the third memory cell share a source region.

2. The semiconductor device of claim 1, wherein:
the first inverter includes a first pull-up transistor that is positioned on a first active region, and a first pull-down transistor that is positioned on a second active region, wherein the first active region supports transistors of a first conductivity type and the second active region supports transistors of a second conductivity type,
the second inverter includes a second pull-up transistor that is positioned on the first active region, and a second pull-down transistor that is positioned on the second active region,
the first pass gate transistor and the second pass gate transistor are disposed on both sides of the first pull-down transistor and the second pull-down transistor on the second active region, and
the first additional transistor and the second additional transistor are disposed on both sides of the first pull-up transistor and the second pull-up transistor, respectively, on the first active region.

3. The semiconductor device of claim 1, wherein:
the substrate further includes a third active region supporting transistors of the first conductivity type, and a fourth active region supporting transistors of the second conductivity,
the first inverter includes a first pull-up transistor that is positioned on the first active region, and a first pull-down transistor that is positioned on the second active region,
the second inverter includes a second pull-up transistor that is positioned on the third active region, and a second pull-down transistor that is positioned on the fourth active region,
the first pass gate transistor is disposed on one side of the first pull-down transistor on the second active region,
the second pass gate transistor is disposed on one side of the second pull-down transistor on the fourth active region,
the first additional transistor is disposed on one side of the first pull-up transistor on the first active region, and
the second additional transistor is disposed on one side of the second pull-up transistor on the third active region.

4. The semiconductor device of claim 2, wherein:
the source region of the first additional transistor is connected to the bit line,
a drain region of the first additional transistor is connected to the input terminal of the second inverter,
the source region of the second additional transistor is connected to the complementary bit line, and
a drain region of the second additional transistor is connected to the input terminal of the first inverter.

5. The semiconductor device of claim 4, further comprising:
a word line and a complementary word line that extend in a second direction parallel with the upper surface of the substrate and perpendicular to the first direction,
wherein a gate electrode of the first pass gate transistor and a gate electrode of the second pass gate transistor are connected to the word line, and
wherein a gate electrode of the first additional transistor and a gate electrode of the second additional transistor are connected to the complementary word line.

6. The semiconductor device of claim 2, wherein:
a gate electrode of the first additional transistor is connected to a gate electrode of the first pull-up transistor, and
a gate electrode of the second additional transistor is connected to a gate electrode of the second pull-up transistor.

7. The semiconductor device of claim 6, further comprising:
a first power line to which a first power voltage is applied; and
a second power line to which a second power voltage lower than the first power voltage is applied,
wherein each of the first inverter and the second inverter is connected between the first power line and the second power line,
wherein the source region of the first additional transistor is connected to the first power line,
wherein a drain region of the first additional transistor is connected to an input terminal of the second inverter,
wherein the source region of the second additional transistor is connected to the first power line, and
wherein a drain region of the second additional transistor is connected to the input terminal of the first inverter.

8. The semiconductor device of claim 1, wherein:
the first inverter includes a first pull-up transistor that is positioned on a first active region, and a first pull-down transistor that is positioned on a second active region, wherein the first active region supports transistors of a first conductivity type and the second active region supports transistors of a second conductivity type,
the second inverter includes a second pull-up transistor that is positioned on the first active region, and a second pull-down transistor that is positioned on the second active region,
the first pass gate transistor and the second pass gate transistor are disposed on both sides of the first pull-up transistor and the second pull-up transistor, respectively, on the first active region, and
the first additional transistor and the second additional transistor are disposed on both sides of the first pull-down transistor and the second pull-down transistor, respectively, on the second active region.

9. The semiconductor device of claim 1, wherein:
the substrate includes a first active region and third active region supporting transistors of a first conductivity type, and a second active region and a fourth active region supporting transistors of a second conductivity type,
the first inverter includes a first pull-up transistor that is positioned on the first active region, and a first pull-down transistor that is positioned on the second active region,
the second inverter includes a second pull-up transistor that is positioned on the third active region, and a second pull-down transistor that is positioned on the fourth active region,
the first pass gate transistor is disposed on one side of the first pull-up transistor on the first active region,
the second pass gate transistor is disposed on one side of the second pull-up transistor on the third active region,
the first additional transistor is disposed on one side of the first pull-down transistor on the second active region, and
the second additional transistor is disposed on one side of the second pull-down transistor on the fourth active region.

10. The semiconductor device of claim 8, wherein:
the gate electrode of the first additional transistor is connected to the gate electrode of the first pull-down transistor, and
the gate electrode of the second additional transistor is connected to the gate electrode of the second pull-down transistor.

11. The semiconductor device of claim 10, further comprising:
a first power line to which a first power voltage is applied; and
a second power line to which a second power voltage lower than the first power voltage is applied,
wherein each of the first inverter and the second inverter is connected between the first power line and the second power line,
the source region of the first additional transistor is connected to the second power line,
the drain region of the first additional transistor is connected to the input terminal of the second inverter,
the source region of the second additional transistor is connected to the second power line, and
the drain region of the second additional transistor is connected to the input terminal of the first inverter.

12. A semiconductor device comprising:
a substrate having an upper surface;
a memory cell array that includes a plurality of memory cells which is disposed on the substrate;
a bit line and a complementary bit line that extend in a first direction parallel with the upper surface of the substrate; and
a word line and a complementary word line that extend in a second direction parallel with the upper surface of the substrate and perpendicular to the first direction,
wherein each of at least some of the plurality of memory cells includes a first inverter, a second inverter, a first pass gate transistor and a first additional transistor that are connected between the bit line and the second inverter, and a second pass gate transistor and a second additional transistor that are connected between the complementary bit line and the first inverter, and
the first pass gate transistor and the second pass gate transistor are connected to the word line, and the first additional transistor and the second additional transistor are connected to the complementary word line.
the plurality of memory cells includes a first memory cell, a second memory cell, and a third memory cell which are sequentially disposed in the first direction,
the first additional transistor of the second memory cell and the first additional transistor of the first memory cell share a source region, and
the second additional transistor of the second memory cell and the second additional transistor of the third memory cell share a source region.

13. The semiconductor device of claim 12, wherein:
the first inverter includes a first pull-up transistor that is positioned on the first active region, and a first pull-down transistor that is positioned on the second active region, wherein the first active region supports transistors of a first conductivity type and the second active region supports transistors of a second conductivity type,
the second inverter includes a second pull-up transistor that is positioned on the first active region, and a second pull-down transistor that is positioned on the second active region,
the first pass gate transistor and the second pass gate transistor are positioned on the second active region, and
the first additional transistor and the second additional transistor are positioned on the first active region.

14. The semiconductor device of claim 13, wherein:
a source region of the first additional transistor is connected to a drain region of the first pass gate transistor, and a source region of the second additional transistor is connected to a drain region of the second pass gate transistor,
the drain region of the first additional transistor is connected to the source region of the first pass gate transistor, and the drain region of the second additional transistor is connected to the source region of the second pass gate transistor, and
a gate electrode of the first additional transistor and a gate electrode of the second additional transistor are connected to the complementary word line.

15. The semiconductor device of claim 13, wherein:
the first pull-up transistor and the second pull-up transistor are disposed between the first additional transistor and the second additional transistor, and
the first pull-down transistor and the second pull-down transistor are disposed between the first pass gate transistor and the second pass gate transistor.

16. A semiconductor device comprising:
a substrate having an upper surface;
a memory cell array that includes a plurality of memory cells which is disposed on the substrate;
a bit line and a complementary bit line that extend in a first direction parallel with the upper surface of the substrate; and
a first power line to which a first power voltage is applied, and a second power line to which a second power voltage lower than the first power voltage is applied, and
wherein each of at least some of the plurality of memory cells includes a first inverter and a second inverter that are connected between the first power line and the second power line, a first pass gate transistor that is connected between the bit line and the second inverter, a second pass gate transistor that is connected between the complementary bit line and the first inverter, a first additional transistor that is connected between the second inverter, and the first power line and the second power line, and a second additional transistor that is connected between the first inverter, and the first power line and the second power line,
the plurality of memory cells includes a first memory cell, a second memory cell, and a third memory cell which are sequentially disposed in the first direction,
the first additional transistor of the second memory cell and the first additional transistor of the first memory cell share a source region, and
the second additional transistor of the second memory cell and the second additional transistor of the third memory cell share a source region.

17. The semiconductor device of claim 16, wherein:
the first inverter includes a first pull-up transistor that is positioned on the first active region, and a first pull-down transistor that is positioned on the second active region, wherein the first active region supports transistors of a first conductivity type and the second active region supports transistors of a second conductivity type,
the second inverter includes a second pull-up transistor that is positioned on the first active region, and a second pull-down transistor that is positioned on the second active region, and
the first pass gate transistor and the second pass gate transistor are positioned on the second active region, and the first additional transistor and the second additional transistor are positioned on the first active region.

18. The semiconductor device of claim 17, wherein:
a source region of the first additional transistor and a source region of the second additional transistor are connected to the first power line,
a drain region of the first additional transistor is connected to a drain region of the first pull-up transistor, and a drain region of the second additional transistor is connected to a drain region of the second pull-up transistor, and
a gate electrode of the first additional transistor is connected to the a electrode of the first pull-up transistor, and a gate electrode of the second additional transistor is connected to a gate electrode of the second pull-up transistor.

19. The semiconductor device of claim 16, wherein:
the substrate includes a first active region supporting transistors of a first conductivity type, and a second active region supporting transistors of a second conductivity type,
the first inverter includes a first pull-up transistor that is positioned on the first active region, and a first pull-down transistor that is positioned on the second active region,
the second inverter includes a second pull-up transistor that is positioned on the first active region, and a second pull-down transistor that is positioned on the second active region, and
the first pass gate transistor and the second pass gate transistor are positioned on the first active region, and the first additional transistor and the second additional transistor are positioned on the second active region.

20. The semiconductor device of claim 19, wherein:
the source region of the first additional transistor and the source region of the second additional transistor are connected to the second power line,
the drain region of the first additional transistor is connected to the drain region of the first pull-down transistor, and the drain region of the second additional transistor is connected to the drain region of the second pull-down transistor, and
the gate electrode of the first additional transistor is connected to the gate electrode of the first pull-down transistor, and the gate electrode of the second additional transistor is connected to the gate electrode of the second pull-down transistor.
